(19) United States
(12) Patent Application Publication
(10) Pub. No.: US 2024/0224616 A1
(43) Pub. Date: Jul. 4, 2024

(54) Display Apparatus

(71) Applicant: Semiconductor Energy Laboratory Co., Ltd., Kanagawa-ken (JP)

(72) Inventors: Yuichi YANAGISAWA, Atsugi, Kanagawa (JP); Kenichi OKAZAKI, Atsugi, Kanagawa (JP); Takashi HAMADA, Atsugi, Kanagawa (JP); Shinya SASAGAWA, Chigasaki, Kanagawa (JP)

(73) Assignee: Semiconductor Energy Laboratory Co., Ltd., Kanagawa-ken (JP)

(21) Appl. No.: 18/569,342

(22) PCT Filed: Jun. 3, 2022
(86) PCT No.: PCT/IB2022/055176

§ 371 Date: Dec. 12, 2023

(30) Foreign Application Priority Data
Jun. 17, 2021 (JP) 2021-100984

(51) Int. Cl. H10K 59/122

(52) U.S. Cl. CPC H10K 59/122

(57) ABSTRACT

A display apparatus with high resolution is provided. A display apparatus which can achieve high color reproducibility is provided. A display apparatus with high luminance is provided. A highly reliable display apparatus is provided. The display apparatus includes a first insulating layer, a first conductive layer provided in an opening of the first insulating layer, a first EL layer over the first conductive layer and the first insulating layer, a second insulating layer in contact with a side surface of the first EL layer and a top surface of the first insulating layer, and a second conductive layer over the first EL layer and the second insulating layer.

### TECHNICAL FIELD

One embodiment of the present invention relates to a display apparatus and a display module. One embodiment of the present invention relates to a method for fabricating a display apparatus.

Note that one embodiment of the present invention is not limited to the above technical field. Examples of a technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a manufacturing method thereof. Note that in this specification and the like, a semiconductor device generally means a device that can function by utilizing semiconductor characteristics.

### BACKGROUND ART

In recent years, higher-resolution display panels have been required. As a device that requires a high-resolution display panel, for example, devices for virtual reality (VR), augmented reality (AR), substitutional reality (SR), or mixed reality (MR) have been actively developed in recent years.

Examples of display apparatuses that can be used for a display panel include, typically, a liquid crystal display apparatus, a light-emitting apparatus including a light-emitting element such as an organic EL (Electro Luminescence) element or a light-emitting diode (LED), and electronic paper performing display by an electrophoretic method or the like.

For example, the basic structure of an organic EL element is a structure where a layer containing a light-emitting organic compound is provided between a pair of electrodes. By voltage application to this element, light emission can be obtained from the light-emitting organic compound. A display apparatus using such an organic EL element does not need a backlight that is necessary for a liquid crystal display apparatus and the like; thus, a thin, lightweight, high-contrast, and low-power display apparatus can be achieved. Patent Document 1, for example, discloses an example of a display apparatus using an organic EL element.

Organic EL devices are used in display portions of display apparatuses and HMDs for AR or VR in some cases. Non-Patent Document 1 discloses a method employing standard UV photolithography for manufacturing an organic optoelectronic device, which is one of organic EL devices.

### REFERENCE

### Patent Document

[Patent Document 1] Japanese Published Patent Application No. 2002-324673

### Non-Patent Document

[Non-Patent Document 1] B. Lamprecht et al., “Organic optoelectronic device fabrication using standard UV photolithography” phys.stat.sol. (RRL) 2, No. 1, p. 16-18 (2008)

### SUMMARY OF THE INVENTION

### Problems to be Solved by the Invention

For example, in the above-described device for VR, AR, SR, or MR that is wearable, a lens for focus adjustment needs to be provided between eyes and the display panel. Since part of the screen is enlarged by the lens, low resolution of the display panel might cause a problem of weak senses of reality and immersion.

The display panel is also required to have high color reproducibility. In particular, when using the display panel with high color reproducibility, the above-described device for VR, AR, SR, or MR can perform display with colors that are close to those of the actual objects, leading to higher senses of reality and immersion.

An object of one embodiment of the present invention is to provide a display apparatus with extremely high resolution. An object of one embodiment of the present invention is to provide a display apparatus which can achieve high color reproducibility. An object of one embodiment of the present invention is to provide a high-luminance display apparatus. An object of one embodiment of the present invention is to provide a highly reliable display apparatus. An object of one embodiment of the present invention is to provide a method for manufacturing the above-described display apparatus.

Note that the description of these objects does not preclude the existence of other objects. Note that one embodiment of the present invention does not have to achieve all the objects. Note that objects other than these can be derived from the description of the specification, the drawings, the claims, and the like.

### Means for Solving the Problems

One embodiment of the present invention is a display apparatus including a first insulating layer, a first conductive layer provided in an opening of the first insulating layer, a first EL layer over the first conductive layer and the first insulating layer, a second insulating layer which is in contact with a side surface of the first EL layer and a top surface of the first insulating layer, and a second conductive layer over the first EL layer and the second insulating layer.

In the above structure, the display apparatus preferably includes a first resin layer over the second insulating layer. The second insulating layer preferably includes a first region sandwiched between the side surface of the first EL layer and the first resin layer, and a second region sandwiched between the top surface of the first insulating layer and the first resin layer. The second conductive layer is preferably in contact with a top surface of the first EL layer and a top surface of the first resin layer.

In the above structure, the display apparatus preferably includes a first resin layer and a first layer. The first layer preferably contains a material with a high electron-injection property. The first resin layer is provided over the second insulating layer. The second insulating layer preferably includes a first region between a side surface of the first EL layer and the first resin layer, and a second region between a top surface of the first insulating layer and the first resin layer. The first layer is preferably in contact with a top surface of the first EL layer and a top surface of the first resin layer. The second conductive layer is preferably in contact with a top surface of the first layer.

One embodiment of the present invention is a display apparatus which includes a first light-emitting element, a second light-emitting element arranged to be adjacent to the first light-emitting element, a first insulating layer, and a second insulating layer. The first light-emitting element includes a first conductive layer provided in a first opening of the first insulating layer, a first EL layer over the first conductive layer and the first insulating layer, and a common electrode over the first EL layer. The second light-emitting element includes a second conductive layer provided in a second opening of the first insulating layer, a second EL layer over the second conductive layer and the first insulating layer, and the common electrode over the second EL layer. The second insulating layer is in contact with a side surface of the first EL layer, a side surface of the second EL layer, and a top surface of the first insulating layer. The common electrode is provided over the second insulating layer and includes a third region overlapping with the second insulating layer.

In the above structure, the display apparatus preferably includes a first resin layer over the second insulating layer. The first insulating layer is preferably provided in a fourth region between the first light-emitting element and the second light-emitting element. The common electrode is preferably in contact with a top surface of the first EL layer, a top surface of the second EL layer, and a top surface of the first resin layer.

In the above structure, the display apparatus preferably includes a first resin layer over the second insulating layer. The first insulating layer is provided in a fourth region between the first EL layer and the second EL layer. The common electrode is preferably in contact with a top surface of the first EL layer, a top surface of the second EL layer, and a top surface of the first resin layer.

In the above structure, the display apparatus preferably includes a first resin layer and a common layer. The common layer preferably contains a material with a high electron-injection property. The first resin layer is preferably provided in a fourth region between the first light-emitting element and the second light-emitting element. The common layer is preferably in contact with a top surface of the first EL layer, a top surface of the second EL layer, and a top surface of the first resin layer. The common electrode is preferably in contact with a top surface of the common layer.

In the above structure, the display apparatus preferably includes a first resin layer and a common layer. The common layer preferably contains a material with a high electron-injection property. The first resin layer is preferably provided in a fourth region between the first EL layer and the second EL layer. The common layer is preferably in contact with a top surface of the first EL layer, a top surface of the second EL layer, and the top surface of the first resin layer. The common electrode is preferably in contact with a top surface of the common layer.

### Effect of the Invention

According to one embodiment of the present invention, a display apparatus with extremely high resolution can be provided. Alternatively, a display apparatus which can achieve high color reproducibility can be provided. Alternatively, a high-luminance display apparatus can be provided. Alternatively, a highly reliable display apparatus can be provided. Alternatively, a method for manufacturing the above-described display apparatus can be provided.

Note that the description of these effects does not preclude the existence of other effects. Note that one embodiment of the present invention does not need to have all of these effects. Note that effects other than these can be derived from the description of the specification, the drawings, the claims, and the like.

### BRIEF DESCRIPTION OF THE DRAWINGS

FIG. 1A to FIG. 1C are diagrams illustrating structure examples of a display apparatus.

FIG. 2A to FIG. 2C are diagrams illustrating structure examples of a display apparatus.

FIG. 3A and FIG. 3B are diagrams illustrating structure examples of a display apparatus.

FIG. 4A to FIG. 4D are diagrams illustrating an example of a fabricating method of a display apparatus.

FIG. 5A to FIG. 5D are diagrams illustrating an example of a fabricating method of a display apparatus.

FIG. 6 is a diagram illustrating a structure example of a display apparatus.

FIG. 7A to FIG. 7E are diagrams illustrating an example of a fabricating method of a display apparatus.

FIG. 8A to FIG. 8F are top views illustrating examples of a pixel.

FIG. 9A to FIG. 9H are top views illustrating examples of a pixel.

FIG. 10A to FIG. 10J are top views illustrating examples of a pixel.

FIG. 11A to FIG. 11D are top views illustrating examples of a pixel. FIG. 11E to FIG. 11G are cross-sectional views illustrating examples of a display panel.

FIG. 12A and FIG. 12B are perspective views illustrating an example of a display panel.

FIG. 13A and FIG. 13B are cross-sectional views illustrating examples of a display panel.

FIG. 14 is a cross-sectional view illustrating an example of a display panel.

FIG. 15 is a cross-sectional view illustrating an example of a display panel.

FIG. 16 is a cross-sectional view illustrating an example of a display panel.

FIG. 17 is a cross-sectional view illustrating an example of a display panel.

FIG. 18 is a cross-sectional view illustrating an example of a display panel.

FIG. 19A is a block diagram illustrating an example of a display panel. FIG. 19B to FIG. 19D are diagrams illustrating examples of a pixel circuit.

FIG. 20A to FIG. 20D are diagrams illustrating examples of transistors.

FIG. 21A to FIG. 21F are diagrams illustrating structure examples of a light-emitting device.

FIG. 22A to FIG. 22D are diagrams illustrating examples of electronic devices.

FIG. 23A to FIG. 23F are diagrams illustrating examples of electronic devices.

FIG. 24A to FIG. 24G are diagrams illustrating examples of electronic devices.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the invention described below, the same reference numerals are commonly used for the same portions or portions having similar functions in different drawings, and a repeated description thereof is omitted. Furthermore, the same hatch pattern is used for the portions having similar functions, and the portions are not especially denoted by reference numerals in some cases.

Note that in each drawing described in this specification, the size, the layer thickness, or the region of each component is exaggerated for clarity in some cases. Therefore, they are not limited to the illustrated scale.

Note that in this specification and the like, ordinal numbers such as “first” and “second” are used in order to avoid confusion among components and do not limit the number.

Note that the expressions indicating directions such as “over” and “under” are basically used to correspond to the directions of drawings. However, in some cases, the direction indicating “over” or “under” in the specification does not correspond to the direction in the drawings for the purpose of description simplicity or the like. For example, when a stacking order (or formation order) of a stacked body or the like is described, even in the case where a surface on which the stacked body is provided (e.g., a formation surface, a support surface, an adhesion surface, or a planar surface) is positioned above the stacked body in the drawings, the direction and the opposite direction are expressed using “under” and “over”, respectively, in some cases.

In addition, in this specification and the like, the term “film” and the term “layer” can be interchanged with each other. For example, in some cases, the term “conductive layer” and the term “insulating layer” can be interchanged with the term “conductive film” and the term “insulating film”, respectively.

Note that in this specification, an EL layer means a layer containing at least a light-emitting substance (also referred to as a light-emitting layer) or a stacked body including the light-emitting layer provided between a pair of electrodes of a light-emitting element. A light-emitting element in one embodiment of the present invention includes a pixel electrode, an EL layer over the pixel electrode, and a common electrode over the EL layer. The pixel electrode functions as a lower electrode and the common electrode functions as an upper electrode; and the pixel electrode and the common electrode are provided across a plurality of light-emitting elements. A common layer may be provided between the EL layer and the common electrode. The common layer is provided across a plurality of light-emitting elements.

In this specification and the like, a display panel that is one embodiment of a display apparatus has a function of displaying (outputting) an image or the like on (to) a display surface. Therefore, the display panel is one embodiment of an output device.

In this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

In this specification and the like, a device fabricated using a metal mask or an FMM (fine metal mask) is sometimes referred to as a device having an MM (metal mask) structure. In addition, in this specification and the like, a device fabricated without using a metal mask or an FMM is sometimes referred to as a device having an MML (metal maskless) structure.

Note that in this specification and the like, a structure in which light-emitting layers in light-emitting elements of different colors (also referred to as light-emitting devices, and the different colors here are blue (B), green (G), and red (R)) are separately formed or separately patterned is sometimes referred to as an SBS (Side By Side) structure. The SBS structure can optimize materials and structures of light-emitting elements and thus increases the degree of freedom in selecting materials and structures, so that the luminance and the reliability can be easily improved. In this specification and the like, a light-emitting element capable of emitting white light may be referred to as a white-light-emitting element. Note that a white-light-emitting element that is combined with coloring layers (e.g., color filters) can be a light-emitting element for full-color display.

Light-emitting elements can be roughly classified into a single structure and a tandem structure. A device having a single structure includes one light-emitting unit between a pair of electrodes, and the light-emitting unit preferably includes one or more light-emitting layers. To obtain white light emission with a single structure, two light-emitting layers are selected so that emission colors of the light-emitting layers have a relationship of complementary colors. For example, when an emission color of a first light-emitting layer and an emission color of a second light-emitting layer are complementary colors, the light-emitting element can be configured to emit white light as a whole. To obtain white light emission by using three or more light-emitting layers, the light-emitting device is configured to emit white light as a whole by combining emission colors of the three or more light-emitting layers.

An element having a tandem structure includes two or more light-emitting units between a pair of electrodes, and each light-emitting unit preferably includes one or more light-emitting layers. When light-emitting layers that emit light of the same color are used in each light-emitting unit, luminance per predetermined current can be increased, and the light-emitting element with a tandem structure can have higher reliability than that with a single structure. To obtain white light emission with a tandem structure, a structure in which white light emission can be obtained by combining light from light-emitting layers of a plurality of light-emitting units is employed. Note that a combination of emission colors for obtaining white light emission is similar to that in the case of a single structure. Note that in the device having a tandem structure, an intermediate layer such as a charge-generation layer is suitably provided between the plurality of light-emitting units.

When the above-described white-light-emitting element (the single structure or the tandem structure) and a light-emitting element having a SBS structure are compared, the light-emitting element having a SBS structure consumes lower power than the white-light-emitting element. To reduce power consumption, the light-emitting element having an SBS structure is suitably used. By contrast, the white light-emitting element is suitable in terms of lower manufacturing cost or higher manufacturing yield because the manufacturing process of the white light-emitting element is simpler than that of the light-emitting element having an SBS structure.

### Embodiment 1

In this embodiment, a display apparatus of one embodiment of the present invention and a fabricating method of the display apparatus are described.

The display apparatus of one embodiment of the present invention includes light-emitting elements (also referred to as light-emitting devices). Each of the light-emitting element includes a pair of electrodes, and an EL layer or part of the EL layer therebetween. The EL layer includes a light-emitting layer (also referred to as a layer containing a light-emitting compound). As the light-emitting element, an electroluminescent element such as an organic EL element or an inorganic EL element is preferably used. Alternatively, a light-emitting diode (LED) may be used.

The display apparatus preferably includes two or more light-emitting elements emitting light of different colors. The light-emitting elements emitting different colors include respective EL layers containing different materials. For example, three kinds of light-emitting elements emitting light of red (R), green (G), and blue (B) are included, whereby a full-color display apparatus can be achieved.

As the EL element, an OLED (Organic Light Emitting Diode), a QLED (Quantum-dot Light Emitting Diode), or the like can be used. Examples of the light-emitting compound (also referred to as a light-emitting substance) contained in the EL element include a substance that emits fluorescent light (a fluorescent material), a substance that emits phosphorescent light (a phosphorescent material), an inorganic compound (e.g., a quantum dot material), and a substance that exhibits thermally activated delayed fluorescence (a thermally activated delayed fluorescence (TADF) material). An LED such as a micro LED can also be used as the light-emitting element.

As the light-emitting substance, a substance whose emission color is blue, violet, bluish violet, green, yellowish green, yellow, orange, red, or the like is appropriately used. A substance that emits near-infrared light may be used.

The light-emitting layer may contain one or more kinds of compounds (a host material and an assist material) in addition to a light-emitting substance (a guest material). As the host material and the assist material, one or more kinds of substances whose energy gap is larger than the energy gap of the light-emitting substance (the guest material) can be selected and used. As the host material and the assist material, compounds that form an exciplex are preferably used in combination. In order to form an exciplex efficiently, it is particularly preferable to combine a compound that easily accepts holes (a hole-transport material) and a compound that easily accepts electrons (an electron-transport material).

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength is to be overlapped with the wavelength of the lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

Either a low molecular compound or a high molecular compound can be used for the light-emitting element, and an inorganic compound (e.g., a quantum dot material) may be contained.

In one embodiment of the present invention, a lower electrode of the light-emitting element or at least part of a conductive layer lower electrode functioning as a pixel electrode of the light-emitting element is formed to be embedded in an opening portions in the insulating layer, whereby unevenness on a surface where an EL layer is formed can be reduced

In the case where unevenness on the surface where the EL layer is formed is large, for example, the thickness of the EL layer is reduced and the upper electrode and the lower electrode may be short-circuited.

By reducing the unevenness on the surface where the EL layer is formed, the yield of the light-emitting element can be improved. In addition, the display quality of the display apparatus can be increased.

In the case of fabricating a display panel including a plurality of light-emitting elements emitting light of different colors, the light-emitting layers emitting light of different colors each need to be formed into an island shape.

For example, an island-shaped light-emitting layer can be deposited by a vacuum evaporation method using a metal mask (also referred to as a shadow mask). However, this method causes a deviation from the designed shape and position of an island-shaped light-emitting layer due to various influences such as the low accuracy of the metal mask, the positional deviation between the metal mask and a substrate, a warp of the metal mask, and the vapor-scattering-induced expansion of outline of the deposited film; accordingly, it is difficult to achieve high resolution and a high aperture ratio of the display apparatus. In addition, the outline of the layer may blur during vapor deposition, whereby the thickness of an end portion may be reduced. That is, the thickness of the island-shaped light-emitting layer may vary from area to area. In the case of fabricating a display panel with a large size, high definition, or high resolution, the manufacturing yield might be reduced because of low dimensional accuracy of the metal mask and deformation due to heat or the like.

In a method of fabricating a display panel of one embodiment of the present invention, a first layer (also referred to as an EL layer or part of an EL layer) including a light-emitting layer emitting light of a first color is formed over the entire surface, and then a first sacrificial layer is formed over the first layer. Then, a first resist mask is formed over the first sacrificial layer and the first layer and the first sacrificial layer are processed using the first resist mask, so that the first layer is formed into an island shape. Next, in a manner similar to that for the first layer, a second layer (also referred to as an EL layer or part of an EL layer) including a light-emitting layer emitting light of a second color is formed into an island shape using a second sacrificial layer and a second resist mask.

Note that in the case where the above light-emitting layer is processed into an island shape, a structure is possible in which pattern is formed so as to overlap with the light-emitting layer and is processed using a photolithography method. In that case, damage to the light-emitting layer (e.g., processing damage) might significantly degrade the reliability. In view of the above, in the fabrication of the display panel of one embodiment of the present invention, a sacrificial layer or the like is preferably formed over a layer above the light-emitting layer (e.g., a carrier-transport layer or a carrier-injection layer, specifically, an electron-transport layer or an electron-injection layer), followed by the processing of the light-emitting layer into an island shape. Such a method provides a highly reliable display panel.

As described above, the island shaped EL layers fabricated in the method of fabricating a display panel of one embodiment of the present invention are not formed by using a metal mask having a fine pattern but formed by processing an EL layer deposited over the entire surface. Accordingly, a high-resolution display panel or a display panel with a high aperture ratio, each of which has been difficult to achieve, can be obtained. Moreover, EL layers can be formed separately for the respective colors, enabling the display panel to perform extremely clear display with high contrast and high display quality. Moreover, providing a sacrificial layer over the EL layer can reduce damage to the EL layer in the fabricating process of the display panel, resulting in an increase in reliability of the light-emitting element.

It is difficult to set the distance between adjacent light-emitting elements to be less than 10 μm with a formation method using a metal mask, for example; however, with the above method, the distance can be decreased to less than 10 μm, less than or equal to 5 μm, less than or equal to 3 μm, less than or equal to 2 μm, or less than or equal to 1 μm. Furthermore, for example, with the use of a light exposure tool for LSI, the interval of adjacent light-emitting elements can be reduced to be less than or equal to 500 nm, less than or equal to 200 nm, less than or equal to 100 nm, or even less than or equal to 50 nm. Accordingly, the area of a non-light-emitting region that may exist between two light-emitting elements can be significantly reduced, and the aperture ratio can be close to 100%. For example, the aperture ratio higher than or equal to 50%, higher than or equal to 60%, higher than or equal to 70%, higher than or equal to 80%, or higher than or equal to 90% and lower than 100% can be achieved.

In addition, a pattern of the EL layer itself can be made much smaller than that in the case of using a metal mask. For example, in the case of using a metal mask for forming EL layers separately, a variation in the thickness of the pattern occurs between the center and the edge of the pattern, which causes a reduction in an effective area that can be used as a light-emitting region with respect to the entire pattern area. In contrast, in the above fabricating method, a film deposited to have a uniform thickness is processed, so that island-shaped EL layers can be formed to have a uniform thickness. Accordingly, even in a fine pattern, almost the whole area can be used as a light-emitting region. Consequently, a display panel having both high resolution and a high aperture ratio can be fabricated.

In addition, in a method for fabricating a display panel of one embodiment of the present invention, it is preferable that a layer including a light-emitting layer (that can be referred to as an EL layer or part of an EL layer) be formed over the entire surface, and then a sacrificial layer be formed over the EL layer. Next, it is preferable that a resist mask be formed over the sacrificial layer, and the EL layer and the sacrificial layer be processed using the resist mask, whereby an island-shaped EL layer be formed.

Moreover, providing a sacrificial layer over the EL layer can reduce damage to the EL layer in the fabricating process of the display panel, resulting in an increase in reliability of the light-emitting element.

Here, each of the first layer and the second layer includes at least a light-emitting layer and preferably consists of a plurality of layers. Specifically, each of the first layer and the second layer preferably includes one or more layers over the light-emitting layer. A layer included between the light-emitting layer and the sacrificial layer can inhibit the light-emitting layer from being exposed on the outermost surface during the fabrication process of the display panel and can reduce damage to the light-emitting layer. As a result, the reliability of the light-emitting element can be increased. Thus, the first layer and the second layer each preferably include the light-emitting layer and a carrier-transport layer (an electron-transport layer or a hole-transport layer) over the light-emitting layer.

Note that it is not necessary to form all layers included in EL layers separately between light-emitting elements that emit different colors, and some layers of the EL layers can be formed in the same step. Examples of the layers in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In the method of fabricating a display panel of one embodiment of the present invention, after some layers included in the EL layer are formed into an island shape separately for the respective colors, the sacrificial layer is removed at least partly, and then the other layers included in the EL layers and a common electrode (also referred to as an upper electrode) are formed (as a single film) so as to be shared by the light-emitting elements of different colors. For example, a carrier-injection layer and the common electrode can be formed so as to be shared by the light-emitting elements of different colors.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that the above-described carrier-injection layer, carrier-transport layer, and carrier-blocking layer cannot be distinguished from each other by the cross-sectional shape or properties in some cases. Furthermore, one layer may have two or three functions of the carrier-injection layer, the carrier-transport layer, and the carrier-blocking layer in some cases.

Meanwhile, the carrier-injection layer is often a layer having relatively high conductivity in the EL layer. Therefore, when the carrier-injection layer is in contact with a side surface of any layer of the EL layers formed into an island shape or a side surface of the pixel electrode, the light-emitting element might be short-circuited. Note that also in the case where the carrier-injection layer is formed into an island shape and the common electrode is formed to be shared by the light-emitting elements of the different colors, the light-emitting element might be short-circuited when the common electrode is in contact with the side surface of the EL layer or the side surface of the pixel electrode.

In view of the above, the display panel of one embodiment of the present invention includes an insulating layer that covers at least a side surface of an island-shaped light-emitting layer. Note that the side surface of the island-shaped light-emitting layer here refers to the plane that is not parallel to the substrate (or the surface where the light-emitting layer is formed) among the interfaces between the island-shaped light-emitting layer and other layers. The side surface is not necessarily one of a flat plane and a curved plane in an exactly mathematical perspective.

This can inhibit at least some layers of the island-shaped EL layers and the pixel electrodes from being in contact with the carrier-injection layer or the common electrode. Thus, a short circuit in the light-emitting element can be inhibited, leading to an increase in the reliability of the light-emitting element.

In addition, the insulating layer preferably has a function of a barrier insulating layer against at least one of water and oxygen. Alternatively, the insulating layer preferably has a function of inhibiting the diffusion of at least one of water and oxygen. Alternatively, the insulating layer preferably has a function of capturing or fixing (also referred to as gettering) at least one of water and oxygen.

Note that in this specification and the like, a barrier insulating layer refers to an insulating layer having a barrier property. A barrier property in this specification and the like refers to a function of inhibiting diffusion of a particular substance (also referred to as having low permeability). Alternatively, a barrier property refers to a function of capturing or fixing (also referred to as gettering) a particular substance.

When the insulating layer used has a function of the barrier insulating layer or a gettering function, entry of impurities (typically, at least one of water and oxygen) that would diffuse into the light-emitting elements from the outside can be suppressed. With this structure, a highly reliable light-emitting element and a highly reliable display panel can be provided.

The display panel of one embodiment of the present invention includes a pixel electrode functioning as an anode; an island-shaped hole-injection layer, an island-shaped hole-transport layer, an island-shaped light-emitting layer, and an island-shaped electron-transport layer that are provided in this order over the pixel electrode; an insulating layer provided to cover side surfaces of the hole-injection layer, the hole-transport layer, the light-emitting layer, and the electron-transport layer; an electron-injection layer provided over the electron-transport layer; and a common electrode that is provided over the electron-injection layer and functions as a cathode.

Alternatively, the display panel of one embodiment of the present invention includes a pixel electrode functioning as a cathode; an island-shaped electron-injection layer, an island-shaped electron-transport layer, an island-shaped light-emitting layer, and an island-shaped hole-transport layer that are provided in this order over the pixel electrode; an insulating layer provided to cover side surfaces of the electron-injection layer, the electron-transport layer, the light-emitting layer, and the hole-transport layer; a hole-injection layer provided over the hole-transport layer; and a common electrode that is provided over the hole-injection layer and functions as an anode.

The hole-injection layer, the electron-injection layer or the like often has relatively high conductivity in the EL layer. Since the side surfaces of these layers are covered with the insulating layer in the display panel of one embodiment of the present invention, these layers can be inhibited from being in contact with the common electrode or the like. Thus, a short circuit in the light-emitting element can be inhibited, leading to an increase in the reliability of the light-emitting element.

The insulating layer that covers the side surface of the island-shaped EL layer may have a single-layer structure or a stacked-layer structure.

For example, an insulating layer having a single-layer structure using an inorganic material can be used for a protective insulating layer for the EL layer. This leads to higher reliability of the display panel.

In the case where the insulating layer having a stacked-layer structure is used, the first layer of the insulating layer is preferably formed using an inorganic insulating material because it is formed in contact with the EL layer. In particular, the first insulating layer is preferably formed by an atomic layer deposition (ALD) method, by which damage due to deposition is small. Alternatively, an inorganic insulating layer is preferably formed by a sputtering method, a chemical vapor deposition (CVD) method, or a plasma-enhanced chemical vapor deposition (PECVD) method, which have higher deposition speed than an ALD method. In that case, a highly reliable display panel can be fabricated with high productivity. The second layer of the insulating layer is preferably formed using an organic material to fill a depressed portion formed by the first layer of the insulating layer.

For example, an aluminum oxide film formed by an ALD method can be used as the first layer of the insulating layer, and an organic resin film can be used as the second layer of the insulating layer.

In the case where the side surface of the EL layer and the organic resin film are in direct contact with each other, the EL layer might be damaged by an organic solvent or the like that might be contained in the organic resin film. When an inorganic insulating film such as an aluminum oxide film formed by an ALD method is used as the first layer of the insulating layer, a structure can be employed in which the organic resin film and the side surface of the EL layer are not in direct contact with each other. Thus, the EL layer can be inhibited from being dissolved by the organic solvent, for example.

In the display panel of one embodiment of the present invention, an insulating layer covering end portions of the pixel electrodes does not need to be provided between the pixel electrodes and the EL layers, so that the distance between adjacent light-emitting electrode can be extremely narrowed. As a result, higher resolution or higher definition of the display panel can be achieved. In addition, a mask for forming the insulating layer is not needed, reducing the manufacturing costs of the display panel.

Furthermore, light emitted from the EL layer can be extracted efficiently with a structure where an insulating layer covering end portions of the pixel electrodes is not provided between the pixel electrode and the EL layer, i.e., a structure where an insulating layer is not provided between the pixel electrode and the EL layer. Therefore, the display panel of one embodiment of the present invention can significantly reduce the viewing angle dependence. A reduction in the viewing angle dependence leads to an increase in visibility of an image on the display panel. For example, in the display panel of one embodiment of the present invention, the viewing angle (the maximum angle with a certain contrast ratio maintained when a screen is seen from an oblique direction) can be greater than or equal to 100° and less than 180°, preferably greater than or equal to 150° and less than or equal to 170°. Note that the above viewing angle refers to that in both the vertical direction and the horizontal direction.

More specific structure examples and a fabrication method example will be described below with reference to drawings.

### Structure Example 1

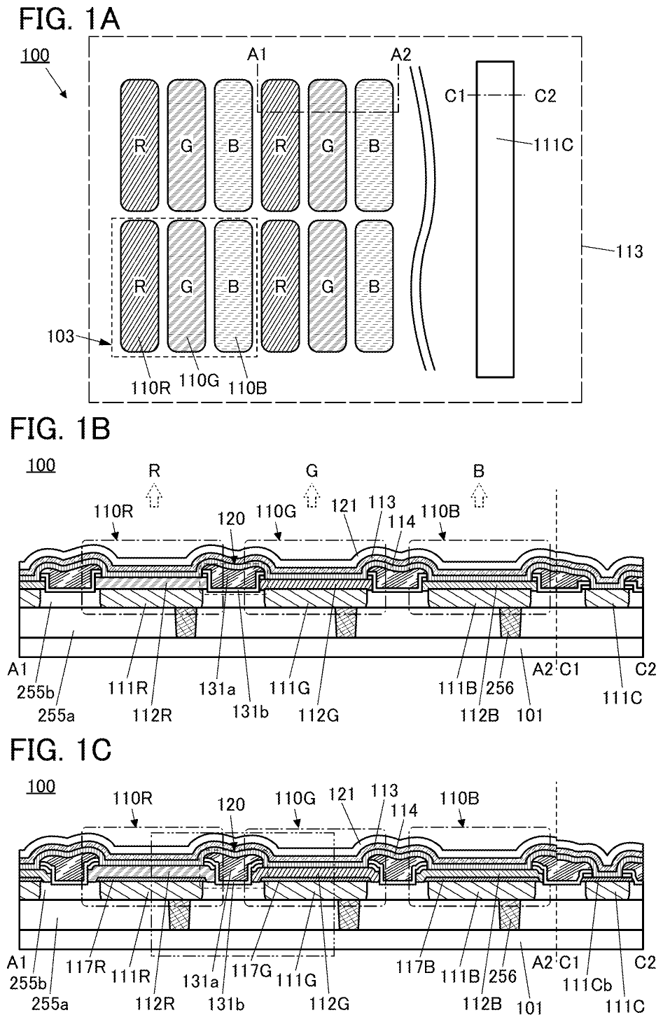

FIG. 1A illustrates a schematic top view of a display apparatus 100. The display apparatus 100 includes a plurality of pixels 103 arranged in a matrix form, and each pixel 103 includes a light-emitting element 110R emitting red light, a light-emitting element 110G emitting green light, and a light-emitting element 110B emitting blue right. In FIG. 1A, light-emitting regions of the light-emitting elements are denoted by R, G, and B to easily differentiate the light-emitting elements.

Note that in FIG. 1A and the like, the light-emitting elements which emit three colors, red (R), green (G), and blue (B), are shown and are denoted by R, G, and B, respectively as an example in order to easily differentiate the light-emitting elements; however, the light-emitting element 110R, the light-emitting element 110G, and the light-emitting element 110B are not limited to the light-emitting elements emit three colors, red (R), green (G), and blue (B). For example, each light-emitting element emits one color chosen from blue, violet, blue violet, green, yellow green, yellow, orange, or red. Alternatively, three light-emitting elements may be the light-emitting elements emitting three colors chosen from blue, violet, blue violet, green, yellow green, yellow, orange, or red; besides, two or more of three light-emitting elements may emit the same color.

The light-emitting elements 110R, the light-emitting elements 110G, and the light-emitting elements 110B are arranged in a matrix. FIG. 1A illustrates what is called a stripe arrangement, in which light-emitting elements of the same color are arranged in one direction. Note that the arrangement method of the light-emitting elements is not limited thereto; another arrangement method such as S stripe arrangement, delta arrangement, Bayer arrangement, or zigzag arrangement may be used, or PenTile arrangement, diamond arrangement, or the like may be used.

As the light-emitting element 110R, the light-emitting element 110G, and the light-emitting element 110B, an EL element such as OLED or QLED is preferably used. Examples of a light-emitting substance contained in the EL element include a substance exhibiting fluorescence (a fluorescent material), a substance exhibiting phosphorescence (a phosphorescent material), an inorganic compound (such as a quantum dot material), and a substance exhibiting thermally activated delayed fluorescence (a thermally activated delayed fluorescence (TADF) material).

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

FIG. 1A also illustrates a connection electrode 111C that is electrically connected to a common electrode 113 functioning as an upper electrode of a light-emitting element 110. The connection electrode 111C is supplied with a potential (e.g., an anode potential or a cathode potential) that is to be supplied to the common electrode 113. The connection electrode 111C is provided outside a display region where the light-emitting elements 110R and the like are arranged. In FIG. 1A, the common electrode 113 is denoted by a dashed line.

The connection electrode 111C can be provided along the outer periphery of the display region. For example, the connection electrode 111C may be provided along one side of the outer periphery of the display region or two or more sides of the outer periphery of the display region. That is, in the case where the display region has a rectangular top surface shape, a top surface shape of the connection electrode 111C can have a band shape, an L shape, a U shape (a square bracket shape), a quadrangular shape, or the like.

FIG. 1B illustrates a schematic cross-sectional view taken along a dashed-dotted line A1-A2 and a dashed-dotted line C1-C2 in FIG. 1A. FIG. 1B illustrates a schematic cross-sectional view of the light-emitting element 110R, the light-emitting element 110G, and the connection electrode 111C.

Note that hereafter, in the description common to the light-emitting element 110R, the light-emitting element 110G, and the light-emitting element 110B, the alphabets are omitted from the reference numerals and the term “light-emitting element 110” is used in some cases. Similarly, an EL layer 112R, an EL layer 112G, and an EL layer 112B described later are also described using the term “EL layer 112” in some cases. The EL layer 112R is included in the light-emitting element 110R. Similarly, the EL layer 112G is included in the light-emitting element 110G, and the EL layer 112B is included in the light-emitting element 110B. Similarly, a conductive layer 111R, a conductive layer 111G, and a conductive layer 111B, which are described later, are described using the term “conductive layer 111” in some cases. The conductive layer 111R is included in the light-emitting element 110R. Similarly, the conductive layer 111G is included in the light-emitting element 110G, and the conductive layer 111B is included in the light-emitting element 110B.

The light-emitting element 110 includes the conductive layer 111 functioning as a lower electrode of the light-emitting element 110, the EL layer 112, and the common electrode 113 functioning as an upper electrode of the light-emitting element 110.

In the cross section of the display apparatus 100 illustrated in FIG. 1B, the common electrode 113 is shared by the light-emitting element 110R, the light-emitting element 110G, and the light-emitting element 110B. The common electrode 113 functions as, for example, an electrode to which a common potential is applied. The common electrode 113 may also be referred to as a common electrode. It is preferable to provide the common electrode 113 because the fabrication steps of the light-emitting element 110 can be reduced. The common electrode 113 has a transmissive property and a reflective property with respect to visible light.

A potential for controlling the amount of light emitted from the light-emitting element 110 is independently applied to the conductive layer 111 provided in the light-emitting elements 110. The conductive layer 111 functions as a pixel electrode. The conductive layer 111 has a reflective property with respect to visible light.

A conductive film having a property of transmitting visible light is used for either the pixel electrodes or the common electrode 113, and a conductive film having a reflective property is used for the other.

The light-emitting element has a top-emission structure, a bottom-emission structure, a dual-emission structure, or the like. A conductive film that transmits visible light is used as an electrode through which light is extracted. A conductive film that reflects visible light is preferably used as the electrode through which light is not extracted.

In one embodiment of the present invention, when the pixel electrodes are light-transmitting electrodes and the common electrode 113 is a reflective electrode, a bottom-emission display apparatus can be obtained; in contrast, when the pixel electrodes are reflective electrodes and the common electrode 113 is a light-transmitting electrode, a top-emission display apparatus can be obtained. Note that when both the pixel electrodes and the common electrode 113 have light-transmitting properties, a dual-emission display apparatus can be obtained.

A protective layer 121 is provided over the common electrode 113 to cover the light-emitting element 110R, the light-emitting element 110G, and the light-emitting element 110B. The protective layer 121 has a function of preventing diffusion of impurities such as water into the light-emitting elements from above. When both the pixel electrodes and the common electrode have light-transmitting properties, the light-emitting elements can transmit external light; thus, a display through which the background can be seen, that is, what is called a transparent display can be obtained.

The protective layer 121 can have, for example, a single-layer structure or a stacked-layer structure at least including an inorganic insulating film. Examples of the inorganic insulating film include an oxide film and a nitride film such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as an indium gallium oxide or an indium gallium zinc oxide may be used for the protective layer 121. As the protective layer 121, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 113. The inorganic film may further contain nitrogen.

When light emitted from the light-emitting element is extracted through the protective layer 121, the protective layer 121 preferably has a high visible-light-transmitting property. For example, ITO, IGZO, and aluminum oxide are preferable because they are inorganic materials having a high visible-light-transmitting property.

The protective layer 121 can have, for example, a stacked-layer structure of an aluminum oxide film and a silicon nitride film over the aluminum oxide film, a stacked-layer structure of an aluminum oxide film and an IGZO film over the aluminum oxide film, or the like. Such a stacked-layer structure can inhibit entry of impurities (e.g., water and oxygen) into the EL layers.

As the protective layer 121, a stacked-layer film of an inorganic insulating film and an organic insulating film can be used. For example, a structure where an organic insulating film is interposed between a pair of inorganic insulating films is preferable. Furthermore, the organic insulating film preferably functions as a planarization film. This enables the top surface of the organic insulating film to be flat, and accordingly coverage with the inorganic insulating film thereover is improved, leading to an improvement in barrier properties. Moreover, this structure is preferable because when a component (e.g., a color filter, an electrode of a touch sensor, a lens array, or the like) is provided above the protective layer 121, the flat top surface of the protective layer 121 allows the component to be less affected by an uneven shape caused by the lower components. As the organic insulating film used as a protective layer, a description of a resin layer 131a can be referred.

The protective layer 121 may have a stacked-layer structure of two layers which are formed by different film formation methods. Specifically, the first layer and the second layer of the protective layer 121 may be formed by an ALD method and a sputtering method, respectively.

There is no limitation on the conductivity of the protective layer 121. For the protective layer 121, at least one of an insulating film, a semiconductor film, and a conductive film can be used.

The protective layer 121 including an inorganic film can inhibit deterioration of the light-emitting elements by preventing oxidation of the common electrode 113 and inhibiting entry of impurities (e.g., water and oxygen) into the light-emitting elements, for example; thus, the reliability of the display panel can be improved.

In addition, a common layer 114 may be provided between the EL layer 112 and the common electrode 113. Like the common electrode 113, the common layer 114 is provided across a plurality of light-emitting elements. The common layer 114 is provided to cover the EL layer 112R, the EL layer 112G, and the EL layer 112B. The structure including the common layer 114 can simplify the fabricating process and thus can reduce the fabricating cost. The common layer 114 and the common electrode 113 can be successively formed without an etching step or the like performed between formations of the common layer 114 and the common electrode 113. Thus, the interface between the common layer 114 and the common electrode can be clean, and the light-emitting element can have favorable characteristics.

The common layer 114 is preferably in contact with one or more of top surfaces of the EL layer 112R, the EL layer 112G, and the EL layer 112B.

The common layer 114 preferably includes one or more of an electron-injection layer, an electron-transport layer, a hole-injection layer, and a hole-transport layer, for example. In the light-emitting element in which the pixel electrode serves as an anode and the common electrode serves as a cathode, a structure including the electron-injection layer or a structure including the electron-injection layer and the electron-transport layer can be used as the common layer 114.

The hole-injection layer is a layer injecting holes from an anode to the hole-transport layer, and a layer containing a material with a high hole-injection property. Examples of a material with a high hole-injection property include an aromatic amine compound and a composite material containing a hole-transport material and an acceptor material (electron-accepting material).

The hole-transport layer is a layer transporting holes, which are injected from the anode by the hole-injection layer, to the light-emitting layer. The hole-transport layer is a layer containing a hole-transport material. As the hole-transport material, a substance having a hole mobility greater than or equal to 10⁻⁶ cm²/Vs is preferable. Note that other substances can also be used materials as long as materials have a property of transporting more holes than electrons. As the hole-transport material, materials with a high hole-transport property, such as a π-electron rich heteroaromatic compound (e.g., a carbazole derivative, a thiophene derivative, and a furan derivative) and an aromatic amine (a compound having an aromatic amine skeleton), are preferable.

The electron-transport layer is a layer transporting electrons, which are injected from a cathode by the electron-injection layer, to the light-emitting layer. The electron-transport layer is a layer containing an electron-transport material. As the electron-transport material, a substance having an electron mobility greater than or equal to 1×10⁻⁶ cm²/Vs is preferable. Note that other substances can also be used as long as materials have a property of transporting more electrons than holes. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The electron-injection layer is a layer injecting electrons from the cathode to the electron-transport layer and a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used. Note that it is preferable that a material with a high electron-injection property be a material whose lowest unoccupied molecular orbital (LUMO) level value has a small difference from the work function value of a material used for the common electrode; for example, the difference of value is preferably lower than or equal to 0.5 eV.

As the electron-injection layer, an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOₓ), or cesium carbonate can be used, for example. In addition, the electron-injection layer may have a stacked-layer structure of two or more layers. In the stacked-layer structure, for example, lithium fluoride can be used for the first layer and ytterbium can be used for the second layer.

Alternatively, the electron-injection layer may be formed using an electron-transport material. For example, a compound having an unshared electron pair and an electron deficient heteroaromatic ring can be used for the electron-transport material. Specifically, a compound having at least one of a pyridine ring, a diazine ring (a pyrimidine ring, a pyrazine ring, and a pyridazine ring), and a triazine ring can be used.

Note that it is preferable that the lowest unoccupied molecular orbital (LUMO) of an organic compound having an unshared electron pair be higher than or equal to −3.6 eV and lower than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used for the organic compound having an unshared electron pair. Note that NBPhen has a higher glass transition temperature (Tg) than BPhen and thus has high heat resistance.

For the charge-generation layer, for example, a material that can be used for the electron-injection layer, such as lithium, can be suitably used. For the charge-generation layer, for example, a material that can be used for the hole-injection layer can be suitably used. For the charge-generation layer, a layer containing a hole-transport material and an acceptor material (electron-accepting material) can be used. For the charge-generation layer, a layer containing an electron-transport material and a donor material can be used. Forming such a charge-generation layer can inhibit an increase in the driving voltage that would be caused by stacking light-emitting units.

The EL layer 112 contains a light-emitting compound. The EL layer 112 includes at least a light-emitting layer included in the light-emitting element 110.

As the light-emitting element 110, it is possible to use an electroluminescent element having a function of emitting light in accordance with current flowing into the EL layer 112 when a potential difference is applied between the conductive layer 111 and the common electrode 113. In particular, an organic EL element using a light-emitting organic compound is preferably used for the EL layer 112.

The EL layer 112 includes at least a light-emitting layer (a layer containing a light-emitting organic compound). The light-emitting layer may contain one or more kinds of compounds (a host material and an assist material) in addition to a light-emitting substance (a guest material). As the host material and the assist material, one or more kinds of substances whose energy gap is larger than the energy gap of the light-emitting substance (the guest material) can be selected and used. As the host material and the assist material, compounds that form an exciplex are preferably used in combination. In order to form an exciplex efficiently, it is particularly preferable to combine a compound that easily accepts holes (a hole-transport material) and a compound that easily accepts electrons (an electron-transport material). Alternatively, as one or more kinds of organic compounds, a bipolar material or a TADF material may be used.

Either a low molecular compound or a high molecular compound can be used for the light-emitting element, and an inorganic compound (e.g., a quantum dot material) may be contained.

In addition to the light-emitting layer, the EL layer 112 may further include a layer containing a material with a high hole-injection property, a material with a high hole-transport property, a hole-blocking material, a material with a high electron-transport property, a material with a high electron-injection property, a material with a bipolar property (a material with a high electron-transport property and a high hole-transport property), or the like.

Either a low molecular compound or a high molecular compound can be used for the EL layer 112, and an inorganic compound may also be contained. The layers that constitute the EL layer 112 can each be formed by a method such as an evaporation method (including a vacuum evaporation method), a transfer method, a printing method, an inkjet method, or a coating method.

Note that the light-emitting layer and the layers containing a material with a high hole-injection property, a material with a high hole-transport property, a material with a high electron-transport property, a material with a high electron-injection property, a material with a bipolar property, and the like may each include an inorganic compound such as a quantum dot or a high molecular compound (an oligomer, a dendrimer, a polymer, or the like). For example, when used for the light-emitting layer, the quantum dots can function as a light-emitting material.

As the quantum dot material, a colloidal quantum dot material, an alloyed quantum dot material, a core-shell quantum dot material, a core quantum dot material, or the like can be used. The material containing elements belonging to Group 12 and Group 16, elements belonging to Group 13 and Group 15, or elements belonging to Group 14 and Group 16, may be used. Alternatively, a quantum dot material containing an element such as cadmium, selenium, zinc, sulfur, phosphorus, indium, tellurium, lead, gallium, arsenic, or aluminum may be used.

When a voltage higher than the threshold voltage of the light-emitting element 110 is applied between a cathode and an anode, holes are injected to the EL layer 112 from the anode side and electrons are injected to the EL layer 112 from the cathode side. The injected electrons and holes are recombined in the EL layer 112 and a light-emitting substance contained in the EL layer 112 emits light.

Here, the EL layer 112 used for the light-emitting element 110B is referred to as the EL layer 112B, the EL layer 112 used for the light-emitting element 110G is referred to as the EL layer 112G, and the EL layer 112 used for the light-emitting element 110R is referred to as the EL layer 112R. The EL layer 112B contains a light-emitting substance emitting B (blue) light. The EL layer 112G contains a light-emitting substance emitting G (green) light. The EL layer 112R contains a light-emitting substance emitting R (red) light. Such a structure in which light-emitting layers are separately formed or separately patterned for light-emitting elements may be referred to as an SBS structure.

The conductive layer 111 has a reflective property with respect to visible light.

The display apparatus 100 includes a substrate 101 including a semiconductor circuit and the light-emitting element 110 over the substrate 101. In the cross section illustrated in FIG. 1B, the display apparatus 100 includes an insulating layer 255a over the substrate 101, an insulating layer 255b over the insulating layer 255a, and the light-emitting element 110 over the insulating layer 255b.

A circuit board including a transistor, a wiring, and the like can be used as the substrate 101. Note that in the case where either a passive matrix method or a segment method can be employed, an insulating substrate such as a glass substrate can be used as the substrate 101. The substrate 101 is a substrate provided with a circuit for driving the light-emitting elements (also referred to as a pixel circuit) and a semiconductor circuit functioning as a driver circuit for driving the pixel circuit. More specific structure examples of the substrate 101 will be described later.

In the cross section of the display apparatus 100 illustrated in FIG. 1B, the substrate 101 and the conductive layer 111 of the light-emitting element 110 are electrically connected to each other through a plug 256. The plug 256 is formed to be embedded in an opening provided in the insulating layer 255a. The conductive layer 111 is formed to be embedded in an opening provided in the insulating layer 255b. The conductive layer 111 is provided over the plug 256. The conductive layer 111 and the plug 256 are electrically connected to each other. The conductive layer 111 is preferably in contact with the top surface of the plug 256.

In the display apparatus of one embodiment of the present invention, the conductive layer functioning as a lower electrode of the light-emitting element is formed to be embedded in the opening of the insulating layer, whereby the EL layer can be formed over a flat surface.

In the case where a conductive layer is formed over an insulating layer, unevenness is caused by the conductive layer. In such a case, the thickness of an EL layer is reduced in some cases when end portions of the conductive layer are covered.

When the thickness of the EL layer that coats the end portions of the conductive layer is thin, the upper electrode and the lower electrode of the light-emitting element may be short-circuited to decrease the yield of the display apparatus. Such a short circuit can be inhibited by providing an insulator covering the end portions of the conductive layer (referred to as a bank, a partition, a barrier, an embankment, or the like in some cases).

However, the distance between adjacent light-emitting elements becomes large when the insulator is provided between the adjacent light-emitting elements; thus, miniaturization might be difficult.

In the display apparatus of one embodiment of the present invention, the EL layer can be formed over the flat surface; thus, a structure in which an insulator covering end portions of the conductive layer is not included can be provided.

An etching residue may be deposited in a depressed portion generated by a step of the conductive layer. Such a residue might lead a failure such as a short circuit, resulting in the decrease in yield of the display apparatus. The use of the structure of the display apparatus of one embodiment of the present invention can inhibit a failure in processing the EL layer and processing the upper electrode in the fabricating process of the light-emitting element. Thus, the yield of the display apparatus can be increased.

The display apparatus of one embodiment of the present invention can be miniaturized with a high yield.

The EL layer 112 may be patterned into an island shape by film formation with use of a shadow mask such as a metal mask; however, it is particularly preferable to employ a processing method using no metal mask. Accordingly, an extremely fine pattern can be formed; thus, resolution and an aperture ratio can be improved as compared to the formation method using a metal mask. A typical example of such a processing method is a photolithography method. Alternatively, a formation method such as a nanoimprinting method, a sandblasting method, or a lift-off method can be used.

In a cross section of the display apparatus 100 illustrated in FIG. 1B, end portions of the EL layer 112 are positioned outward from end portions of the conductive layer 111. The end portions of the conductive layer 111 are covered with the end portions of the EL layer 112. The end portions of the EL layer 112 are positioned outward from the end portions of the conductive layer 111, whereby a short circuit between the conductive layer 111 and the common electrode 113 can be inhibited. In the cross section of the display apparatus 100 illustrated in FIG. 1B, end portions of the common electrode 113 are positioned outward from the end portions of the conductive layer 111.

A slit 120 is preferably provided between adjacent light-emitting elements. The slit 120 corresponds to a portion where the EL layer 112 positioned between adjacent light-emitting elements is etched. A bottom surface of the slit 120 includes, for example, a region where a top surface of the insulating layer 255b is exposed.

In the slit 120, an insulating layer 131b and the resin layer 131a are provided. The insulating layer 131b is provided along the sidewalls and bottom surface of the slit 120. There is a case where the insulating layer 131b is provided to fill the depressed portion because the insulating layer 131b is provided along the sidewalls and bottom surface of the slit 120. The insulating layer 131b preferably includes a region in contact with a top surface of the insulating layer 255b. In addition, the resin layer 131a is provided over the insulating layer 131b and has a function of filling a depressed portion positioned in the slit 120 and planarizing the top surface; the planarization for the depressed portion in the slit 120 by the resin layer 131a can improve the coverage of the common electrode 113, the common layer 114, and the protective layer 121. The common layer 114 is, for example, in contact with the top surface of the resin layer 131a. In addition, in the case where the display apparatus 100 does not include the common layer 114, the common electrode 113 is, for example, in contact with the top surface of the resin layer 131a.

The slit 120 can be formed at the same time as the formation of an opening portion for an external connection terminal such as the connection electrode 111C; thus, they can be formed without increasing the number of steps. Since the slit 120 includes the insulating layer 131b and the resin layer 131a, an effect of preventing a short circuit between the conductive layer 111 and the common electrode 113 is produced. The resin layer 131a has an effect of improving adhesion of the common layer 114. That is, providing the resin layer 131a improves adhesion of the common layer 114, so that film separation of the common layer 114 can be inhibited.

The insulating layer 131b is provided in contact with the side surface of the EL layer 112, thereby preventing the EL layer 112 and the resin layer 131a from being in contact with each other. In the case where the resin layer 131a is in contact with the EL layer 112, the EL layer 112 might be dissolved by an organic solvent or the like contained in the resin layer 131a. In view of this, the side surface of the EL layer 112 can be protected with the structure in which the insulating layer 131b is provided between the EL layer 112 and the resin layer 131a as described in this embodiment. Note that the slit 120 can have any structure that allows division of at least any one or more of a hole-injection layer, a hole-transport layer, an electron-blocking layer, a light-emitting layer, an active layer, a hole-blocking layer, an electron-transport layer, and an electron-injection layer.

In addition, the insulating layer 131b includes a region between the side surface of the EL layer 112 and the resin layer 131a, for example.

In addition, the insulating layer 131b includes a region between the top surface of the insulating layer 255b and the resin layer 131a, for example.

The insulating layer 131b can be an insulating layer containing an inorganic material. As the insulating layer 131b, an inorganic insulating film such as an oxide insulating film, a nitride insulating film, an oxynitride insulating film, or a nitride oxide insulating film can be used, for example. The insulating layer 131b may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the oxynitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, a metal oxide film such as an aluminum oxide film or a hafnium oxide film, or an inorganic insulating film such as a silicon oxide film, which is formed by an ALD method, is used for the insulating layer 131b, whereby the insulating layer 131b can have few pinholes and an excellent function of protecting the EL layer.

Note that in this specification and the like, oxynitride refers to a material that contains more oxygen than nitrogen in tis composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The insulating layer 131b can be formed by a sputtering method, a CVD method, a PLD method, an ALD method, or the like. The insulating layer 131b is preferably formed by an ALD method with favorable coverage.

An insulating layer containing an organic material can be suitably used for the resin layer 131a. For the resin layer 131a, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the resin layer 131a, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Moreover, the resin layer 131a can be formed using a photosensitive resin. A photoresist may be used for the photosensitive resin. As the photosensitive resin, a positive material or a negative material can be used.

The resin layer 131a may be formed using a colored material (e.g., a material containing a black pigment) to have a function of blocking stray light from adjacent pixels and inhibiting color mixture.

A reflective film (e.g., a metal film containing one or more selected from silver, palladium, copper, titanium, aluminum, and the like) may be provided between the insulating layer 131b and the resin layer 131a to have a function of reflecting light emitted from the light-emitting layer and increasing the light extraction efficiency.

Although the top surface of the resin layer 131a is preferably as flat as possible, its surface has a gently curved shape in some cases. FIG. 1B and the like illustrate an example in which the top surface of the resin layer 131a has a wave shape with a depressed portion and a projected portion; however, one embodiment of the present invention is not limited thereto. For example, the top surface of the resin layer 131a may be a convex surface, a concave surface, or a flat surface.

For a portion of the conductive layer 111 that is positioned on the EL layer 112 side, the above conductive film that reflects visible light is preferably used. For the conductive layer 111, for example, a metal material such as aluminum, gold, platinum, silver, nickel, tungsten, chromium, molybdenum, iron, cobalt, copper, or palladium or an alloy containing any of these metal materials can be used. Copper is preferably used because of its high reflectance with respect to visible light. Aluminum is preferable because an aluminum electrode is easily etched and thus is easily processed, and aluminum has high reflectance with respect to visible light and near-infrared light. Lanthanum, neodymium, germanium, or the like may be added to the above metal material or alloy. An alloy (an aluminum alloy) containing aluminum and titanium, nickel, or neodymium may be used. An alloy containing silver and copper, palladium, or magnesium may be used. An alloy containing silver and copper is preferable because of its high heat resistance.

The conductive layer 111 may have a structure in which a conductive metal oxide film is stacked over a conductive film that reflects visible light. With such a structure, oxidization and corrosion of the conductive film reflecting visible light can be inhibited. When a metal film or a metal oxide film is stacked in contact with an aluminum film or an aluminum alloy film, for example, oxidization can be inhibited. Examples of a material for the metal film or the metal oxide film include titanium and titanium oxide. Alternatively, the above conductive film that transmits visible light and a film containing a metal material may be stacked. For example, a stacked-layer film of silver and indium tin oxide or a stacked-layer film of an alloy of silver and magnesium and indium tin oxide can be used.

In addition, as illustrated in FIG. 1C, a conductive layer 117R can be provided between the conductive layer 111R and the EL layer 112R in the light-emitting element 110R, a conductive layer 117G can be provided between the conductive layer 111G and the EL layer 112G in the light-emitting element 110G, and a conductive layer 117B can be provided between the conductive layer 111B and the EL layer 112B in the light-emitting element 110B. Note that hereinafter, in the description common to the conductive layer 117R, the conductive layer 117G, and the conductive layer 117B, the alphabets added to the reference numerals are omitted and the term “conductive layer 117” is used in some cases. The conductive layer 117 has a function of transmitting visible light. The conductive layer 117 can function as the pixel electrode of the light-emitting element 110. The conductive layer 111 and the conductive layer 117 are collectively referred to as a pixel electrode in some cases. An end portion of the conductive layer 117 preferably has a tapered shape. This can improve the step coverage with the EL layer 112. Note that in this specification and the like, an end portion of an object having a tapered shape indicates that the end portion of the object has a cross-sectional shape in which the angle between a surface of the object and a surface on which the object is formed is greater than 0° and less than 90° in a region of the end portion, and the thickness continuously increases from the end portion.

The conductive layer 117 provided in each of the light-emitting elements 110 that are included in the display apparatus 100 illustrated in FIG. 1C is placed between the conductive layer 111 and the EL layer 112. The conductive layer 117 is positioned over the conductive layer 111. The conductive layer 117 includes a region positioned over the insulating layer 255b. The EL layer 112 is preferably provided to cover end portions of the conductive layer 117.

The conductive layer 117 can function as an optical adjustment layer.

The optical path length is set different among the light-emitting elements using a microcavity structure, whereby light of a specific wavelength can be intensified. This can achieve a display apparatus having an increased color purity.

In the case where the optical path length is set different by using a microcavity structure, the optical path length in each light-emitting element is, for example, equal to the sum of the thickness of the conductive layer 117 and the thickness of the layer provided under the light-emitting layer in EL layer 112.

In each of the light-emitting elements, the optical distance between the surface of the conductive layer 111 reflecting visible light and the common electrode 113 having a semi-transmissive property and a semi-reflective property with respect to visible light is preferably adjusted to be mλ/2 (m is a positive integer) or in the neighborhood, where λ is the wavelength of light whose intensity is desired to be increased.

For example, the thickness of the conductive layer 117 is set different among the light-emitting elements, whereby a microcavity structure can be obtained.

For example, the thickness of the EL layer 112 is set different among the light-emitting elements, whereby a microcavity structure can be obtained. For example, the EL layer 112R of the light-emitting element 110R emitting light whose wavelength is the longest can be made to have the largest thickness, and the EL layer 112B of the light-emitting element 110B emitting light whose wavelength is the shortest can be made to have the smallest thickness. Note that without limitation to this, the thicknesses of the EL layers can be adjusted in consideration of the wavelengths of light emitted by the light-emitting elements, the optical characteristics of the layers included in the light-emitting elements, the electrical characteristics of the light-emitting elements, and the like.

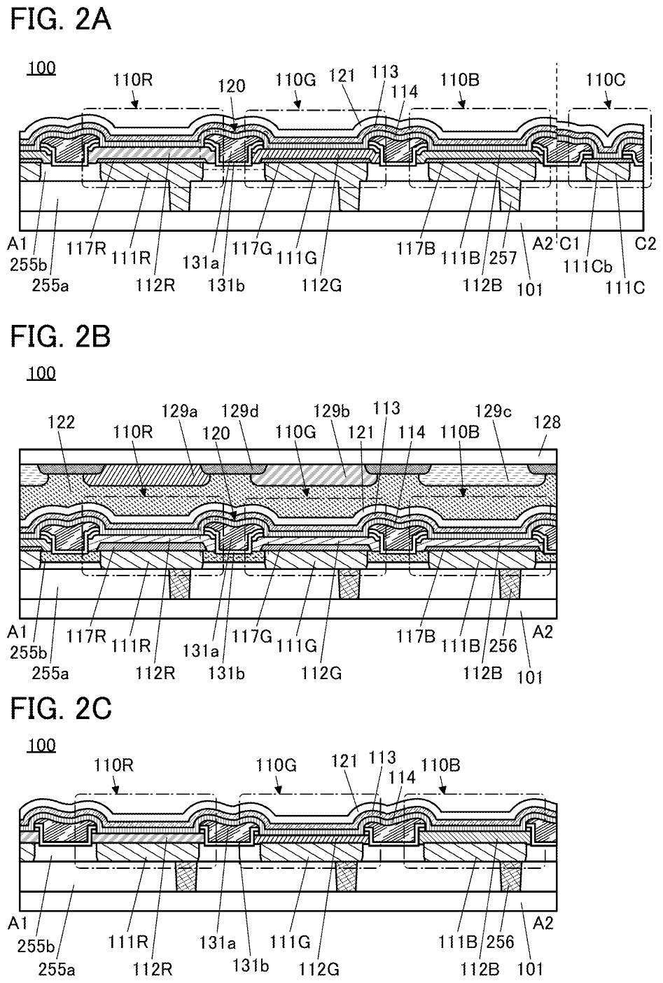

Note that in the case where three light-emitting elements emit red, green, and blue, and have the same thickness of the conductive layer 117 and the same m of mλ/2 (m is a positive integer), the EL layer 112R of the light-emitting element 110R emitting light whose wavelength is the longest has the largest thickness, and the EL layer 112B of the light-emitting element 110B emitting light whose wavelength is the shortest has the smallest thickness, for example. The same does not apply to the case where the value of m is different between each light-emitting element. For example, there is a case where the EL layer 112B has the largest thickness. FIG. 2C illustrates another example of the cross section in FIG. 1B; the thickness of the EL layer 112B is larger than the thicknesses of the EL layer 112R and the EL layer 112G.

For simplicity, figures or the like in this specification do not clearly show the difference in thicknesses of the EL layer 112 and the conductive layer 117 among the light-emitting elements; however, the thicknesses are preferably adjusted as appropriate in each light-emitting element to intensify light with a wavelength corresponding to each light-emitting element.

The conductive film that can be used for the conductive layer 117 or the like and transmits visible light can be formed using, for example, indium oxide, indium tin oxide, indium zinc oxide, zinc oxide, or zinc oxide to which gallium is added. Alternatively, a metal material such as gold, silver, platinum, magnesium, nickel, tungsten, chromium, molybdenum, iron, cobalt, copper, palladium, or titanium; an alloy containing any of these metal materials; a nitride of any of these metal materials (e.g., titanium nitride), or the like formed thin enough to have a light-transmitting property can be used. Furthermore, a stacked-layer film of the above materials can be used for a conductive layer. For example, a stacked-layer film of indium tin oxide and an alloy of silver and magnesium is preferably used, in which case conductivity can be increased. Further alternatively, graphene or the like may be used.

As the conductive film having a transmissive property and a reflective property that can be used for the common electrode 113, the above conductive film reflecting visible light formed to be thin enough to transmit visible light can be used. In addition, with the stacked-layer structure of the conductive film and the above conductive film transmitting visible light described above, the conductivity and the mechanical strength can be increased.

Examples of a material that can be used for the plug 256 include metals such as aluminum, titanium, chromium, nickel, copper, yttrium, zirconium, molybdenum, gold, silver, platinum, magnesium, iron, cobalt, palladium, tantalum, and tungsten; an alloy containing any of these metal materials; and a nitride of any of these metal materials. As the plug 256, a single layer or a stacked-layer structure including a film containing any of these materials can be used. For example, a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which an aluminum film or a copper film is stacked over a titanium film or a titanium nitride film and a titanium film or a titanium nitride film is formed thereover, a three-layer structure in which an aluminum film or a copper film is stacked over a molybdenum film or a molybdenum nitride film and a molybdenum film or a molybdenum nitride film is formed thereover, and the like can be given. Note that an oxide such as indium oxide, tin oxide, or zinc oxide may be used. In addition, copper containing manganese is preferably used because controllability of a shape by etching is increased.

The example where the conductive layer 111 has a two-layer structure is described. Here, the case where the conductive layer 111 illustrated in FIG. 1B or the like has a two-layer stacked structure is considered as an example. In FIG. 1B or the like, it is preferable to use a conductive film reflecting visible light as an upper layer of the two-layer stacked structure of the conductive layer 111 (hereinafter referred to as an upper layer of the conductive layer 111). In addition, in FIG. 1B or the like, the reflectance of a lower layer of the two-layer stacked structure of the conductive layer 111 (hereinafter referred to as a lower layer of the conductive layer 111) may be lower than the upper layer of the conductive layer 111. A material with high conductivity may be used for the lower layer of the conductive layer 111. A material having a high processing property may be used for the lower layer of conductive layer 111.

For the upper layer of the conductive layer 111, the above-described material and structure which can be used for the conductive layer 111 are preferably employed. For the lower layer of the conductive layer 111, for example, a metal material such as gold, silver, platinum, magnesium, nickel, tungsten, chromium, molybdenum, iron, cobalt, copper, palladium, titanium, yttrium, zirconium, or tantalum; an alloy containing any of these metal materials; or a nitride of any of these metal materials (e.g., titanium nitride) can be used.

When aluminum is used for the conductive layer 111 or the upper layer of the conductive layer 111, the thickness of aluminum is preferably greater than or equal to 40 nm, further preferably greater than or equal to 70 nm, whereby the reflectivity of visible light or the like can be sufficiently increased. In the case where silver is used for the conductive layer 111 or the upper layer of the conductive layer 111, the thickness of silver is preferably greater than or equal to 70 nm, further preferably greater than or equal to 100 nm, in which case reflectance with respect to visible light or the like can be sufficiently increased.

As an example, tungsten can be used for the lower layer of the conductive layer 111 and aluminum or an aluminum alloy can be used for the upper layer of the conductive layer 111. The upper layer of the conductive layer 111 may have a structure in which titanium oxide is provided in contact with an upper portion of aluminum or an aluminum alloy. Alternatively, the upper layer of the conductive layer 111 may have a structure in which titanium is provided in contact with the upper portion of aluminum or the aluminum alloy, and titanium oxide is provided in contact with the upper portion of the titanium.

Alternatively, both the lower layer and the upper layer of the conductive layer 111 can be formed using the above-described materials and structures selected from those that can be used for the conductive layer 111.

The conductive layer 111 may be a stacked film including three or more layers.

As a material that forms the pair of electrodes (the pixel electrode and the common electrode) of the light-emitting element, a metal, an alloy, an electrically conductive compound, a mixture thereof, and the like can be used as appropriate. Specific examples include indium tin oxide (In—Sn oxide, also referred to as ITO), In—Si—Sn oxide (also referred to as ITSO), indium zinc oxide (In—Zn oxide), In—W—Zn oxide, an alloy containing aluminum (an aluminum alloy) such as an alloy of aluminum, nickel, and lanthanum (Al—Ni—La), and an alloy of silver, palladium, and copper (Ag—Pd—Cu, also referred to as APC). In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use a Group 1 element or a Group 2 element in the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

As illustrated in FIG. 2A, a conductive layer 257 serving as both the conductive layer 111 and the plug 256 may be provided. The conductive layer 257 can be formed by a dual damascene method. The use of the dual damascene method enables the formation of the plugs and the formation of the conductive layer to be performed together; thus, the process can be simplified. Note that in the structures illustrated in FIG. 2A, either the insulating layer 255a or the insulating layer 255b is not necessarily provided, and in that case, the conductive layer 257 may be embedded in only one of the insulating layers.

For materials which can be used for the conductive layer 257, the materials used for the conductive layer 111 and the plug 256 can be referred to. A conductive film reflecting visible light is preferably used for the conductive layer 257. Furthermore, copper can be used for the conductive layer 257, for example.

Note that a depressed portion is formed on a surface of the insulating layer 255 where the EL layer 112 or the common electrode 113 is not provided, in some cases. For example, a depressed portion is formed by etching of the insulating layer 255 in the etching step at the time of forming the EL layer 112 and at the time of forming the common electrode 113. Here, when the insulating layer 255 has a two-layer stacked structure and an upper layer is formed using a material with a low etching rate, formation of a depressed portion is inhibited in the etching at the time of forming the EL layer 112 and at the time of forming the common electrode 113 in some cases. As the upper layer of the insulating layer 255, for example, hafnium oxide or aluminum oxide can be used.

The conductive film having a semi-transmissive property and a semi-reflective property preferably has a reflectance with respect to visible light (e.g., the reflectance with respect to light having a certain wavelength within the range of 400 nm to 700 nm) of higher than or equal to 20% and lower than or equal to 80%, further preferably higher than or equal to 40% and lower than or equal to 70%. The conductive film having a reflective property preferably has a reflectance with respect to visible light of higher than or equal to 40% and lower than or equal to 100%, further preferably higher than or equal to 70% and lower than or equal to 100%. The conductive film having a light-transmitting property preferably has a reflectance with respect to visible light of higher than or equal to 0% and lower than or equal to 40%, further preferably higher than or equal to 0% and lower than or equal to 30%.

The electrodes included in the light-emitting element may each be formed by an evaporation method such as a vacuum evaporation method or a sputtering method. Alternatively, a discharging method such as an ink-jet method, a printing method such as a screen printing method, or a plating method may be used for the formation.

As the EL layer 112 included in the light-emitting element 110, a light-emitting substance that emits white light may be used. When a light-emitting substance emitting white light is employed as the EL layer 112, the EL layer 112 preferably contains two or more kinds of light-emitting substances. White emission can be obtained by selecting two or more light-emitting substances so as to emit light of complementary colors, for example. For example, it is preferable to contain two or more of light-emitting substances emitting light of R (red), G (green), B (blue), Y (yellow), O (orange), and the like or light-emitting substances emitting light containing two or more of spectral components of R, G, and B. A light-emitting element whose emission spectrum has two or more peaks in the wavelength range of a visible light region (e.g., 350 nm to 750 nm) is preferably employed. An emission spectrum of a material emitting light having a peak in a yellow wavelength range preferably includes spectral components also in green and red wavelength ranges.

The EL layer 112 can have a structure in which a light-emitting layer containing a light-emitting material emitting light of one color and a light-emitting layer containing a light-emitting material emitting light of another color are stacked. For example, the plurality of light-emitting layers in the EL layer 112 may be stacked in contact with each other or may be stacked with a region not including any light-emitting material therebetween. For example, between a fluorescent light-emitting layer and a phosphorescent light-emitting layer, a region that contains the same material as the fluorescent light-emitting layer or the phosphorescent light-emitting layer (for example, a host material or an assist material) and no light-emitting material may be provided. This facilitates the fabrication of the light-emitting element and reduces the drive voltage.

Light-emitting elements overlap with coloring layers transmitting light of different colors, whereby light from the light-emitting elements that emit white light can be emitted through the coloring layers. For example, three kinds of color layers transmitting light of red (R), green (G), and blue (B) are used in the light-emitting elements emitting white light, whereby a full-color display apparatus can be achieved.

The light-emitting element 110 may have a single structure including one EL layer or a tandem structure in which a plurality of EL layers are stacked with a charge-generation layer therebetween.

In the case where a light-emitting substance emitting white light is used as the EL layer 112, separate formation of the light-emitting layer is not necessary in each light-emitting element. In addition, the continuous EL layer 112 can be provided across the plurality of light-emitting elements 110.

In the display apparatus 100 illustrated in FIG. 2B, the conductive layer 117 provided in each light-emitting element 110 has a thickness that differs among the light-emitting elements. For example, in the case where the light-emitting substance emitting white light is used as the EL layer 112, it is preferable to vary an optical path length with the structure where the conductive layer 117 has a thickness that differs among the light-emitting elements. In FIG. 2B, the thickness of the conductive layer 117B is the smallest and the thickness of the conductive layer 117R is the largest among the three conductive layers 117. Here, the distance between the top surface of the conductive layer 111 and the bottom surface of the common electrode 113 (i.e., the interface between the common electrode 113 and the EL layer 112) is the largest in the light-emitting element 110R and the smallest in the light-emitting element 110B among the light-emitting elements. In each light-emitting element, by changing the distance between the top surface of the conductive layer 111 and the bottom surface of the common electrode 113, optical distance (optical path length) of each light-emitting element can be changed.

Among the three light-emitting elements, the light-emitting element 110R has the longest optical path length, and thus emits light R that is the intensified light with the longest wavelength. In contrast, the light-emitting element 110B has the shortest optical path length, and thus emits light B that is the intensified light with the shortest wavelength. The light-emitting element 110G emits light G that is the intensified light with the intermediate wavelength. For example, the light R is the intensified red light, the light G is the intensified green light, and the light B is the intensified blue light.

With such a structure, the EL layer included in the light-emitting element 110 need not be formed separately for the light-emitting elements of different colors; thus, color display with high color reproducibility can be performed using elements with the same structure. Moreover, the light-emitting elements 110 can be arranged extremely densely. For example, a display apparatus having a resolution exceeding 5000 ppi can be achieved.

In each of the light-emitting elements, the optical distance between the surface of the conductive layer 111 reflecting visible light and the common electrode 113 having a semi-transmissive property and a semi-reflective property with respect to visible light is preferably adjusted to be mλ/2 (m is a positive integer) or in the neighborhood, where λ is the wavelength of light whose intensity is desired to be increased.

Note that the above-described optical distance depends on a product of the physical distance between the reflective surface of the conductive layer 111 and the reflective surface of the common electrode 113 having a semi-transmissive and a semi-reflective property and the refractive index of a layer provided therebetween, and thus is difficult to adjust the optical distance exactly. Thus, it is preferable to adjust the optical distance on the assumption that the surface of the conductive layer 111 and the surface of the common electrode 113 having a semi-transmissive and a semi-reflective property are each the reflective surface.

In the case where the EL layer emitting white light is used as the EL layer 112, for example, the EL layer 112R, the EL layer 112G, and the EL layer 112B can be a common layer.

In addition, by providing the coloring layer which overlaps with the light-emitting element 110, color purity of light from the light-emitting element can be increased. In FIG. 2B, a structure where the display apparatus 100 includes a substrate 128, coloring layers 129a, 129b, and 129c, and a black matrix 129d is illustrated.

A resin layer 122 is provided between the protective layer 121 and the substrate 128. The resin layer 122 has a function of attaching the light-emitting element 110 provided over the substrate 101 with the coloring layers 129a, 129b, and 129c and the black matrix 129d provided over the substrate 128.

For the resin layer 122, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. Alternatively, a two-liquid-mixture-type resin may be used. An adhesive sheet or the like may be used.

The coloring layer 129a, the coloring layer 129b, and the coloring layer 129c have functions of transmitting light of different colors from one another. Light that penetrates the coloring layer 129a and light that penetrates the coloring layer 129b have different wavelength ranges, for example. Light that penetrates the coloring layer 129b and light that penetrates the coloring layer 129c have different wavelength ranges, for example. Light that penetrates the coloring layer 129c and light that penetrates the coloring layer 129a have different wavelength ranges, for example. For example, the coloring layer 129a has a function of transmitting red light, the coloring layer 129b has a function of transmitting green light, and the coloring layer 129c has a function of transmitting blue light. Thus, the display apparatus 100 can perform full-color display. Note that the coloring layer 129a, the coloring layer 129b, and the coloring layer 129c may each have a function of transmitting light of any of cyan, magenta, and yellow. Note that in the following description common to the coloring layer 129a, the coloring layer 129b, and the coloring layer 129c, the alphabets added to the reference numerals are omitted and the term “coloring layer 129” is used in some cases.

Here, adjacent coloring layers 129 sometimes overlap with each other in a region not overlapping with the light-emitting element 110, for example. When the coloring layers 129 that transmit light of different colors overlap with each other, the coloring layers 129 in the region where the coloring layers 129 overlap with each other can function as light-blocking layers. Thus, light emitted from the light-emitting element 110 can be inhibited from leaking to an adjacent subpixel. For example, light emitted from the light-emitting element 110R overlapping with the coloring layer 129a can be inhibited from entering the coloring layer 129b. Consequently, the contrast of images displayed on the display apparatus can be increased, and the display apparatus can have high display quality.

Note that the adjacent coloring layers 129 does not necessarily include the overlapping region. In this case, the black matrix 129d is preferably provided in a region not overlapping with the light-emitting element 110. The black matrix 129d can be provided on a surface of the substrate 128 on the resin layer 122 side. Furthermore, the coloring layer 129 may be provided on the surface of the substrate 128 on the resin layer 122 side.

The black matrix is referred to a black layer in some cases.

In this specification and the like, the thicknesses of a layer and a film are sometimes drawn to be larger for easy viewing in a drawing that is not enlarged. In an enlarged drawing, the distance between components included in a display apparatus or the like may differ.

Note that an end portion of the EL layer 112 can be positioned inward from an end portion of the conductive layer 111.

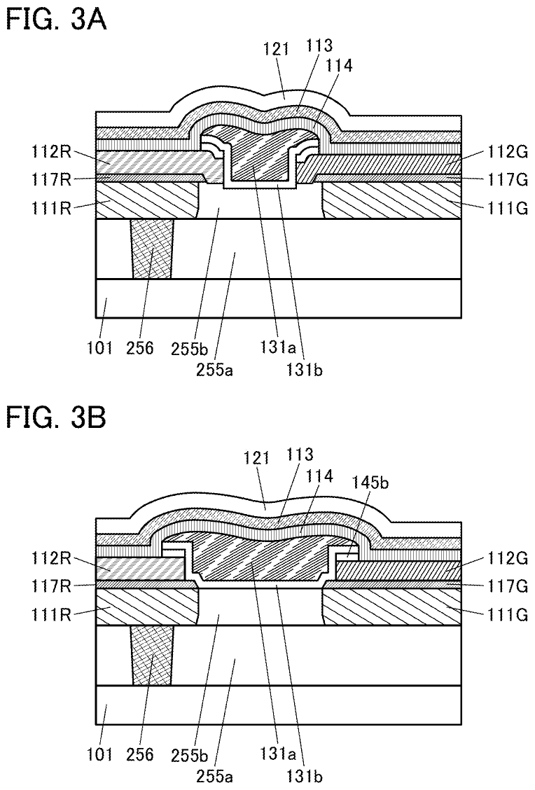

FIG. 3A illustrates an enlarged view of a region surrounded by a dashed double-dotted line in FIG. 1C. In FIG. 3A, the end portion of the EL layer 112 is positioned outside the end portion of the conductive layer 111. On the other hand, the structure illustrated in FIG. 3B is different from that in FIG. 3A mainly in that the end portion of the EL layer 112 positioned inward from the end portion of the conductive layer 111. Note that the end portion of the EL layer 112 may be substantially aligned with the end portion of the conductive layer 111. One end portion of the EL layer 112 may be positioned outward from the conductive layer 111 and the other may be substantially aligned with the end portion of the conductive layer 111. One end portion of the EL layer 112 may be positioned inward from the conductive layer 111 and the other may be substantially aligned with the end portion of the conductive layer 111. One end portion of the EL layer 112 may be positioned outward from the conductive layer 111 and the other may be positioned inward from the end portion of the conductive layer 111.

Note that a sacrificial layer formed when the EL layer 112 is processed into an island shape may remain between the EL layer 112 and the insulating layer 131b. FIG. 3A and FIG. 3B show examples where the sacrificial layer 145R remains between the EL layer 112R and the insulating layer 131b, the sacrificial layer 145G remains between the EL layer 112G and the insulating layer 131b, and the sacrificial layer 145B remains between the EL layer 112B and the insulating layer 131b. The details of the sacrificial layer 145R, the sacrificial layer 145G, and the sacrificial layer 145B will be described later.

### Fabricating Method Example 1

An example of a fabricating method of the display apparatus of one embodiment of the present invention will be described with reference to drawings.

Note that thin films included in the display apparatus (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD) method and a thermal CVD method. As an example of the thermal CVD method, a metal organic chemical vapor deposition (MOCVD) method can be given.

Alternatively, thin films that form the display apparatus (insulating films, semiconductor films, conductive films, and the like) can be formed by a method such as spin coating, dipping, spray coating, ink-jetting, dispensing, screen printing, offset printing, a doctor knife, a slit coater, a roll coater, a curtain coater, and a knife coater.

When the thin films that form the display apparatus are processed, a photolithography method or the like can be used for the processing. Besides, a nanoimprinting method, a sandblasting method, a lift-off method, or the like may be used for the processing of the thin films. Alternatively, island-shaped thin films may be directly formed by a film formation method using a shielding mask such as a metal mask.

There are the following two typical methods of a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As the light used for light exposure in the photolithography method, for example, an i-line (with a wavelength of 365 nm), a g-line (with a wavelength of 436 nm), an h-line (with a wavelength of 405 nm), or combined light of any of them can be used. Besides, ultraviolet rays can be used. Alternatively, KrF laser light, ArF laser light, or the like can be used. In addition, light exposure may be performed by liquid immersion exposure technique. Furthermore, as the light used for the exposure, extreme ultra-violet (EUV) light or X-rays may be used. Instead of the light used for the light exposure, an electron beam can also be used. It is preferable to use EUV light, X-rays, or an electron beam because they can perform extremely minute processing. Note that a photomask is not needed when light exposure is performed by scanning with a beam such as an electron beam.

For etching of thin films, a dry etching method, a wet etching method, a sandblast method, or the like can be used.

For planarization treatment of the thin film, typically, a polishing method such as a chemical mechanical polishing (CMP) method can be suitably used. A reflow method in which the conductive layer is fluidized by heat treatment can be suitably used. Alternatively, a combination of the reflow method and the CMP method may be used. Alternatively, dry etching treatment or plasma treatment may be used. Note that polishing treatment, dry etching treatment, or plasma treatment may be performed a plurality of times, or these treatments may be performed in combination. In the case where the treatments are performed in combination, the order of steps is not particularly limited and may be set as appropriate depending on the roughness of the surface to be processed.

In order to accurately process the thin film to have a desired thickness, for example, the CMP method is employed. In that case, first, polishing is performed at a constant processing rate until part of the top surface of the thin film is exposed. After that, polishing is performed under a condition with a lower processing rate until the thin film has a desired thickness, so that highly accurate processing can be performed.

Examples of a method for detecting the end of the polishing include an optical method in which the surface to be processed is irradiated with light and a change in the reflected light is detected; a physical method in which a change in the polishing resistance received by the processing apparatus from the surface to be processed is detected; and a method in which a magnetic line is applied to the surface to be processed and a change in the magnetic line due to the generated eddy current is used.

After the top surface of the thin film is exposed, polishing treatment is performed under a condition with a low processing rate while the thickness of the thin film is monitored by an optical method using a laser interferometer or the like, whereby the thickness of the thin film can be controlled with high accuracy. Note that the polishing treatment may be performed a plurality of times until the thin film has a desired thickness, as necessary.

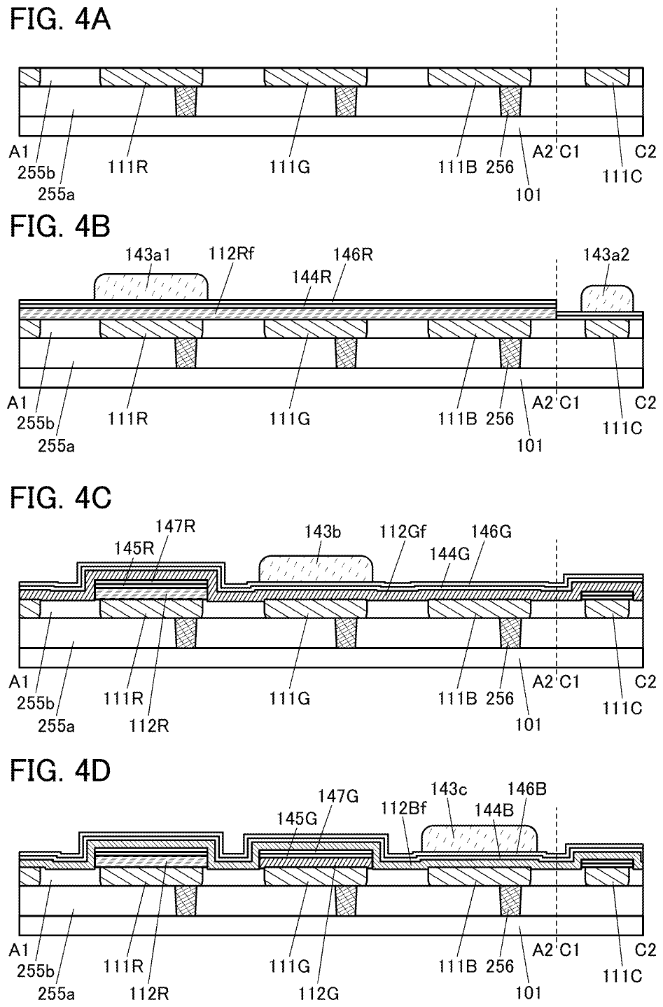

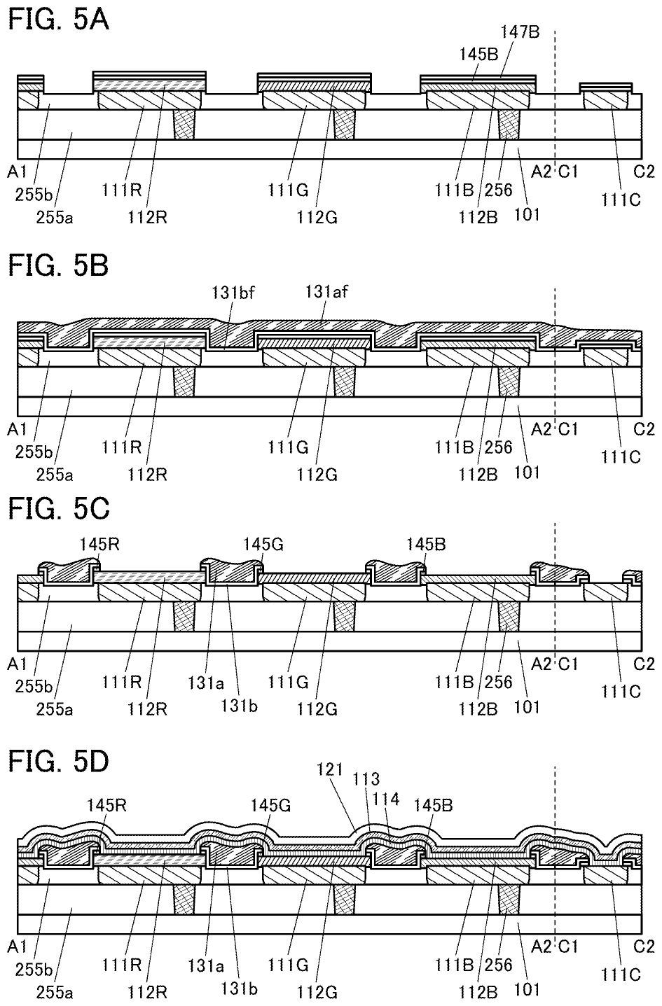

Examples of a method for fabricating the display apparatus illustrated in FIG. 1B will be described with reference to FIG. 4A to FIG. 5D. By the fabricating method illustrated in FIG. 4A to FIG. 5D, the EL layer 112 can be processed without using a metal mask.

### Preparation of Substrate 101

As the substrate 101, a substrate having at least heat resistance high enough to withstand the following heat treatment can be used. In the case where an insulating substrate is used as the substrate 101, a glass substrate, a quartz substrate, a sapphire substrate, a ceramic substrate, or the like can be used. Alternatively, a single crystal semiconductor substrate or a polycrystalline semiconductor substrate using silicon or silicon carbide as a material, a compound semiconductor substrate of silicon germanium or the like, a semiconductor substrate such as an SOI substrate, or the like can be used.

As the substrate 101, it is particularly preferable to use the above semiconductor substrate or the insulating substrate where a semiconductor circuit including a semiconductor element such as a transistor is formed. The semiconductor circuit preferably forms a pixel circuit, a gate line driver circuit (a gate driver), a source line driver circuit (a source driver), or the like. In addition to the above, an arithmetic circuit, a memory circuit, or the like may be formed.

In this embodiment, a substrate including at least a pixel circuit is used as the substrate 101.

### [Formation of Insulating Layer 255a, Plug 256, Insulating Layer 255b, and Conductive Layer 111]

An insulating film to be the insulating layer 255a is formed over the substrate 101. Next, an opening reaching the substrate 101 is formed in the insulating layer 255a in a position where the plug 256 is to be formed. The opening is preferably an opening reaching an electrode or a wiring provided in the substrate 101. Then, a conductive film is formed to fill the opening and planarization treatment is performed to expose a top surface of the insulating layer 255a. In this manner, the plug 256 embedded in the insulating layer 255a can be formed.

An insulating layer to be the insulating layer 255b is formed over the insulating layer 255a, and the plug 256. The insulating layer to be the insulating layer 255b preferably covers the plug 256. Next, an opening reaching the plug 256 is formed in the insulating layer to be the insulating layer 255b in a position where the conductive layer 111 is to be formed. Then, a conductive film is formed to fill the opening and planarization treatment is performed to expose a top surface of the insulating layer 255b. Thus, the conductive layer 111 embedded in the insulating layer 255b can be formed (FIG. 4A). The conductive layer 111 is electrically connected to the plug 256.

The top surface of the insulating layer 255b is preferably substantially aligned with the top surface of the conductive layer 111. The top surface of the conductive layer 111 may be lower than the top surface of the insulating layer 255b, and the conductive layer 111 may be depressed more deeply than the insulating layer 255b.

Alternatively, the level difference between the top surface of the insulating layer 255b and the top surface of the conductive layer 111 is smaller than 0.1 times the thickness of the conductive layer 111, for example.

### [Formation of EL Layer 112]

Next, an EL film 112Rf is formed over the conductive layer 111 and the insulating layer 255b. The EL film 112Rf is a film to be the EL layer 112R of the light-emitting element 110R. Note that shown here is an example in which the EL layer 112R, the EL layer 112G, and the EL layer 112B are formed in this order, but the formation order of three EL layers 112 is not limited thereto.

A layer to be the EL film 112Rf includes at least a film containing a light-emitting compound. Besides, a structure where one or more of films functioning as an electron-injection layer, an electron-transport layer, a charge generation layer, a hole-transport layer, and a hole-injection layer are stacked may be employed. A layer to be the EL layer 112R can be formed by, for example, an evaporation method, a sputtering method, an inkjet method, or the like. Note that without limitation to this, the above film formation method can be used as appropriate.

### [Formation of Sacrificial Film]

Next, the film formation step of sacrificial films will be described.

An example in which a sacrificial layer with a two-layer structure is used will be described below.

A sacrificial film 144R is a film to be the sacrificial layer 145R, and a sacrificial film 146R is a film to be the sacrificial layer 147R. A sacrificial film 144G is a film to be the sacrificial layer 145G, and a sacrificial film 146G is a film to be the sacrificial layer 147G. A sacrificial film 144B is a film to be the sacrificial layer 145B, and a sacrificial film 146B is a film to be the sacrificial layer 147B.

In the film formation step of the sacrificial film, first, the sacrificial film 144R is formed to cover the EL film 112Rf. The sacrificial film 144R is provided to be in contact with the top surface of the connection electrode 111C. Next, the sacrificial film 146R is formed over the sacrificial film 144R.

The sacrificial film 144R and the sacrificial film 146R can be formed by a sputtering method, an ALD method (a thermal ALD method or a PEALD method), or a vacuum evaporation method, for example. Note that a formation method that gives less damage to an EL layer is preferable, and an ALD method or a vacuum evaporation method is more suitable than a sputtering method for the formation of the sacrificial film 144R that is formed directly over the EL film 112Rf.

An inorganic film such as a metal film, an alloy film, a metal oxide film, a semiconductor film, or an inorganic insulating film can be suitably used as the sacrificial film 144R.

Alternatively, an oxide film can be used as the sacrificial film 144R. Typically, an oxide film or an oxynitride film such as silicon oxide, silicon oxynitride, aluminum oxide, aluminum oxynitride, hafnium oxide, or hafnium oxynitride can be used. A nitride film, for example, can be used as the sacrificial film 144R. Specifically, it is possible to use a nitride such as silicon nitride, aluminum nitride, hafnium nitride, titanium nitride, tantalum nitride, tungsten nitride, gallium nitride, or germanium nitride. A film containing such an inorganic insulating material can be formed by a film formation method such as a sputtering method, a CVD method, or an ALD method; the sacrificial film 144R, which is formed directly over the EL film 112Rf, is particularly preferably formed by an ALD method.

For the sacrificial film 144R, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example. It is particularly preferable to use a low-melting-point material such as aluminum or silver.

Alternatively, a metal oxide such as an indium gallium zinc oxide (In—Ga—Zn oxide, also referred to as IGZO) can be used for the sacrificial film 144R. It is also possible to use indium oxide, indium zinc oxide (In—Zn oxide), indium tin oxide (In—Sn oxide), indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like. Alternatively, indium tin oxide containing silicon or the like can also be used.

Note that an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium described above. Specifically, M is preferably one or more kinds selected from gallium, aluminum, and yttrium.

Any of the above-described materials usable for the sacrificial film 144R can be used for the sacrificial film 144(2)R. Alternatively, from the above materials usable for the sacrificial film 144R, one material can be selected for the sacrificial film 144R and another material can be selected for the sacrificial film 146R. Alternatively, one or more materials can be selected for the sacrificial film 144R from the above materials usable for the sacrificial film 144R, and a material selected from the materials excluding the material(s) selected for the sacrificial film 144R can be used for the sacrificial film 146R.

As the sacrificial film 144R, it is possible to use a film highly resistant to etching treatment performed on various EL films such as the EL film 112Rf, i.e., a film having high etching selectivity. Moreover, as the sacrificial film 144R, it is particularly preferable to use a film that can be removed by a wet etching method less likely to cause damage to EL films.

Alternatively, for the sacrificial film 144R, a material that can be dissolved in a solvent chemically stable with respect to at least the uppermost film of the EL film 112Rf may be used. Specifically, a material that can be dissolved in water or alcohol can be suitably used for the sacrificial film 144R. In film formation of the sacrificial film 144R, it is preferable that application of such a material dissolved in a solvent such as water or alcohol be performed by a wet film formation method and then heat treatment for evaporating the solvent be performed. At this time, the heat treatment is preferably performed in a reduced-pressure atmosphere, in which case the solvent can be removed at a low temperature in a short time and thermal damage to the EL film 112Rf can be reduced accordingly.

As a wet film formation method for forming the sacrificial film 144R, spin coating, dipping, spray coating, ink-jetting, dispensing, screen printing, offset printing, a doctor knife method, a slit coater, a roll coater, a curtain coater, a knife coater, or the like can be given.

For the sacrificial film 144R, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used.

As the sacrificial film 146R, a film having high etching selectivity with respect to the sacrificial film 144R is used.

For example, for the sacrificial film 144R, an inorganic insulating material, such as aluminum oxide, hafnium oxide, or silicon oxide, formed by an ALD method is particularly preferably used; and for the sacrificial film 146R, a metal oxide containing indium, such as indium gallium zinc oxide (also referred to as an In—Ga—Zn oxide or IGZO), formed by a sputtering method is particularly preferably used.

Alternatively, as the sacrificial film 146R, an organic film that can be used as the EL film 112Rf or the like may be used. For example, the organic film that is used as the EL film 112Rf, an EL film 112Gf, or an EL film 112Bf can be used as the sacrificial film 146R. Such an organic film can be preferably used, in which case the film formation apparatus for the EL film 112Rf or the like can be used in common. Furthermore, a sacrificial layer 147R can be removed at the same time as the etching of the EL film 112Rf; thus, the process can be simplified.

For example, in the case where dry etching using a gas containing fluorine (also referred to as a fluorine-based gas) is used for the etching of the sacrificial film 144R, silicon, silicon nitride, silicon oxide, tungsten, titanium, molybdenum, tantalum, tantalum nitride, an alloy containing molybdenum and niobium, an alloy containing molybdenum and tungsten, or the like can be used for the sacrificial film 146R. Here, for example, a metal oxide film of IGZO, ITO, or the like is given as a film having high etching selectivity (that is, enabling low etching rate) in dry etching using the above-described fluorine-based gas, and such a film can be used as the sacrificial film 144R.

[Formation of Resist Mask 143a]

Next, a resist mask 143a is formed over the sacrificial film 146R (FIG. 4B). Note that FIG. 4B illustrates an example in which the EL film 112Rf is not formed over the connection electrode 111C. In the case where the region over the connection electrode 111C is shielded in formation of the EL film 112Rf, a metal mask can be used. Since the metal used here does not need to shield a pixel region of a display portion, a fine mask does not need to be used.

For the resist mask 143a, a resist material containing a photosensitive resin such as a positive resist material or a negative resist material can be used.

Here, in the case where the resist mask 143a is formed over the sacrificial film 146R, if a defect such as a pinhole exists in the sacrificial film 146R, the EL film 112Rf might be dissolved in a solvent of the resist material. With the use of an inorganic insulating material such as aluminum oxide, hafnium oxide, or silicon oxide formed by an ALD method for the sacrificial film 144R, a film with few pinholes can be formed and generation of such a defect can be prevented.

### [Etching of Sacrificial Film 144R and Sacrificial Film 146R]

Then, part of each of the sacrificial film 146R and the sacrificial film 144R that is not covered with the resist mask 143a is removed by etching, whereby island-shaped or band-shaped sacrificial layers 145R and 147R are formed. Here, the sacrificial layer 145R and the sacrificial layer 147R are formed over the conductive layer 111R and over the connection electrode 111C.

Preferably, part of the sacrificial film 146R is removed by etching using the resist mask 143a to form the sacrificial layer 147R, the resist mask 143a is removed, and then the sacrificial film 144R is etched using the sacrificial layer 147R as a hard mask. The etching of the sacrificial film 146R preferably employs etching conditions with high selectivity with respect to the sacrificial film 144R. Either wet etching or dry etching can be used for the etching for forming the hard mask; the use of the dry etching method is preferable can inhibit a shrinkage of the pattern. For example, in the case where an inorganic insulating material such as aluminum oxide, hafnium oxide, or silicon oxide formed by an ALD method is used for the sacrificial film 144R and a metal oxide containing indium, such as indium gallium zinc oxide (also referred to as an In—Ga—Zn oxide or IGZO), formed by a sputtering method is used for the sacrificial film 146R, the sacrificial film 146R formed by a sputtering method is etched here to form a hard mask.

The removal of the resist mask 143a can be performed by wet etching or dry etching. It is particularly preferable to perform dry etching (also referred to as plasma ashing) using an oxygen gas as an etching gas to remove the resist mask 143a.

When the sacrificial film 144R is etched using the sacrificial layer 147R as a hard mask, the removal of the resist mask 143a can be performed while the EL film 112Rf is covered with the sacrificial film 144R. This is particularly suitable in the case where etching using an oxygen gas, such as plasma ashing, is performed because the electrical characteristics might be adversely affected when the EL film 112Rf is exposed to oxygen.

Next, the sacrificial film 144R is removed by etching using the sacrificial layer 147R as a mask, so that the island-shaped or band-shaped sacrificial layer 145R is formed. Note that in the fabrication method of the display apparatus of one embodiment of the present invention, a structure may be employed where either the sacrificial layer 145R or the sacrificial layer 147R is not used.

### [Etching of the EL Film 112Rf]

Next, part of the EL film 112Rf that is not covered with the sacrificial layer 145R is removed by etching, so that the island-shaped or band-shaped EL layer 112R is formed.

For the etching of the EL film 112Rf, it is preferable to use dry etching using an etching gas that does not contain oxygen as its main component. This can inhibit the alteration of the EL film 112Rf to achieve a highly reliable display apparatus. Examples of the etching gas that does not contain oxygen as its main component include CF₄, C₄F₈, SF₆, CHF₃, Cl₂, H₂O, BCl₃, and a noble gas such as He. Alternatively, a mixed gas of the above gas and a dilution gas that does not contain oxygen can be used as the etching gas. Here, in the etching of the EL film 112Rf, part of the sacrificial layer 145(1)a may be removed. For example, in the case where the sacrificial film 144(1)a has a two-layer structure, an inorganic insulating material such as aluminum oxide, hafnium oxide, or silicon oxide formed by an ALD method is used for a lower layer, and a metal oxide containing indium such as indium gallium zinc oxide (also referred to as In—Ga—Zn oxide or IGZO) formed by a sputtering method is used for an upper layer, the upper layer may be etched in the etching of the EL film 112Rf.

Note that etching of the EL film 112Rf is not limited to the above and may be performed by dry etching using another gas or wet etching.

When dry etching using an oxygen gas or an etching gas containing an oxygen gas is employed for the etching of the EL film 112Rf, the etching rate can be increased. Consequently, etching under a low-power condition can be performed while the etching rate is kept adequately high; hence, damage due to the etching can be reduced. Furthermore, a defect such as attachment of a reaction product generated in the etching can be inhibited. For example, an etching gas obtained by adding an oxygen gas to the above etching gas that does not contain oxygen as its main component can be used.

### [Formation of EL Layer 112G and EL Layer 112B]

Next, the EL film 112Gf to be the EL layer 112G is formed over the sacrificial layer 145(1)R. For the EL film 112Gf, the description of the EL film 112Rf can be referred to.

Next, the sacrificial film 144G is formed over the EL film 112Gf. For the sacrificial film 144G, the description of the sacrificial film 144R can be referred to.

Next, a protective film 146G is formed over the sacrificial film 144G. For the sacrificial film 146G, the description of the sacrificial film 146R can be referred to.

Next, a resist mask 143b is formed over the sacrificial film 146G (FIG. 4C).

Next, the sacrificial layer 145G, the sacrificial layer 147G, and the EL layer 112G are formed. For the formation of the sacrificial layer 145G, the sacrificial layer 147G, and the EL layer 112G, the formation of the sacrificial layer 145R, the sacrificial layer 147R, and the EL layer 112R can be referred to.

Next, the EL film 112Bf to be the EL layer 112B is formed over the sacrificial layer 147R and the sacrificial layer 147G. For the EL film 112Bf, the description of the EL film 112Rf can be referred to.

Next, the sacrificial film 144B is formed over the EL film 112Bf. For the sacrificial film 144B, the description of the sacrificial film 144R can be referred to.

Next, a sacrificial film 146B is formed over the sacrificial film 144B. For the sacrificial film 146B, the description of the sacrificial film 146R can be referred to.

Next, a resist mask 143c is formed over the sacrificial film 146B (FIG. 4D).

Next, the sacrificial layer 145B, a sacrificial layer 147B, and the EL layer 112B are formed. For the formation of the sacrificial layer 145B, the sacrificial layer 147B, and the EL layer 112B, the formation of the sacrificial layer 145R, the sacrificial layer 147R, and the EL layer 112R can be referred to.

Next, the sacrificial layer 147R, the sacrificial layer 147G, and the sacrificial layer 147B (hereinafter collectively referred to as sacrificial layer 147) are removed by etching or the like (FIG. 5A). For the etching of the sacrificial layer 147, the condition that can provide a high selectivity with respect to the sacrificial layer 145R, the sacrificial layer 145G, and the sacrificial layer 145B (hereinafter collectively referred to as sacrificial layer 145) is preferably employed. Note that the sacrificial layer 147 is not necessarily removed.

[Formation of Resin Layer 131a and Insulating Layer 131b]

Next, an insulating film 131bf to be the insulating layer 131b is formed. A film containing an inorganic material is preferably used as the insulating film 131bf. For example, a single layer or stacked layers of a film containing aluminum oxide, magnesium oxide, hafnium oxide, gallium oxide, indium gallium zinc oxide, silicon oxide, silicon oxynitride, silicon nitride, silicon nitride oxide, or the like can be used.

For the formation of the insulating film 131bf, a sputtering method, a chemical vapor deposition (CVD) method, a molecular beam epitaxy (MBE) method, a pulsed laser deposition (PLD) method, an atomic layer deposition (ALD) method, or the like can be used. An ALD method achieving favorable coverage can be suitably used for formation of the insulating film 131bf.

As the insulating film 131bf, a single layer or stacked layers of aluminum oxide, magnesium oxide, hafnium oxide, gallium oxide, indium gallium zinc oxide, silicon oxide, silicon oxynitride, silicon nitride, silicon nitride oxide, or the like can be used. In particular, aluminum oxide is preferable because it has high selectivity with respect to the EL layer 112 in etching and has a function of protecting the EL layer 112 in forming the insulating layer 131b which is to be described later.

The insulating film 131bf formed by an ALD method can be a film with few pinholes, and the insulating layer 131b can have an excellent function of protecting the EL layer 112.

The film formation temperature of the insulating film 131bf is preferably lower than the upper temperature limit of the EL layer 112.

Here, aluminum oxide is formed by an ALD method for the insulating film 131bf. The formation temperature of the insulating film 131bf by an ALD method is preferably higher than or equal to 60° C. and lower than or equal to 150° C., further preferably higher than or equal to 70° C. and lower than or equal to 115° C., still further preferably higher than or equal to 80° C. and lower than or equal to 100° C. By forming the insulating film 131bf at such a temperature, a dense insulating film can be obtained and damage to the EL layer 112 can be reduced.

Next, a resin film 131af to be the resin layer 131a is formed (FIG. 5B). The resin film 131af is provided so as to fill the depressed portion on the insulating film 131bf. Furthermore, the resin film 131af is provided so as to cover the sacrificial layer 145, the EL layer 112, and the conductive layer 111. The resin film 131af is preferably a planarization film.

As the resin film 131af, an insulating film containing an organic material is preferably used, and a resin is preferably used as the organic material.

As a material that can be used for the resin film 131af, an acrylic resin, a polyimide resin, an epoxy resin, a polyamide resin, a polyimide-amide resin, a siloxane resin, a benzocyclobutene-based resin, a phenol resin, and precursors of these resins can be given, for example. A photosensitive resin can be used for the resin film 131af. As the photosensitive resin, a positive material or a negative material can be used.

By forming the resin film 131af using a photosensitive resin, the resin film 131af can be fabricated only by light exposure and development steps; thus, damage to layers included in the light-emitting elements 110, in particular, damage to EL layers, can be reduced.

As illustrated in FIG. 5B, the resin film 131af has a slight unevenness reflecting unevenness of the formation surface in some cases. Alternatively, the resin film 131af may be less affected by the unevenness of the formation surface and may have higher planarity than that in FIG. 5B.

Next, the resin layer 131a is formed. Here, when a photosensitive resin is used for the resin film 131af, the resin layer 131a can be formed without providing an etching mask such as a resist mask or a hard mask. Since a photosensitive resin can be processed only by light exposure and development steps, the resin layer 131a can be formed without using a dry etching method or the like. Thus, the process can be simplified. In addition, damage to the EL layer due to etching of the resin film 131af can be reduced. Furthermore, the upper portion of the resin layer 131a may be partly etched to adjust the level of the surface.

The resin layer 131a may alternatively be formed by performing etching substantially uniformly on the top surface of the resin film 131af. Such uniform etching for planarization is also referred to as etch back.

To form the resin layer 131a, the light exposure and development steps and the etch back step may be used in combination.

Next, etching of the insulating film 131bf and the sacrificial layer 145 is performed (FIG. 5C). At this time, a method that causes damage to the EL layer 112R, the EL layer 112G, and the EL layer 112B as little as possible is preferably employed. Thus, the insulating layer 131b covering the side surfaces of the EL layer 112R, the EL layer 112G, and the EL layer 112B is formed.

The insulating film 131bf and the sacrificial layer 145 are formed using the same material, whereby etching can be performed at the same time, so that the step can be simplified in some cases.

A dry etching method or a wet etching method can be used for the etching of the insulating film 131bf. The etching may be performed by ashing using oxygen plasma or the like. Chemical mechanical polishing (CMP) may be used for the etching of the insulating film 131bf.

Note that it is preferable to reduce damage to the EL layer 112 due to etching at the time of etching the insulating film 131bf. Accordingly, it is preferable to use a material with high etching selectivity with respect to the EL layer 112 for the insulating film 131bf, for example.

By using an inorganic material for the insulating film 131bf, the selectivity with respect to the EL layer 112 can be high in some cases. As the insulating layer 131b, a single layer or stacked layers of aluminum oxide, magnesium oxide, hafnium oxide, gallium oxide, indium gallium zinc oxide, silicon oxide, silicon oxynitride, silicon nitride, silicon nitride oxide, or the like can be used. In particular, aluminum oxide is preferable because it has high selectivity with respect to the EL layer 112 in etching and has a function of protecting the EL layer 112 in forming the insulating layer 131b which is to be described later. In particular, with the use of an inorganic insulating material such as aluminum oxide, hafnium oxide, or silicon oxide formed by an ALD method for the insulating layer 131b, the insulating layer 131b can be a film with few pinholes and can have an excellent function of protecting the EL layer 112.

At the time of forming the resin film 131af and the insulating film 131bf, the levels of the top surfaces can be adjusted by the etching amounts. Here, the etching amount is preferably adjusted so that the insulating layer 131b can cover the side surface of the EL layer 112. In particular, the etching amount is preferably adjusted so that the insulating layer 131b can cover a side surface of the light-emitting layer included in the EL layer 112.

Note that the surface planarity of the resin film 131af containing an organic material may change due to unevenness of the formation surface and the sparseness and density of the pattern formed on the formation surface. The planarity of the resin film 131af may change due to the viscosity or the like of a material used for the resin film 131af. For example, in some cases, the thickness of the resin film 131af in a region not overlapping with the EL layer 112 becomes smaller than the thickness of the resin film 131af in a region overlapping with the EL layer 112. In such a case, for example, etch back of the resin film 131af is performed, whereby the level of the top surface of the resin layer 131a becomes lower than the level of the top surface of the sacrificial layer 145 in some cases.

The resin film 131af has a concave curved surface shape (a hollow shape), a convex curved surface shape (a bulging shape), or the like in a region between the plurality of EL layers 112 in some cases.

### [Formation of Common Layer 114]

Next, the common layer 114 is formed. Note that in the case of a structure not including the common layer 114, the common electrode 113 is formed to cover the EL layer 112R, the EL layer 112G, and the EL layer 112B.

### [Formation of Common Electrode 113]

Next, the common electrode 113 is formed over the common layer 114. The common electrode 113 can be formed by an evaporation method, more specifically, a sputtering method or a vacuum evaporation method, for example. Note that in the case of a structure in which the common layer 114 is not provided over the connection electrode 111C, a metal mask that shields the upper portion of the connection electrode 111C may be used in formation of the common layer 114. Since the metal mask used here does not need to shield a pixel region of the display portion, a fine mask does not need to be used.

Through the above steps, the light-emitting element 110R, the light-emitting element 110G, and the light-emitting element 110B can be fabricated.

### [Formation of Protective Layer 121]

Next, the protective layer 121 is formed over the common electrode 113 (FIG. 5D). An inorganic insulating film used for the protective layer 121 is preferably formed by a sputtering method, a PECVD method, or an ALD method. In particular, an ALD method is preferable because it provides excellent step coverage and is less likely to cause a defect such as a pinhole. In addition, an organic insulating film is preferably formed by an inkjet method because a uniform film can be formed in a desired area.

Through the above steps, the display apparatus 100 illustrated in FIG. 1B can be fabricated.

### Structure Example 2

Another structure example of a display apparatus according to one embodiment of the present invention will be described below.

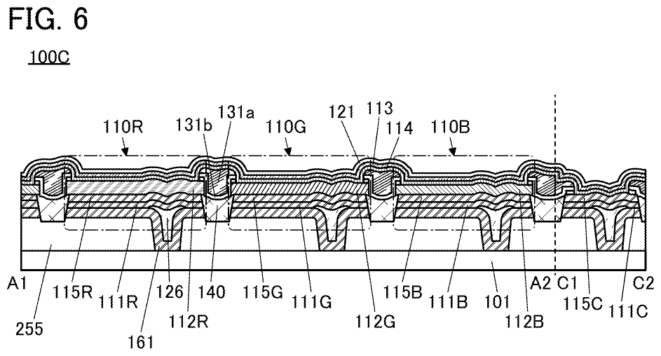

FIG. 6 is a schematic cross-sectional view of a display apparatus. FIG. 6 illustrates a cross section of a region including the connection electrode 111C, and a cross section where the light-emitting element 110R, the light-emitting element 110G, and the light-emitting element 110B are arranged in this order.

A conductive layer 161 and a resin layer 126 are provided below the conductive layer 111 included in the light-emitting element 110.

The conductive layer 161 is provided over the insulating layer 255 and the substrate 101. The conductive layer 161 includes a portion penetrating the insulating layer 255 in an opening provided in the insulating layer 255. The conductive layer 161 functions as a wiring or an electrode electrically connecting the conductive layer 111 and the wiring provided on the substrate 101, the transistor, the electrode, and the like.

A depressed portion is formed in a portion of the conductive layer 161 that is positioned in the opening in the insulating layer 255. The resin layer 126 is provided to fill the depressed portion and functions as a planarization film. Although the top surface of the resin layer 126 is preferably as flat as possible, its surface has a gently curved surface shape in some cases. FIG. 6 and the like illustrate an example in which the top surface of the resin layer 126 has a wave shape with a depressed portion and a projected portion; however, one embodiment of the present invention is not limited thereto. For example, the top surface of the resin layer 126 may be a convex surface, a concave surface, or a flat surface.

The conductive layer 111 is provided over the insulating layer 161.

A conductive layer 115R is provided over the conductive layer 111R, a conductive layer 115G is provided over the conductive layer 111G, a conductive layer 115B is provided over the conductive layer 111B, and a conductive layer 115C is provided over a conductive layer 111C. Note that hereinafter, in the description common to the conductive layer 115R, the conductive layer 115G, the conductive layer 115B, and the conductive layer 115C, the alphabets added to the reference numerals are omitted and the term “conductive layer 115” is used in the description in some cases.

A resin layer 140 is provided to fill a depressed portion generated by a step of the conductive layer 161, the conductive layer 111, and the conductive layer 115. By providing the resin layer 140, the EL layer 112 can be formed on a flat surface. Although the top surface of the resin layer 140 is preferably as flat as possible, its surface has a gently curved surface shape in some cases. In FIG. 6 and the like, examples in which the top surface of the resin layer 140 has a slight depressed portion are illustrated, but the shape of the top surface is not limited to this. For example, the top surface of the resin layer 140 may have a wave shape with a projected portion and a projected portion. For another example, the top surface of the resin layer 140 may be a convex surface, a concave surface, or a flat surface.

### Formation Method Example 2

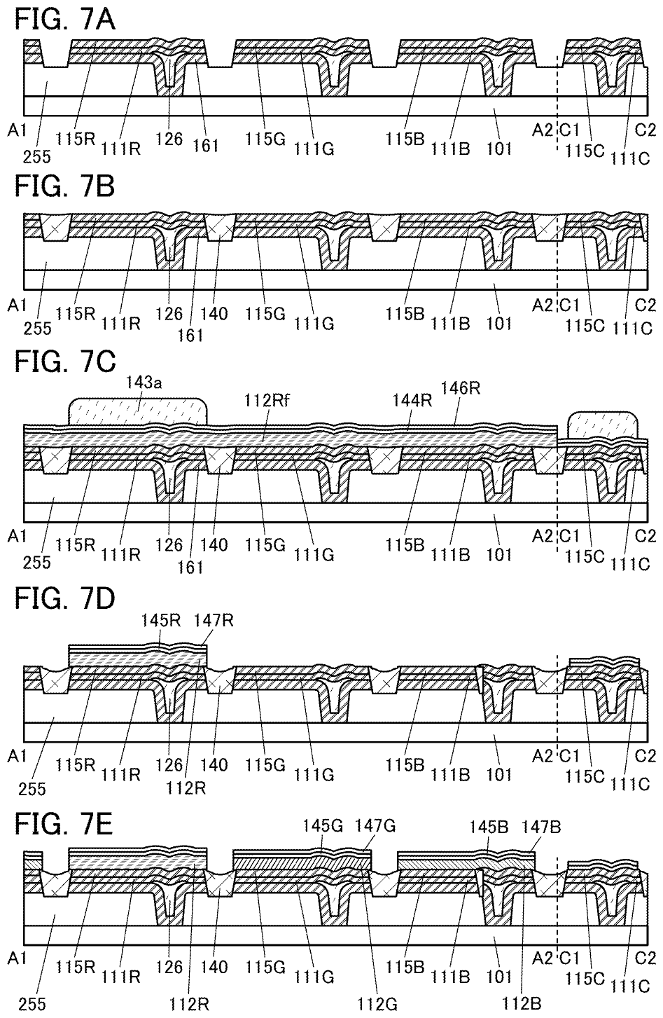

A method for fabricating the display apparatus 100C illustrated in FIG. 6 will be described with using FIG. 7A to FIG. 7E.

As illustrated in FIG. 7A, the insulating layer 255 is formed over the substrate 101. Then, an opening reaching to the substrate 101 is formed in the insulating layer 255. Next, the conductive film is formed along a bottom surface and a side surface of the opening portion. Next, a part of the conductive film is removed by etching or the like, whereby the conductive layer 161 is formed.

Next, the resin layer 126 is formed to fill a depressed portion of the conductive layer 161. For the formation method of the resin layer 126, the formation method of the resin layer 131a can be referred to.

Next, a conductive film to be the conductive layer 111 is formed over the conductive layer 161 and the resin layer 126. Next, a conductive film to be the conductive layer 115 is formed over the conductive layer 111. Next, part of the conductive film to be the conductive layer 111 and part of the conductive film to be the conductive layer 115 are removed by etching or the like, whereby the conductive layer 115 and the conductive layer 111 are formed (FIG. 7A). Next, the resin layer 140 is formed to fill the depressed portion generated by a step of the conductive layer 161, the conductive layer 111, and the conductive layer 115 (FIG. 7B). For the formation method of the resin layer 140, the formation method of the resin layer 131a can be referred to.

Next, the EL film 112Rf, the sacrificial film 144R, and the sacrificial film 146R are formed in this order over the conductive layer 115 and the resin layer 140.

Next, the resist mask 143a is formed over the sacrificial film 146R (FIG. 7C).

Then, part of each of the sacrificial film 146R and the sacrificial film 144R that is not covered with the resist mask 143a is removed by etching, whereby the sacrificial layer 145R and the sacrificial layer 147R are formed. Next, part of the EL film 112Rf that is not covered with the sacrificial layer 145R is removed by etching, so that the EL layer 112R is formed (FIG. 7D).

Next, the EL film 112Gf, a film to be the sacrificial layer 145G, and a sacrificial film to be the sacrificial layer 147G are formed in this order over the conductive layer 115 and the resin layer 126. Next, part of each of a film to be the sacrificial layer 145G and a sacrificial film to be the sacrificial layer 147G is removed by etching, whereby the sacrificial layer 145G and the sacrificial layer 147G is formed. Next, part of the EL film 112Gf is removed by etching, whereby the EL layer 112G is formed.

Next, the EL film 112Bf, a sacrificial film to be the sacrificial layer 145B, and a sacrificial film to be the sacrificial layer 147B are formed in this order over the conductive layer 115 and the resin layer 126. Next, part of each of a sacrificial film to be the sacrificial layer 145B and a sacrificial film to be the sacrificial layer 147B is removed by etching, whereby the sacrificial layer 145B and the sacrificial layer 147B is formed. Next, part of the EL layer 112Bf is removed by etching, whereby the EL layer 112B is formed (FIG. 7E).

Next, the insulating layer 131b, the resin layer 131a, the common layer 114, the common electrode 113, and the protective layer 121 are formed, whereby the display apparatus 100C illustrated in FIG. 6 is formed.

At least part of this embodiment can be implemented in combination with the other embodiments described in this specification as appropriate.

### Embodiment 2

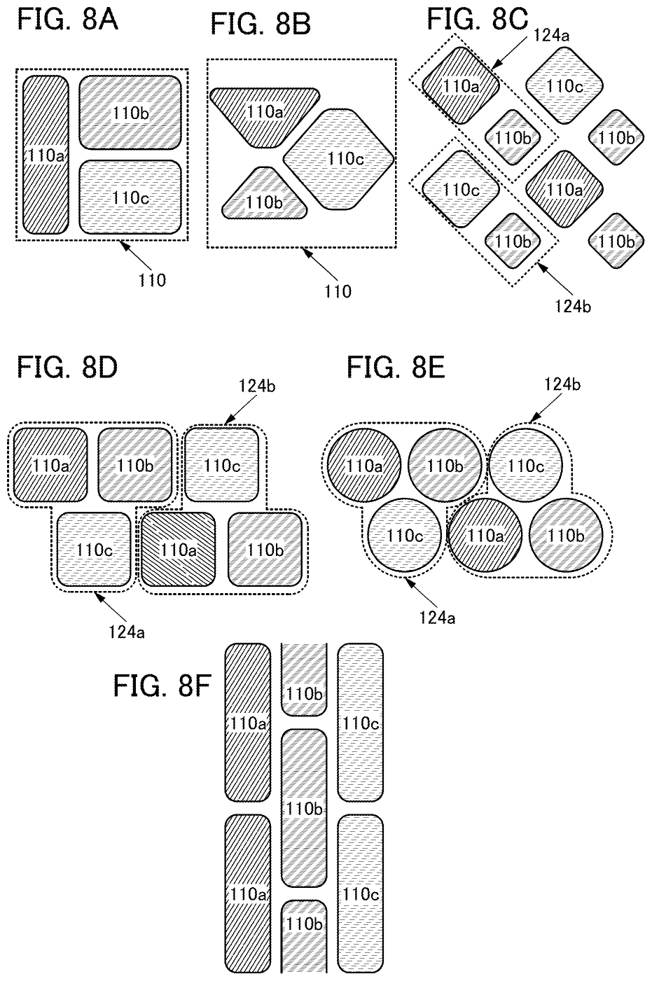

In this embodiment, a display panel of one embodiment of the present invention is described with reference to FIG. 8 to FIG. 11.

### [Pixel Layout]

In this embodiment, pixel layouts different from that in FIG. 1A will be mainly described. There is no particular limitation on the arrangement of subpixels, and any of a variety of methods can be employed. Examples of the arrangement of subpixels include stripe arrangement, S-stripe arrangement, matrix arrangement, delta arrangement, Bayer arrangement, and PenTile arrangement.

Each subpixel includes, for example, a light-emitting element. In addition, each subpixel includes a light-emitting element and a coloring layer provided to overlap with the light-emitting element.

Examples of a top surface shape of the subpixel include polygons such as a triangle, a tetragon (including a rectangle and a square), and a pentagon; polygons with rounded corners; an ellipse; and a circle. Here, a top surface shape of the subpixel corresponds to a top surface shape of a light-emitting region of the light-emitting element.

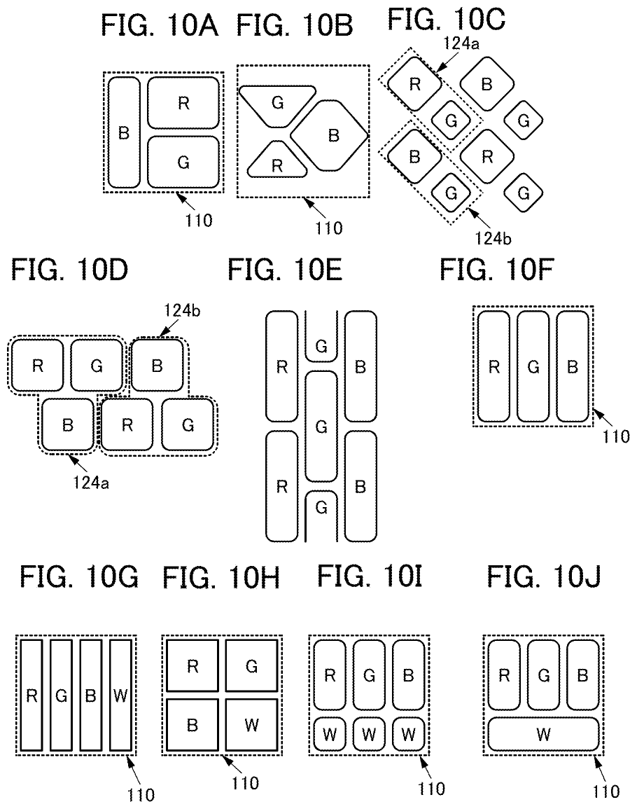

A pixel 110 illustrated in FIG. 8A employs S-stripe arrangement. The pixel 110 illustrated in FIG. 8A consists of the three subpixels 110a, 110b, and 110c. For example, the subpixel 110a may be a blue subpixel B, the subpixel 110b may be a red subpixel R, and the subpixel 110c may be a green subpixel G as illustrated in FIG. 10A. The subpixels B, R, and G respectively include the light-emitting elements 110B, 110R, and 110G described in the above embodiment.

The pixel 110 illustrated in FIG. 8B includes the subpixel 110a whose top surface shape is a rough trapezoid with rounded corners, the subpixel 110b whose top surface shape is a rough triangle with rounded corners, and the subpixel 110c whose top surface shape is a rough tetragon or a rough hexagon with rounded corners. The subpixel 110a has a larger light-emitting area than the subpixel 110b. In this manner, the shapes and sizes of the subpixels can be determined independently. For example, the size of a subpixel including a light-emitting element with higher reliability can be smaller. For example, the subpixel 110a may be the green subpixel G, the subpixel 110b may be the red subpixel R, and the subpixel 110c may be the blue subpixel B as illustrated in FIG. 10B.

Pixels 124a and 124b illustrated in FIG. 8C employ PenTile arrangement. FIG. 8C illustrates an example in which the pixel 124a including the subpixel 110a and the subpixel 110b and the pixel 124b including the subpixel 110b and the subpixel 110c are alternately arranged. For example, the subpixel 110a may be the red subpixel R, the subpixel 110b may be the green subpixel G, and the subpixel 110c may be the blue subpixel B as illustrated in FIG. 10C.

The pixels 124a and 124b illustrated in FIG. 8D and FIG. 8E employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row). For example, the subpixel 110a may be the red subpixel R, the subpixel 110b may be the green subpixel G, and the subpixel 110c may be the blue subpixel B as illustrated in FIG. 10D.

FIG. 8D illustrates an example where a top surface shape of each subpixel is a rough tetragon with rounded corners, and FIG. 8E shows an example where a top surface shape of each subpixel is a circle.

FIG. 8F illustrates an example where subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in a top view. For example, the subpixel 110a may be the red subpixel R, the subpixel 110b may be the green subpixel G, and the subpixel 110c may be the blue subpixel B as illustrated in FIG. 10E.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, a top surface shape of a subpixel is a polygon with rounded corners, an ellipse, a circle, or the like, in some cases.

Furthermore, in the method for fabricating the display panel of one embodiment of the present invention, the EL layer is processed into an island shape with the use of a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape by processing. As a result, a top surface shape of the EL layer may be a polygon with rounded corners, an ellipse, a circle, or the like. For example, when a resist mask whose top surface shape is a square is intended to be formed, a resist mask whose top surface shape is a circle may be formed, and the top surface shape of the EL layer may be a circle.

Note that to obtain a desired top surface shape of the EL layer, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

Note that in the pixel 110 illustrated in FIG. 1A, which employs stripe arrangement, the subpixel 110R can be the red subpixel R, the subpixel 110G can be the green subpixel G, and the subpixel 110B can be the blue subpixel B as illustrated in FIG. 10F, for example.

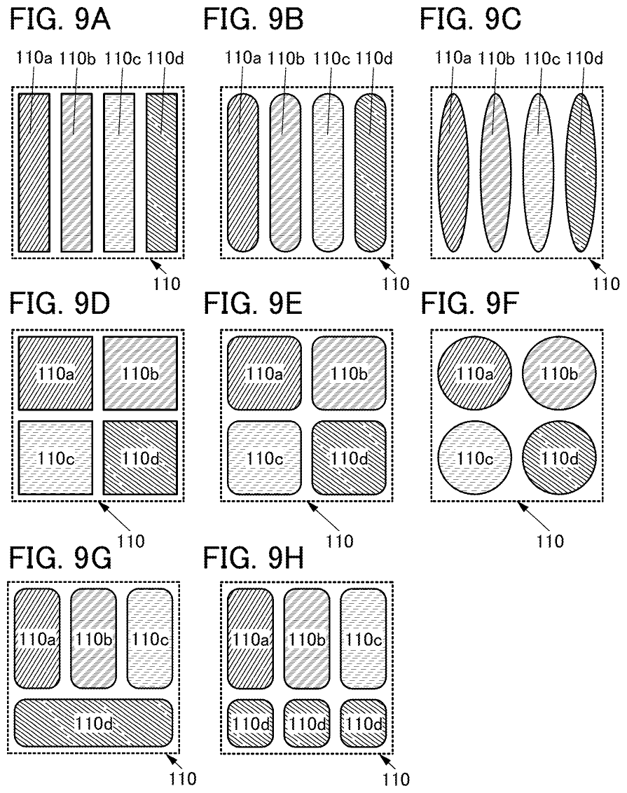

As illustrated in FIG. 9A to FIG. 9H, the pixel can include four types of subpixels.

The pixels 110 illustrated in FIG. 9A to FIG. 9C each employ stripe arrangement.

FIG. 9A illustrates an example in which each subpixel has a rectangular top surface shape, FIG. 9B illustrates an example in which each subpixel has a top surface shape formed by combining two half circles and a rectangle, and FIG. 9C illustrates an example in which each subpixel has an elliptical top surface shape.

The pixels 110 illustrated in FIG. 9D to FIG. 9F each employ matrix arrangement.

FIG. 9D illustrates an example in which each subpixel has a square top surface shape, FIG. 9E illustrates an example in which each subpixel has a substantially square top surface shape with rounded corners, and FIG. 9F illustrates an example in which each subpixel has a circular top surface shape.

FIG. 9G and FIG. 9H each illustrate an example in which one pixel 110 is composed of two rows and three columns.

The pixel 110 illustrated in FIG. 9G includes three subpixels (the subpixels 110a, 110b, and 110c) in the upper row (first row) and one subpixel (a subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 9H includes three subpixels (the subpixels 110a, 110b, and 110c) in the upper row (first row) and three subpixels 110d in the lower row (second row). In other words, the pixel 110 includes the subpixel 110a and the subpixel 110d in the left column (first column), the subpixel 110b and the subpixel 110d in the center column (second column), and the subpixel 110c and the subpixel 110d in the right column (third column). Aligning the positions of the subpixels in the upper row and the lower row as illustrated in FIG. 9H enables dust and the like that would be produced in the manufacturing process to be removed efficiently. Thus, a display panel having high display quality can be provided.

The pixels 110 illustrated in FIG. 9A to FIG. 9H each consist of the four subpixels 110a, 110b, 110c, and 110d. The subpixels 110a, 110b, 110c, and 110d include light-emitting elements that emit light of different colors. The subpixels 110a, 110b, 110c, and 110d can be subpixels of four colors of R, G, B, and white (W), subpixels of four colors of R, G, B, and Y, or subpixels of R, G, B, and infrared light (IR), for example. As illustrated in FIG. 10G to FIG. 10J, the subpixels 110a, 110b, 110c, and 110d can be, respectively, red, green, blue, and white subpixels, for example.

The display panel of one embodiment of the present invention may include a light-receiving element in the pixel.

Three of the four subpixels included in each of the pixels 103 illustrated in FIG. 10G to FIG. 10J may include a light-emitting element and the other one may include a light-receiving element.

For example, the subpixels 110a, 110b, and 110c may be subpixels of three colors of R, G, and B, and the subpixel 110d may be a subpixel including the light-receiving element.

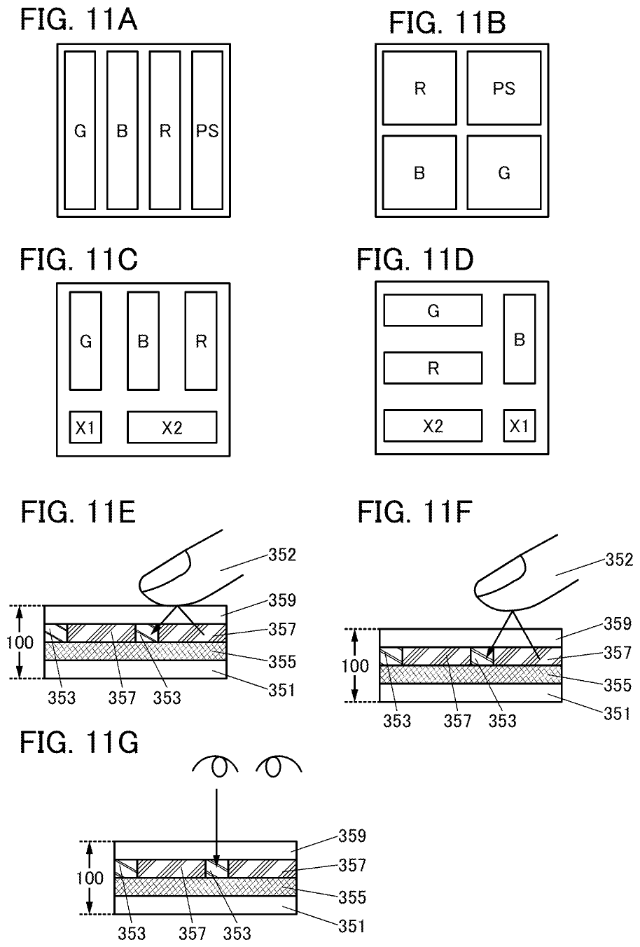

The pixels illustrated in FIG. 11A and FIG. 11B each include the subpixel G, the subpixel B, the subpixel R, and a subpixel PS. Note that the arrangement order of the subpixels is not limited to the structures illustrated in the drawings and can be determined as appropriate. For example, the positions of the subpixel G and the subpixel R may be reversed.

The pixel illustrated in FIG. 11A employs stripe arrangement. The pixel illustrated in FIG. 11B employs matrix arrangement.

The subpixel R includes a light-emitting element that emits red light. The subpixel G includes a light-emitting element that emits green light. The subpixel B includes a light-emitting element that emits blue light.

The subpixel PS includes a light-receiving element. There is no particular limitation on the wavelength of light detected by the subpixel PS. The subpixel PS can have a structure in which one or both of visible light and infrared light can be detected.

The pixels illustrated in FIG. 11C and FIG. 11D each include the subpixel G, the subpixel B, the subpixel R, a subpixel X1, and a subpixel X2. Note that the arrangement order of the subpixels is not limited to the structures illustrated in the drawings and can be determined as appropriate. For example, the positions of the subpixel G and the subpixel R may be reversed.

FIG. 11C illustrates an example in which one pixel is provided in two rows and three columns. Three subpixels (the subpixel G, the subpixel B, and the subpixel R) are provided in the upper row (first row). In FIG. 11C, two subpixels (the subpixel X1 and the subpixel X2) are provided in the lower row (second row).

FIG. 11D illustrates an example in which one pixel is provided in three rows and two columns. In FIG. 11D, the pixel includes the subpixel G in the first row, the subpixel R in the second row, and the subpixel B in the first and second rows. In addition, two subpixels (the subpixel X1 and the subpixel X2) are provided in the third row. In other words, the pixel illustrated in FIG. 11D includes three subpixels (the subpixel G, the subpixel R, and the subpixel X2) in the left column (first column) and two subpixels (the subpixel B and the subpixel X1) in the right column (second column).

The layout of the subpixels R, G, and B in FIG. 11C is stripe arrangement. The layout of the subpixels R, G, and B in FIG. 11D is what is called S stripe arrangement. Thus, high display quality is possible.

At least one of the subpixel X1 and the subpixel X2 preferably includes the light-receiving element (also referred to the subpixel PS).

Note that the layout of the pixels including the subpixel PS is not limited to the structures illustrated in FIG. 11A to FIG. 11D.

The subpixel X1 or the subpixel X2 can include a light-emitting element that emits infrared light (IR), for example. In this case, the subpixel PS preferably detects infrared light. For example, while an image is displayed using the subpixels R, G, and B, reflected light of the light emitted from one of the subpixel X1 and the subpixel X2 as a light source can be detected by the other of the subpixel X1 and the subpixel X2.

In addition, both the subpixel X1 and the subpixel X2 can be configured to include the light-receiving element. In this case, the wavelength ranges of the light detected by the subpixel X1 and the subpixel X2 may be the same, different, or partially the same. For example, one of the subpixel X1 and the subpixel X2 mainly detects visible light while the other mainly detects infrared light.

The light-receiving area of the subpixel X1 is smaller than the light-receiving area of the subpixel X2. A smaller light-receiving area leads to a narrower image-capturing range, inhibits a blur in a captured image, and improves the definition. Thus, the use of the subpixel X1 enables higher-resolution or higher-definition image capturing than the use of a light-receiving element included in the subpixel X2. For example, image capturing for personal authentication with the use of a fingerprint, a palm print, the iris, the shape of a blood vessel (including the shape of a vein and the shape of an artery), a face, or the like can be performed by using the subpixel X1.

The light-receiving element included in the subpixel PS preferably detects visible light, and preferably detects one or more of blue light, violet light, bluish violet light, green light, greenish yellow light, yellow light, orange light, red light, and the like. The light-receiving element included in the subpixel PS may detect infrared light.

Moreover, in the case where a structure including a light-receiving element in the subpixel X2 is employed, the subpixel X2 can be used in a touch sensor (also referred to as a direct touch sensor), a near touch sensor (also referred to as a hover sensor, a hover touch sensor, a contactless sensor, or a touchless sensor), or the like. The wavelength of light detected by the subpixel X2 can be determined as appropriate depending on the application purpose. For example, the subpixel X2 preferably detects infrared light. Thus, touch can be detected even in a dark place.

Here, the touch sensor or the near touch sensor can detect the approach or contact of an object (e.g., a finger, a hand, or a pen).

The touch sensor can detect an object when the display panel and the object come in direct contact with each other. Furthermore, even when an object is not in contact with the display panel, the near touch sensor can detect the object. For example, the display panel is preferably capable of detecting an object when the distance between the display panel and the object is greater than or equal to 0.1 mm and less than or equal to 300 mm, preferably greater than or equal to 3 mm and less than or equal to 50 mm. This structure enables the display panel to be operated without direct contact of an object; in other words, the display panel can be operated in a contactless (touchless) manner. With the above-described structure, the display panel can have a reduced risk of being dirty or damaged, or can be operated without the object directly touching a dirt (e.g., dust or a virus) attached to the display panel.

The refresh rate of the display panel of one embodiment of the present invention can be variable. For example, the refresh rate is adjusted (adjusted in the range from 1 Hz to 240 Hz, for example) in accordance with contents displayed on the display panel, whereby power consumption can be reduced. The driving frequency of the touch sensor or the near touch sensor may be changed in accordance with the refresh rate. In the case where the refresh rate of the display panel is 120 Hz, for example, the driving frequency of the touch sensor or the near touch sensor can be higher than 120 Hz (typically 240 Hz). With this structure, low power consumption can be achieved, and the response speed of the touch sensor or the near touch sensor can be increased.

The display apparatus 100 illustrated in FIG. 11E to FIG. 11G includes a layer 353 including a light-receiving element, a functional layer 355, and a layer 357 including a light-emitting element between a substrate 351 and a substrate 359.

The functional layer 355 includes a circuit for driving the light-receiving element and a circuit for driving the light-emitting element. A switch, a transistor, a capacitor, a resistor, a wiring, a terminal, and the like can be provided in the functional layer 355. Note that in the case where the light-emitting element and the light-receiving element are driven by a passive-matrix method, a structure not provided with a switch or a transistor may be employed.

For example, light emitted from the light-emitting element in the layer 357 including the light-emitting element is reflected by a finger 352 that touches the display apparatus 100 as illustrated in FIG. 11E, and the light-receiving element in the layer 353 including the light-receiving device detects the reflected light. Thus, the touch of the finger 352 on the display apparatus 100 can be detected.

The display panel may have a function of detecting an object that is close to (but is not touching) the display panel as illustrated in FIG. 11F and FIG. 11G or capturing an image of such an object. FIG. 11F illustrates an example in which a human finger is detected, and FIG. 11G illustrates an example in which information on the surroundings, surface, or inside of the human eye (e.g., the number of blinks, the movement of an eyeball, and the movement of an eyelid) is detected.

In the display panel in this embodiment, an image of the periphery, surface, or inside (e.g., fundus) of an eye of a user of a wearable device can be captured with the use of the light-receiving element. Therefore, the wearable device can have a function of detecting one or more selected from blinking, movement of an iris, and movement of an eyelid of the user.

As described above, the pixel composed of the subpixels each including the light-emitting element can employ any of a variety of layouts in the display panel of one embodiment of the present invention. The display panel of one embodiment of the present invention can have a structure in which the pixel includes both a light-emitting element and a light-receiving element. Also in this case, any of a variety of layouts can be employed.

This embodiment can be combined with the other embodiments as appropriate.

### Embodiment 3

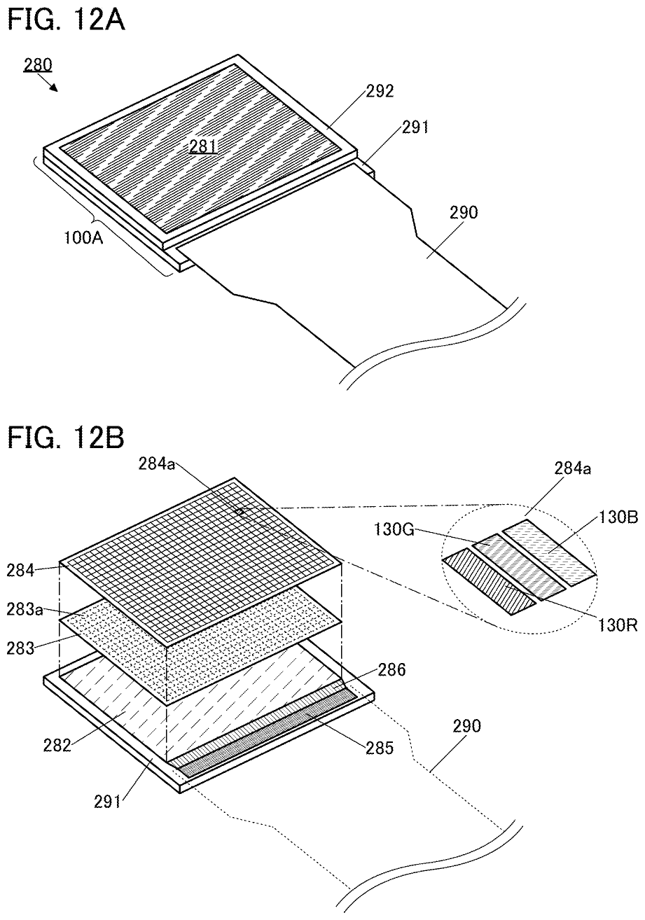

In this embodiment, the display panel of one embodiment of the present invention will be described with reference to FIG. 12 to FIG. 18.

The display panel in this embodiment can be a high-resolution display panel. Accordingly, the display panel in this embodiment can be used for display portions of information terminals (wearable devices) such as watch-type and bracelet-type information terminals and display portions of wearable devices capable of being worn on the head, such as a VR device like a head mounted display and a glasses-type AR device.

The display panel of this embodiment can be a high-definition display panel or a large-sized display panel. Accordingly, the display panel of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

In the display panel of this embodiment, since the light-emitting elements of different colors are separately formed, the difference between the chromaticity at low luminance emission and that at high luminance emission is small. Furthermore, since the EL layers of the respective light-emitting elements are separated from each other, crosstalk generated between adjacent subpixels can be prevented while the display panel of this embodiment has high resolution. Accordingly, the display panel can have high resolution and high display quality.

Thus, the display panel of this embodiment can be used for one or both of the wearable display apparatus and the terminal in a display system of one embodiment of the present invention.

### [Display Module]

FIG. 12A is a perspective view of a display module 280. The display module 280 includes the display apparatus 100A and an FPC 290. Note that the display panel included in the display module 280 is not limited to the display apparatus 100A and may be any of a display apparatus 100B to a display apparatus 100F described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 12B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 12B. The pixel 284a includes a light-emitting element 110R that emits red light, a light-emitting element 110G that emits green light, and a light-emitting element 110B that emits blue light.

The pixel circuit portion 283 includes a plurality of pixel circuits 283a arranged periodically.

One pixel circuit 283a is a circuit that controls light emission of three light-emitting elements included in one pixel 284a. One pixel circuit 283a may include three circuits each of which controls light emission of one light-emitting element. For example, the pixel circuit 283a can include at least one selection transistor, one current control transistor (driving transistor), and a capacitor for one light-emitting element. In this case, a gate signal is input to a gate of the selection transistor, and a source signal is input to a source of the selection transistor. Thus, an active-matrix display panel is obtained.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are provided to be stacked below the pixel portion 284; hence, the aperture ratio (effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a VR device such as a head mounted display or a glasses-type AR device. For example, even with a structure in which the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be favorably used in a display portion of a wearable electronic device, such as a wrist watch.

### [Display Apparatus 100A]

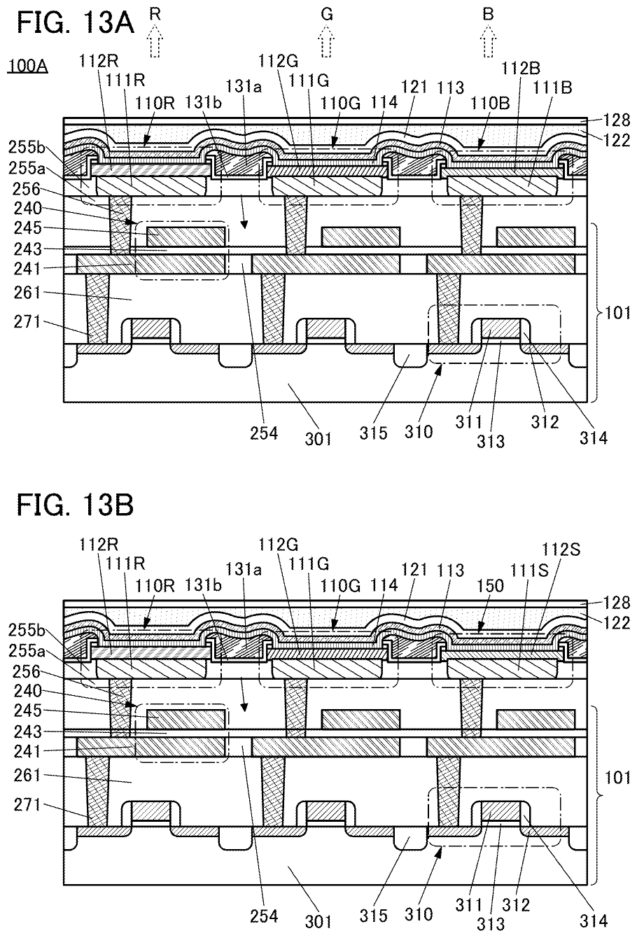

The display apparatus 100A illustrated in FIG. 13A includes a substrate 301, the light-emitting devices 110R, 110G and 110B, a capacitor 240, and a transistor 310.

The substrate 301 corresponds to the substrate 291 in FIG. 12A and FIG. 12B. A stacked-layer structure including the substrate 301 and the components thereover up to the capacitor 240 corresponds to the substrate 101 including transistors in Embodiment 1. Note that FIG. 12A and FIG. 12B illustrate an example where the structure illustrated in FIG. 1B is used for the light-emitting elements 110R, 110G, and 110B, but the structure illustrated in FIG. 1C, FIG. 2A, FIG. 2B, FIG. 2C, FIG. 6, or the like can be used.

The transistor 310 includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance regions 312 are regions where the substrate 301 is doped with an impurity, and function as one of a source and a drain. The insulating layer 314 is provided to cover the side surface of the conductive layer 311 and functions as an insulating layer.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between these conductive layers. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, and an insulating layer 255b is provided over the insulating layer 255a.

As each of the insulating layer 255a and the insulating layer 255b, a variety of inorganic insulating films such as an oxide insulating film, a nitride insulating film, an oxynitride insulating film, and a nitride oxide insulating film can be suitably used. As each of the insulating layer 255a and the insulating layer 255b, an oxide insulating film or an oxynitride insulating film, such as a silicon oxide film, a silicon oxynitride film, or an aluminum oxide film, is preferably used. The insulating layer 255a can have a stacked-layer structure. For example, an oxide insulating film or an oxynitride insulating film can be used as a lower layer of a stacked-layer structure, and a nitride insulating film or a nitride oxide insulating film such as a silicon nitride film, a silicon nitride oxide film, or the like can be used as an upper layer. Specifically, it is preferred that a silicon oxide film be used as the lower layer of the insulating layer 255a and a silicon nitride film be used as the upper layer of the insulating layer 255a. The upper layer of the insulating layer 255a preferably has a function of an etching protective film.

The light-emitting element 110R, the light-emitting element 110G, and the light-emitting element 110B are provided over the insulating layer 255b. FIG. 13A illustrates an example in which the light-emitting element 110R, the light-emitting element 110G, and the light-emitting element 110B each have the stacked-layer structure illustrated in FIG. 1B.

An insulator is provided in a region between adjacent light-emitting elements. In FIG. 13A and the like, the insulating layer 131b and the resin layer 131a over the insulating layer 131b are provided in the region.

The conductive layer 111 functioning as the pixel electrode of the light-emitting element is electrically connected to one of the source and the drain of the transistor 310 through the plug 256 embedded in the insulating layer 255a and the insulating layer 255b, the conductive layer 241 embedded in the insulating layer 254, and the plug 271 embedded in the insulating layer 261. For the conductive layer 111 and the plug 256, the description in Embodiment 1 can be referred to.

The protective layer 121 is provided over the light-emitting element 110R, the light-emitting element 110G, and the light-emitting element 110B. The substrate 128 is attached over the protective layer 121 with the resin layer 122. Embodiment 1 can be referred to for details of the components of the light-emitting elements.

As described in Embodiment 1, a coloring layer may be provided so as to overlap with the light-emitting element 110.

A light-blocking layer may be provided on the surface of the substrate 128 on the resin layer 122 side. A variety of optical members can be arranged on the outer surface of the substrate 128. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film suppressing the attachment of stain, a hard coat film inhibiting generation of a scratch caused by the use, a surface protective layer such as an impact-absorbing layer, may be provided on the outer surface of the substrate 128. For example, a glass layer or a silica layer (SiOx layer) is preferably provided as the surface protective layer to inhibit the surface contamination and generation of a scratch. The surface protective layer may be formed using DLC (diamond like carbon), aluminum oxide (AlOₓ), a polyester-based material, a polycarbonate-based material, or the like. Note that for the surface protective layer, a material having a high transmittance with respect to visible light is preferably used. The surface protective layer is preferably formed using a material with high hardness.

For the substrate 128, glass, quartz, ceramic, sapphire, a resin, a metal, an alloy, a semiconductor, or the like can be used. The substrate on the side where light from the light-emitting element is extracted is formed using a material that transmits the light. When a flexible material is used for the substrate 128, the flexibility of the display panel can be increased. Furthermore, a polarizing plate may be used as the substrate 128.

For the substrate 128, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 128.

Note that in the case where a circularly polarizing plate overlaps with the display panel, a highly optically isotropic substrate is preferably used as the substrate included in the display panel. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the film having high optical isotropy include a triacetyl cellulose (TAC, also referred to as cellulose triacetate) film, a cycloolefin polymer (COP) film, a cycloolefin copolymer (COC) film, and an acrylic film.

In the case where a film is used for the substrate and the film absorbs water, the shape of the display panel might be changed, e.g., creases are generated. Thus, for the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

For the resin layer 122, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. Alternatively, a two-liquid-mixture-type resin may be used. An adhesive sheet or the like may be used.

Although the display apparatus 100A includes the light-emitting elements 110R, 110G, and 110B in this example, the display panel of this embodiment may further include the light-receiving element.

The display panel illustrated in FIG. 13B includes the light-emitting elements 110R and 110G and a light-receiving element 150. The light-receiving element 150 has a stack of a conductive layer 111S, an active layer 112S, the common layer 114, and the common electrode 113. The conductive layer 111S can be fabricated using materials and a method similar to those of the conductive layer 111 in Embodiment 1. A photoelectric conversion element (also referred to a photoelectric conversion device) can be used as the light-receiving element 150. One or both of an inorganic semiconductor and an organic semiconductor can be used for an active layer of the photoelectric conversion element.

### [Display Apparatus 100B]

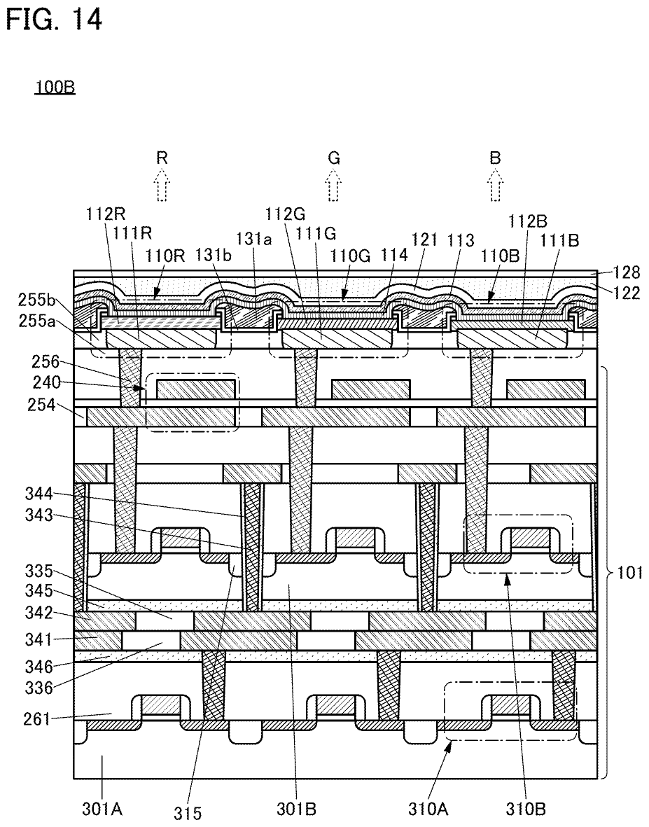

The display apparatus 100B illustrated in FIG. 14 has a structure where a transistor 310A and a transistor 310B in each of which a channel is formed in a semiconductor substrate are stacked. Note that in the description of the display panel below, components similar to those of the above-mentioned display panel are not described in some cases.

In the display apparatus 100B, a substrate 301B provided with the transistor 310B, the capacitor 240, and light-emitting elements is bonded to a substrate 301A provided with the transistor 310A.

Here, an insulating layer 345 is preferably provided on the bottom surface of the substrate 301B. An insulating layer 346 is preferably provided over the insulating layer 261 over the substrate 301A. The insulating layers 345 and 346 function as protective layers and can inhibit diffusion of impurities into the substrate 301B and the substrate 301A. As the insulating layers 345 and 346, an inorganic insulating film that can be used as the protective layer 121 or the insulating layer 332 can be used.

The substrate 301B is provided with a plug 343 that penetrates the substrate 301B and the insulating layer 345. An insulating layer 344 is preferably provided to cover the side surface of the plug 343. The insulating layer 344 functions as a protective layer and can inhibit diffusion of impurities into the substrate 301B. As the insulating layer 344, an inorganic insulating film that can be used as the protective layer 121 can be used.

A conductive layer 342 is provided under the insulating layer 345 on the rear surface of the substrate 301B (the surface opposite to the substrate 128). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

A conductive layer 341 is provided over the insulating layer 346 over the substrate 301A. The conductive layer 341 is preferably provided to be embedded in the insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the planarity of a plane formed by the conductive layer 342 and the insulating layer 335 and a plane formed by the conductive layer 341 and the insulating layer 336 allows the conductive layer 341 and the conductive layer 342 to be bonded to each other favorably.

The conductive layer 341 and the conductive layer 342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layer 341 and the conductive layer 342. In that case, it is possible to employ Cu—Cu (copper-to-copper) direct bonding (a technique for achieving electrical continuity by connecting Cu (copper) pads).

### [Display Apparatus 100C]

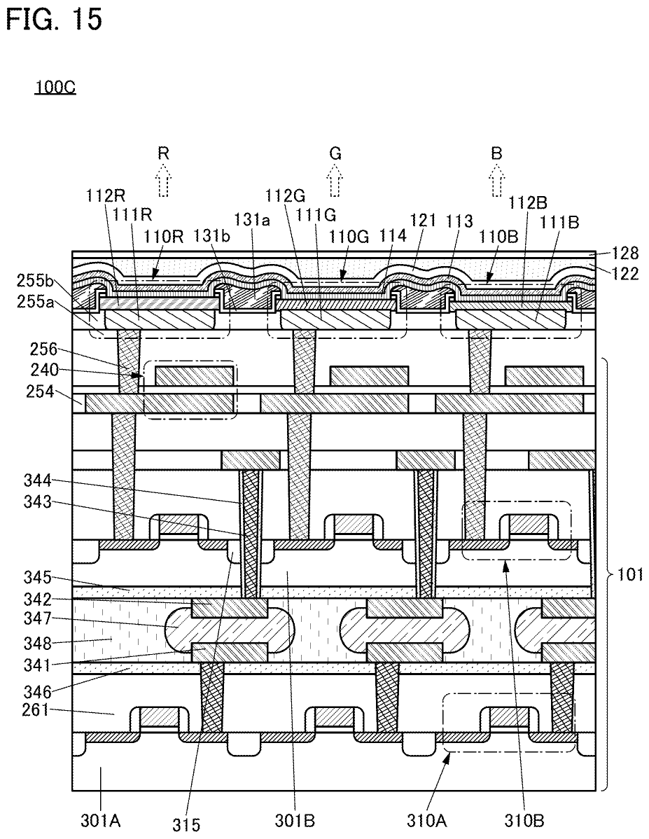

The display apparatus 100C illustrated in FIG. 15 has a structure in which the conductive layer 341 and the conductive layer 342 are bonded to each other through a bump 347.

As illustrated in FIG. 15, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. For another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Apparatus 100D]

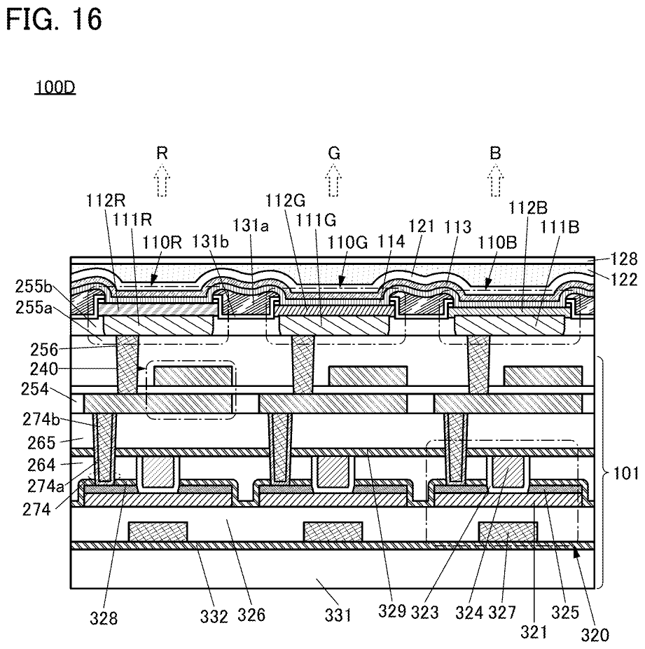

A display apparatus 100D illustrated in FIG. 16 differs from the display apparatus 100A mainly in a structure of a transistor.

A transistor 320 is a transistor (OS transistor) that contains a metal oxide (also referred to as an oxide semiconductor) in its semiconductor layer where a channel is formed. An oxide semiconductor having crystallinity is preferably used for a channel formation region of the OS transistor.

As the oxide semiconductor having crystallinity, a CAAC (c-axis aligned crystalline)-OS, an nc (nanocrystalline)-OS, and the like are given.

A transistor using silicon in a channel formation region (a Si transistor) may be used as the transistor 320. For example, a transistor using polycrystalline silicon, amorphous silicon, or the like is used in a channel formation region may be used as the transistor 320. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of a Si transistors such as an LTPS transistor, a circuit required to be driven at a high frequency (e.g., a source driver circuit) can be formed on the same substrate as the display portion. Thus, external circuits mounted on the display panel can be simplified, whereby parts costs and mounting costs can be reduced.

An OS transistor has extremely higher field-effect mobility than a transistor containing amorphous silicon. In addition, an OS transistor has an extremely low leakage current between a source and a drain in an off state (hereinafter, also referred to as off-state current), and charge accumulated in a capacitor that is connected in series to the transistor can be retained for a long period. Furthermore, power consumption of the display panel can be reduced with the use of an OS transistor.

The off-state current value per micrometer of channel width of an OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than the off-state current of a Si transistor by approximately ten orders of magnitude.

To increase the emission luminance of the light-emitting element included in the pixel circuit, the amount of current flowing through the light-emitting element needs to be increased. For that purpose, the source-drain voltage of the driving transistor included in the pixel circuit needs to be increased. Since an OS transistor has a higher withstand voltage between the source and the drain than a Si transistor, a high voltage can be applied between the source and the drain of an OS transistor. Accordingly, when an OS transistor is used as the driving transistor included in the pixel circuit, the amount of current flowing through the light-emitting element can be increased, so that the emission luminance of the light-emitting element can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be set minutely by a change in gate-source voltage; hence, the amount of current flowing through the light-emitting element can be controlled. Accordingly, the number of gray level in the pixel circuit can be increased.

Regarding saturation characteristics of current flowing when a transistor operates in a saturation region, even in the case where the source-drain voltage of an OS transistor increases gradually, more stable constant current (saturation current) can be fed through an OS transistor than through a Si transistor. Thus, by using an OS transistor as the driving transistor, stable constant current can be fed through a light-emitting element even when the current-voltage characteristics of an EL device vary, for example. In other words, when an OS transistor operates in a saturation region, the source-drain current hardly changes with an increase in the source-drain voltage; hence, the emission luminance of the light-emitting element can be stable.

As described above, the use of the OS transistor as the driving transistor included in the pixel circuit enables “inhibition of black floating”, “an increase in emission luminance”, “an increase in gray levels”, “inhibition of variation in light-emitting elements”, and the like.

The semiconductor layer preferably contains indium, M (M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin.

It is particularly preferable that an oxide containing indium (In), gallium (Ga), and zinc (Zn) (also referred to as IGZO) be used as the semiconductor layer. Alternatively, it is preferable to use an oxide containing indium, tin, and zinc. Further alternatively, it is preferable to use an oxide containing indium, gallium, tin, and zinc. Alternatively, it is preferable to use an oxide containing indium (In), aluminum (Al), and zinc (Zn) (also referred to as IAZO) for the semiconductor layer. Further alternatively, it is preferable to use an oxide containing indium (In), aluminum (Al), gallium (Ga), and zinc (Zn) (also referred to as IAGZO).

When the semiconductor layer is an In-M-Zn oxide, the atomic proportion of In is preferably greater than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, in the case of describing an atomic ratio of In:Ga:Zn=4:2:3 or a composition in the neighborhood thereof, the case is included in which with the atomic ratio of In being 4, the atomic ratio of Ga is greater than or equal to 1 and less than or equal to 3 and the atomic ratio of Zn is greater than or equal to 2 and less than or equal to 4. In the case of describing an atomic ratio of In:Ga:Zn=5:1:6 or a composition in the neighborhood thereof, the case is included in which with the atomic ratio of In being 5, the atomic ratio of Ga is greater than 0.1 and less than or equal to 2 and the atomic ratio of Zn is greater than or equal to 5 and less than or equal to 7. In the case of describing an atomic ratio of In:Ga:Zn=1:1:1 or a composition in the neighborhood thereof, the case is included in which with the atomic ratio of In being 1, the atomic ratio of Ga is greater than 0.1 and less than or equal to 2 and the atomic ratio of Zn is greater than 0.1 and less than or equal to 2.

The transistor included in the circuit portion 282 and the transistor included in the pixel circuit portion 283 may have the same structure or different structures. One structure or two or more kinds of structures may be employed for a plurality of transistors included in the circuit portion 282. Similarly, one structure or two or more kinds of structures may be employed for a plurality of transistors included in the pixel circuit portion 283.

All of the transistors included in the pixel circuit portion 283 may be OS transistors or all of the transistors included in the pixel circuit portion 283 may be Si transistors; alternatively, some of the transistors included in the pixel circuit portion 283 may be OS transistors and the others may be Si transistors.

For example, when both an LTPS transistor and an OS transistor are used in the pixel circuit portion 283, the display panel can have low power consumption and high drive capability. A structure where an LTPS transistor and an OS transistor are used in combination is referred to as LTPO in some cases. Note that as a more preferable example, it is preferable to use an OS transistor as a transistor or the like functioning as a switch for controlling electrical continuity between wirings and an LTPS transistor as a transistor or the like for controlling current.

For example, one of the transistors included in the pixel circuit portion 283 functions as a transistor for controlling current flowing through the light-emitting element and can be referred to as a driving transistor. One of a source and a drain of the driving transistor is electrically connected to the pixel electrode of the light-emitting element. An LTPS transistor is preferably used as the driving transistor. In this case, the amount of current flowing through the light-emitting element can be increased in the pixel circuit.

Another transistor included in the pixel circuit portion 283 functions as a switch for controlling selection and non-selection of the pixel and can be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

As described above, the display panel of one embodiment of the present invention can have all of a high aperture ratio, a high resolution, high display quality, and low power consumption.

Note that the display panel of one embodiment of the present invention has a structure including the OS transistor and the light-emitting element having an MML (metal maskless) structure. With this structure, leakage current that might flow through the transistor and leakage current that might flow between adjacent light-emitting elements (also referred to as lateral leakage current, side leakage current, or the like) can become extremely low. With the above structure, a viewer can notice any one or more of the image crispness, the image sharpness, a high chroma, and a high contrast ratio in an image displayed on the display panel. Note that with the structure where the leakage current that might flow through the transistor and the lateral leakage current that might flow between light-emitting elements are extremely low, display with little leakage of light at the time of black display can be achieved.

The structure of the transistors used in the display panel may be selected as appropriate depending on the size of the screen of the display panel. For example, single crystal Si transistors can be used in the display panel with a screen diagonal greater than or equal to 0.1 inches and less than or equal to 3 inches. In addition, LTPS transistors can be used in the display panel with a screen diagonal greater than or equal to 0.1 inches and less than or equal to 30 inches, preferably greater than or equal to 1 inch and less than or equal to 30 inches. In addition, an LTPO structure (where an LTPS transistor and an OS transistor are used in combination) can be used in the display panel with a screen diagonal greater than or equal to 0.1 inches and less than or equal to 50 inches, preferably greater than or equal to 1 inch and less than or equal to 50 inches. In addition, OS transistors can be used in the display panel with a screen diagonal greater than or equal to 0.1 inches and less than or equal to 200 inches, preferably greater than or equal to 50 inches and less than or equal to 100 inches.

Note that with single crystal Si transistors, a size increase is extremely difficult because of the size of a single crystal Si substrate. Furthermore, since a laser crystallization apparatus is used in the manufacturing process, LTPS transistors are unlikely to respond to a size increase (typically to a screen diagonal greater than 30 inches). By contrast, since the manufacturing process does not necessarily require a laser crystallization apparatus or the like or can be performed at a relatively low process temperature (typically, lower than or equal to 450° C.), OS transistors can be used for a display panel with a relatively large area (typically, a screen diagonal greater than or equal to 50 inches and less than or equal to 100 inches). In addition, LTPO can be applied to a display panel with a size (typically, a screen diagonal greater than or equal to 1 inch and less than or equal to 50 inches) midway between the case of using LTPS transistors and the case of using OS transistors.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 illustrated in FIG. 12A and FIG. 12B. A stacked-layer structure including the substrate 331 and the components thereover up to the capacitor 240 corresponds to the substrate 101 including transistors in Embodiment 1. As the substrate 331, an insulating substrate or a semiconductor substrate can be used.

The insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide film having semiconductor characteristics (also referred to as an oxide semiconductor). The pair of conductive layers 325 is provided over and in contact with the semiconductor layer 321 and functions as a source electrode and a drain electrode.

An insulating layer 328 is provided to cover the top surfaces and the side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. As the insulating layer 328, an insulating film similar to the above insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that their levels are the same or substantially the same, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water or hydrogen from the insulating layer 265 or the like into the transistor 320. For the insulating layer 329, an insulating film similar to the above insulating layer 328 and the above insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a that covers the side surface of an opening formed in the insulating layer 265, the insulating layer 329, the insulating layer 264, and the insulating layer 328 and part of the top surface of the conductive layer 325, and a conductive layer 274b in contact with the top surface of the conductive layer 274a. For the conductive layer 274a, a conductive material that does not easily allow diffusion of hydrogen and oxygen is preferably used.

### [Display Apparatus 100E]

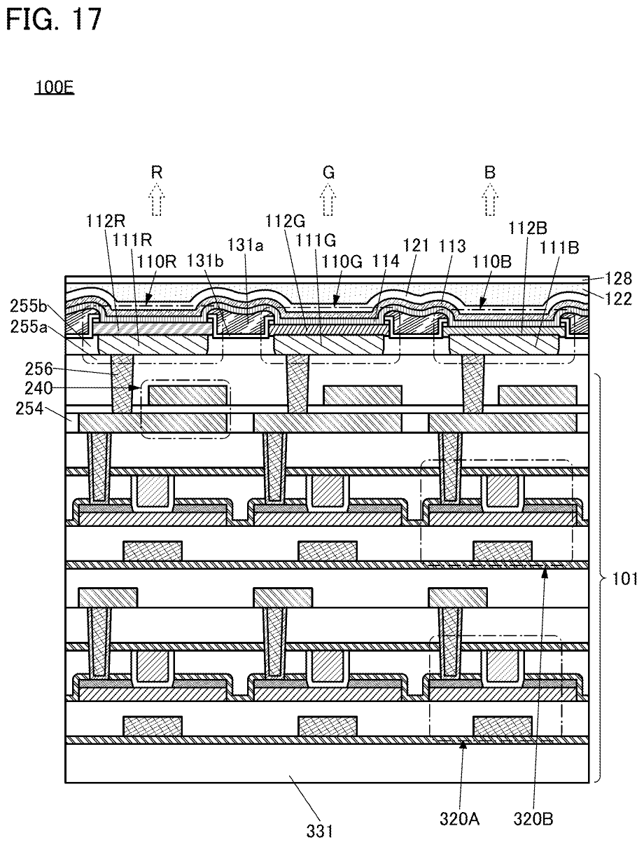

A display apparatus 100E illustrated in FIG. 17 has a structure in which a transistor 320A and a transistor 320B each including an oxide semiconductor in a semiconductor where a channel is formed are stacked.

The above display apparatus 100D can be referred to for the transistor 320A, the transistor 320B, and other peripheral structures.

Although the structure where two transistors including an oxide semiconductor are stacked is described, the present invention is not limited thereto. For example, three or more transistors may be stacked.

### [Display Apparatus 100F]

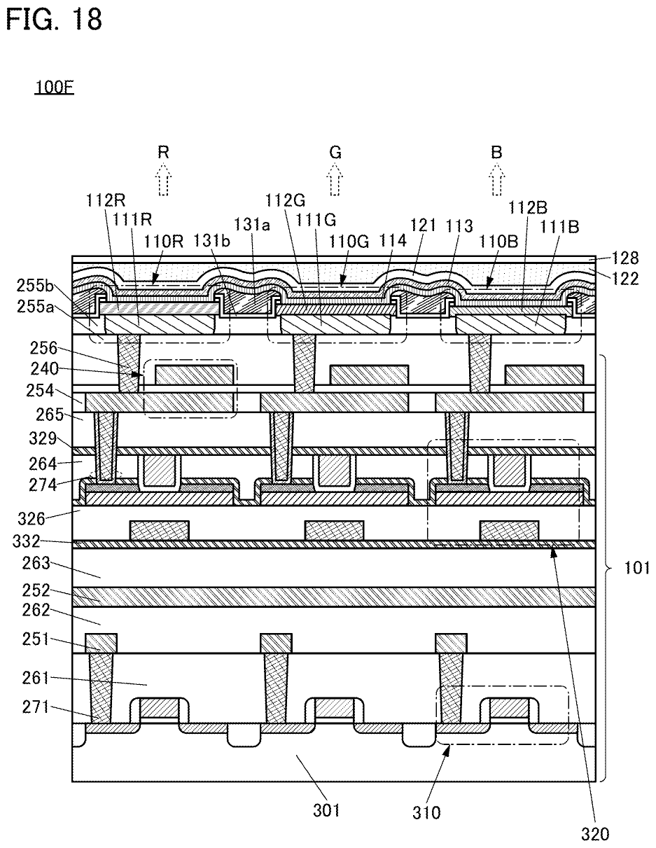

A display apparatus 100F illustrated in FIG. 18 has a structure in which the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistor 310 and the transistor 320 can also be used as transistors included in a variety of circuits such as an arithmetic circuit and a memory circuit.

With such a structure, not only the pixel circuit but also the driver circuit and the like can be formed directly under the light-emitting elements; thus, the display panel can be downsized as compared with the case where a driver circuit is provided around a display region.

This embodiment can be combined with the other embodiments as appropriate.

### Embodiment 4

In this embodiment, structure examples of a transistor that can be used in the display panel of one embodiment of the present invention will be described. Specifically, the case of using a transistor including silicon as a semiconductor where a channel is formed will be described.

One embodiment of the present invention is a display panel including light-emitting elements and pixel circuits. The display panel can perform full-color display by including three types of light-emitting elements that emit red (R) light, green (G) light, and blue (B) light.

Transistors containing silicon in their semiconductor layers where channels are formed are preferably used as all transistors included in the pixel circuit for driving the light-emitting element. Examples of silicon include single crystal silicon, polycrystalline silicon, and amorphous silicon. It is particularly preferable to use LTPS transistors in their semiconductor layers. The LTPS transistor has high field-effect mobility and favorable frequency characteristics.

With the use of the transistors containing silicon, such as the LTPS transistors, a circuit required to drive at a high frequency (e.g., a source driver circuit) can be formed on the same substrate as a display portion. This allows simplification of an external circuit mounted on the display panel and a reduction in costs of parts and mounting costs.

It is preferable to use a transistor containing a metal oxide (hereinafter also referred to as an oxide semiconductor) in its semiconductor layer where a channel is formed (hereinafter such a transistor is also referred to as an OS transistor) as at least one of the transistors included in the pixel circuit. An OS transistor has extremely higher field-effect mobility than a transistor containing amorphous silicon. In addition, the OS transistor has an extremely low leakage current between a source and a drain in an off state (hereinafter, also referred to as off-state current), and charge accumulated in a capacitor that is connected in series to the transistor can be held for a long period. Furthermore, power consumption of the display panel can be reduced with an OS transistor.

When an LTPS transistor is used as one or more of the transistors included in the pixel circuit and an OS transistor is used as the rest, the display panel can have low power consumption and high driving capability. In a more favorable example, it is preferable that an OS transistor be used as a transistor functioning as a switch for controlling electrical continuity between wirings and an LTPS transistor be used as a transistor for controlling current.

For example, one of the transistors included in the pixel circuit functions as a transistor for controlling current flowing through the light-emitting element and can be referred to as a driving transistor. One of a source and a drain of the driving transistor is electrically connected to the pixel electrode of the light-emitting element. An LTPS transistor is preferably used as the driving transistor. In that case, the amount of current flowing through the light-emitting element can be increased in the pixel circuit.

Another transistor included in the pixel circuit functions as a switch for controlling selection and non-selection of the pixel and can be referred to as a selection transistor. A gate of the selection transistor is electrically connected to a gate line, and one of a source and a drain thereof is electrically connected to a source line (signal line). An OS transistor is preferably used as the selection transistor. In that case, the gray level of the pixel can be maintained even with an extremely low frame frequency (e.g., 1 fps or less); thus, power consumption can be reduced by stopping the driver in displaying a still image.

More specific structure examples will be described below with reference to drawings.

### Structure Example 2 of Display Panel

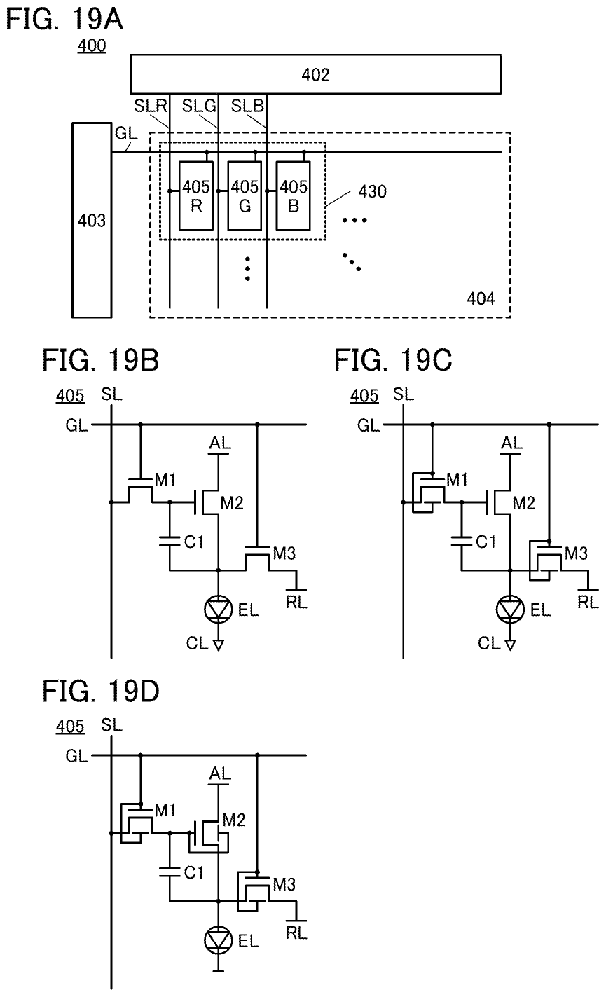

FIG. 19A illustrates a block diagram of a display panel 400. The display panel 400 includes a display portion 404, a driver circuit portion 402, a driver circuit portion 403, and the like.

The display portion 404 includes a plurality of pixels 430 arranged in a matrix. The pixels 430 each include a subpixel 405R, a subpixel 405G, and a subpixel 405B. The subpixel 405R, the subpixel 405G, and the subpixel 405B each include a light-emitting element functioning as a display device.

The pixel 430 is electrically connected to a wiring GL, a wiring SLR, a wiring SLG, and a wiring SLB. The wiring SLR, the wiring SLG, and the wiring SLB are electrically connected to the driver circuit portion 402. The wiring GL is electrically connected to the driver circuit portion 403. The driver circuit portion 402 functions as a source line driver circuit (also referred to as a source driver), and the driver circuit portion 403 functions as a gate line driver circuit (also referred to as a gate driver). The wiring GL functions as a gate line, and the wiring SLR, the wiring SLG, and the wiring SLB function as source lines.

The subpixel 405R includes a light-emitting element that emits red light. The subpixel 405G includes a light-emitting element that emits green light. The subpixel 405B includes a light-emitting element that emits blue light. Thus, the display panel 400 can perform full-color display. Note that the pixel 430 may include a subpixel including a light-emitting element that emits light of another color. For example, the pixel 430 may include, in addition to the above three subpixels, a subpixel including a light-emitting element that emits white light, a subpixel including a light-emitting element that emits yellow light, or the like.

The wiring GL is electrically connected to the subpixel 405R, the subpixel 405G, and the subpixel 405B arranged in a row direction (an extending direction of the wiring GL). The wiring SLR, the wiring SLG, and the wiring SLB are electrically connected to the subpixels 405R, the subpixels 405G, and the subpixels 405B (not illustrated) arranged in a column direction (an extending direction of the wiring SLR and the like), respectively.

### Structure Example of Pixel Circuit

FIG. 19B illustrates an example of a circuit diagram of a pixel 405 that can be used as the above subpixel 405R, the above subpixel 405G, and the above subpixel 405B. The pixel 405 includes a transistor M1, a transistor M2, a transistor M3, a capacitor C₁, and a light-emitting element EL. The wiring GL and a wiring SL are electrically connected to the pixel 405. The wiring SL corresponds to any of the wiring SLR, the wiring SLG, and the wiring SLB illustrated in FIG. 19A.

A gate of the transistor M1 is electrically connected to the wiring GL, one of a source and a drain of the transistor M1 is electrically connected to the wiring SL, and the other of the source and the drain of the transistor M1 is electrically connected to one electrode of the capacitor C1 and a gate of the transistor M2. One of a source and a drain of the transistor M2 is electrically connected to a wiring AL, and the other of the source and the drain of the transistor M2 is electrically connected to one electrode of the light-emitting element EL, the other electrode of the capacitor C1, and one of a source and a drain of the transistor M3. A gate of the transistor M3 is electrically connected to the wiring GL, and the other of the source and the drain of the transistor M3 is electrically connected to a wiring RL. The other electrode of the light-emitting element EL is electrically connected to a wiring CL.

A data potential D is supplied to the wiring SL. A selection signal is supplied to the wiring GL. The selection signal includes a potential for bringing a transistor into a conducting state and a potential for bringing a transistor into a non-conducting state.

A reset potential is supplied to the wiring RL. An anode potential is supplied to the wiring AL. A cathode potential is supplied to the wiring CL. In the pixel 405, the anode potential is a potential higher than the cathode potential. The reset potential supplied to the wiring RL can be set such that a potential difference between the reset potential and the cathode potential is lower than the threshold voltage of the light-emitting element EL. The reset potential can be a potential higher than the cathode potential, a potential equal to the cathode potential, or a potential lower than the cathode potential.

The transistor M1 and the transistor M3 each function as a switch. The transistor M2 functions as a transistor that controls current flowing through the light-emitting element EL. For example, the transistor M1 can be regarded as functioning as a selection transistor and the transistor M2 as a driving transistor.

Here, it is preferable to use LTPS transistors as all of the transistor M1 to the transistor M3. Alternatively, it is preferable to use OS transistors as the transistor M1 and the transistor M3 and to use an LTPS transistor as the transistor M2.

Alternatively, an OS transistor may be used as each of the transistor M1 to the transistor M3. In that case, an LTPS transistor can be used as one or more of a plurality of transistors included in the driver circuit portion 402 and a plurality of transistors included in the driver circuit portion 403, and OS transistors can be used as the other transistors. For example, OS transistors can be used as the transistor provided in the display portion 404, and LTPS transistors can be used as the transistors provided in the driver circuit portion 402 and the driver circuit portion 403.

A transistor using an oxide semiconductor having a wider band gap and a lower carrier density than silicon can achieve an extremely low off-state current. Thus, such a low off-state current enables retention of charge accumulated in a capacitor that is series-connected to the transistor for a long period. Therefore, it is particularly preferable to use a transistor including an oxide semiconductor as the transistor M1 and the transistor M3 each of which is connected in series with the capacitor C1. The use of the transistor including an oxide semiconductor as each of the transistor M1 and the transistor M3 can prevent leakage of charge retained in the capacitor C1 through the transistor M1 or the transistor M3. Furthermore, since charge retained in the capacitor C1 can be retained for a long time, a still image can be displayed for a long period without rewriting data in the pixel 405.

Although n-channel transistors are illustrated as the transistors in FIG. 19B, p-channel transistors can also be used.

The transistors included in the pixel 405 are preferably arranged over one substrate.

Transistors each including a pair of gates overlapping with each other with a semiconductor layer therebetween can be used as the transistors included in the pixel 405.

In the transistor including a pair of gates, the same potential is supplied to the pair of gates electrically connected to each other, which brings advantage that the transistor can have a higher on-state current and improved saturation characteristics. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

The pixel 405 illustrated in FIG. 19C is an example of the case where a transistor including a pair of gates is used as each of the transistor M1 and the transistor M3. In each of the transistor M1 and the transistor M3, the pair of gates is electrically connected to each other. Such a structure can shorten the period in which data is written to the pixel 405.

The pixel 405 illustrated in FIG. 19D is an example of the case where a transistor including a pair of gates is used as the transistor M2 in addition to the transistor M1 and the transistor M3. The pair of gates of the transistor M2 is electrically connected to each other. When such a transistor is used as the transistor M2, the saturation characteristics are improved, whereby emission luminance of the light-emitting element EL can be controlled easily and the display quality can be increased.

### Structure Example of Transistor

Cross-sectional structure examples of a transistor that can be used in the above display panel will be described below.

### Structure Example 1

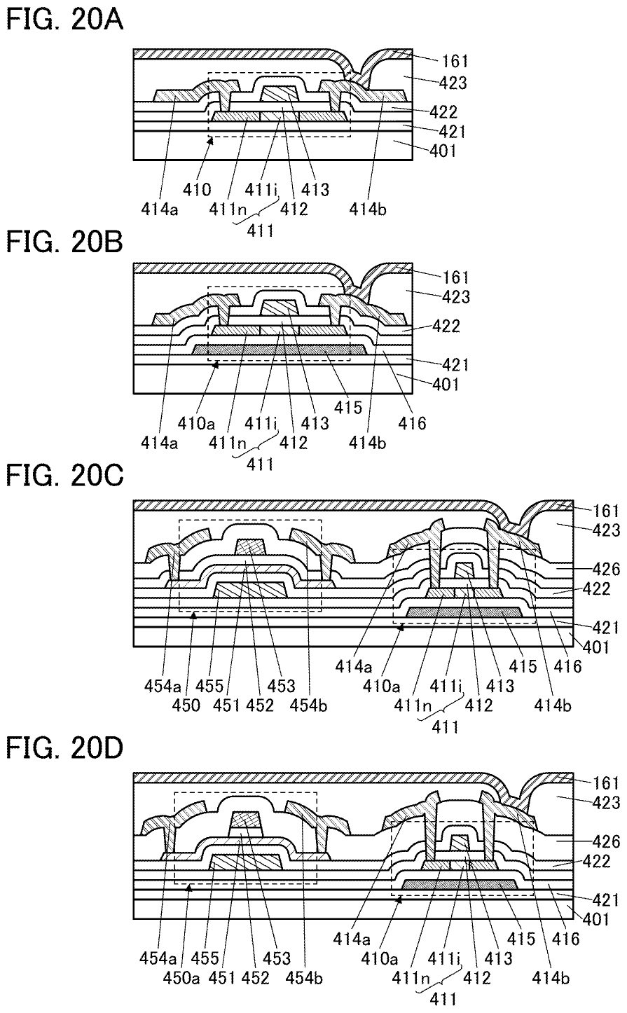

FIG. 20A is a cross-sectional view including a transistor 410.

The transistor 410 is provided over a substrate 401 and contains polycrystalline silicon in its semiconductor layer. For example, the transistor 410 corresponds to the transistor M2 in the pixel 405. In other words, FIG. 20A illustrates an example in which one of a source and a drain of the transistor 410 is electrically connected to the conductive layer 161 of the light-emitting element.

The transistor 410 includes a semiconductor layer 411, an insulating layer 412, a conductive layer 413, and the like. The semiconductor layer 411 includes a channel formation region 411i and low-resistance regions 411n. The semiconductor layer 411 contains silicon. The semiconductor layer 411 preferably contains polycrystalline silicon. Part of the insulating layer 412 functions as a gate insulating layer. Part of the conductive layer 413 functions as a gate electrode.

Note that the semiconductor layer 411 can alternatively contain a metal oxide exhibiting semiconductor characteristics (also referred to as an oxide semiconductor). In that case, the transistor 410 can be referred to as an OS transistor.

The low-resistance regions 411n are regions containing an impurity element. For example, in the case where the transistor 410 is an n-channel transistor, phosphorus, arsenic, or the like is added to the low-resistance regions 411n. Meanwhile, in the case where the transistor 410 is a p-channel transistor, boron, aluminum, or the like is added to the low-resistance regions 411n. In addition, in order to control the threshold voltage of the transistor 410, the above-described impurity may be added to the channel formation region 411i.

An insulating layer 421 is provided over the substrate 401. The semiconductor layer 411 is provided over the insulating layer 421. The insulating layer 412 is provided to cover the semiconductor layer 411 and the insulating layer 421. The conductive layer 413 is provided at a position that is over the insulating layer 412 and overlaps with the semiconductor layer 411.

An insulating layer 422 is provided to cover the conductive layer 413 and the insulating layer 412. A conductive layer 414a and a conductive layer 414b are provided over the insulating layer 422. The conductive layer 414a and the conductive layer 414b are each electrically connected to the low-resistance regions 411n in an opening portion provided in the insulating layer 422 and the insulating layer 412. Part of the conductive layer 414a functions as one of a source electrode and a drain electrode and part of the conductive layer 414b functions as the other of the source electrode and the drain electrode. An insulating layer 423 is provided to cover the conductive layer 414a, the conductive layer 414b, and the insulating layer 422.

The conductive layer 161 functioning as a pixel electrode is provided over the insulating layer 423. The conductive layer 161 is provided over the insulating layer 423 and is electrically connected to the conductive layer 414b in an opening provided in the insulating layer 423. Although not illustrated here, a conductive layer included in a light-emitting element, an EL layer, and a common electrode can be stacked over the conductive layer 161.

### Structure Example 2

FIG. 20B illustrates a transistor 410a including a pair of gate electrodes. The transistor 410a illustrated in FIG. 20B is different from FIG. 20A mainly in including a conductive layer 415 and an insulating layer 416.

The conductive layer 415 is provided over the insulating layer 421. The insulating layer 416 is provided to cover the conductive layer 415 and the insulating layer 421. The semiconductor layer 411 is provided such that at least the channel formation region 411i overlaps with the conductive layer 415 with the insulating layer 416 therebetween.

In the transistor 410a illustrated in FIG. 20B, part of the conductive layer 413 functions as a first gate electrode, and part of the conductive layer 415 functions as a second gate electrode. At this time, part of the insulating layer 412 functions as a first gate insulating layer, and part of the insulating layer 416 functions as a second gate insulating layer.

Here, to electrically connect the first gate electrode to the second gate electrode, the conductive layer 413 is electrically connected to the conductive layer 415 through an opening portion provided in the insulating layer 412 and the insulating layer 416 in a region not illustrated. To electrically connect the second gate electrode to a source or a drain, the conductive layer 415 is electrically connected to the conductive layer 414a or the conductive layer 414b through an opening portion provided in the insulating layer 422, the insulating layer 412, and the insulating layer 416 in a region not illustrated.

In the case where LTPS transistors are used as all of the transistors included in the pixel 405, the transistor 410 illustrated in FIG. 20A as an example or the transistor 410a illustrated in FIG. 20B as an example can be used. In this case, the transistor 410a may be used as all of the transistors included in the pixel 405, the transistor 410 may be used as all of the transistors, or the transistor 410a and the transistor 410 may be used in combination.

### Structure Example 3

Described below is an example of a structure including both a transistor containing silicon in its semiconductor layer and a transistor containing a metal oxide in its semiconductor layer.

FIG. 20C is a schematic cross-sectional view including the transistor 410a and a transistor 450.

Structure example 1 described above can be referred to for the transistor 410a. Although an example using the transistor 410a is shown here, a structure including the transistor 410 and the transistor 450 or a structure including all the transistor 410, the transistor 410a, and the transistor 450 may alternatively be employed.

The transistor 450 contains a metal oxide in its semiconductor layer. The structure illustrated in FIG. 20C is an example in which the transistor 450 and the transistor 410a respectively correspond to the transistor M1 and the transistor M2 in the pixel 405, for example. That is, FIG. 20C illustrates an example in which one of a source and a drain of the transistor 410a is electrically connected to the conductive layer 161.

Moreover, FIG. 20C illustrates an example in which the transistor 450 includes a pair of gates.

The transistor 450 includes a conductive layer 455, the insulating layer 422, a semiconductor layer 451, an insulating layer 452, a conductive layer 453, and the like. Part of the conductive layer 453 functions as a first gate of the transistor 450, and part of the conductive layer 455 functions as a second gate of the transistor 450. In this case, part of the insulating layer 452 functions as a first gate insulating layer of the transistor 450, and part of the insulating layer 422 functions as a second gate insulating layer of the transistor 450.

The conductive layer 455 is provided over the insulating layer 412. The insulating layer 422 is provided to cover the conductive layer 455. The semiconductor layer 451 is provided over the insulating layer 422. The insulating layer 452 is provided to cover the semiconductor layer 451 and the insulating layer 422. The conductive layer 453 is provided over the insulating layer 452 and includes a region overlapping with the semiconductor layer 451 and the conductive layer 455.

An insulating layer 426 is provided to cover the insulating layer 452 and the conductive layer 453. A conductive layer 454a and a conductive layer 454b are provided over the insulating layer 426. The conductive layer 454a and the conductive layer 454b are electrically connected to the semiconductor layer 451 in opening portions provided in the insulating layer 426 and the insulating layer 452. Part of the conductive layer 454a functions as one of a source electrode and a drain electrode and part of the conductive layer 454b functions as the other of the source electrode and the drain electrode. The insulating layer 423 is provided to cover the conductive layer 454a, the conductive layer 454b, and the insulating layer 426.

Here, the conductive layer 414a and the conductive layer 414b electrically connected to the transistor 410a are preferably formed by processing the same conductive film as the conductive layer 454a and the conductive layer 454b. In FIG. 20C, the conductive layer 414a, the conductive layer 414b, the conductive layer 454a, and the conductive layer 454b are formed on the same plane (i.e., in contact with the top surface of the insulating layer 426) and contain the same metal element. In this case, the conductive layer 414a and the conductive layer 414b are electrically connected to the low-resistance regions 411n through openings provided in the insulating layer 426, the insulating layer 452, the insulating layer 422, and the insulating layer 412. This can simplify the fabricating process and is thus preferable.

Moreover, the conductive layer 413 functioning as the first gate electrode of the transistor 410a and the conductive layer 455 functioning as the second gate electrode of the transistor 450 are preferably formed by processing the same conductive film. In FIG. 20C, the conductive layer 413 and the conductive layer 455 are formed on the same plane (i.e., in contact with the top surface of the insulating layer 412) and contain the same metal element. This can simplify the fabricating process and is thus preferable.

In FIG. 20C, the insulating layer 452 functioning as the first gate insulating layer of the transistor 450 covers an end portion of the semiconductor layer 451; alternatively, as in a transistor 450a illustrated in FIG. 20D, the insulating layer 452 may be processed to have the same or substantially the same top surface shape as the conductive layer 453.

Note that in this specification and the like, the expression “top surface shapes are substantially the same” means that outlines of stacked layers at least partly overlap with each other. For example, the case of processing the upper layer and the lower layer with the use of the same mask pattern or mask patterns that are partly the same is included. However, in some cases, the outlines do not completely overlap with each other and the upper layer is positioned inward from the lower layer or the upper layer is positioned outward from the lower layer; such a case is also described with the expression “top surface shapes are substantially the same”.

Although the example in which the transistor 410a corresponds to the transistor M2 and is electrically connected to the pixel electrode is shown here, one embodiment of the present invention is not limited thereto. For example, a structure where the transistor 450 or the transistor 450a corresponds to the transistor M2 may be employed. In that case, the transistor 410a corresponds to the transistor M1, the transistor M3, or another transistor.

This embodiment can be combined with the other embodiments as appropriate.

### Embodiment 5

In this embodiment, a light-emitting device that can be used for the display panel according to one embodiment of the present invention will be described.

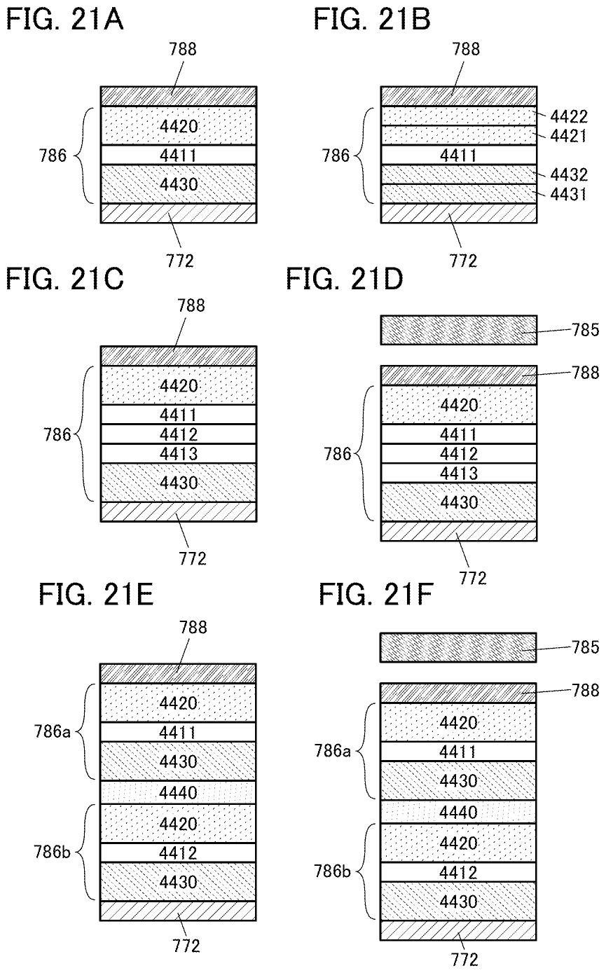

As illustrated in FIG. 21A, the light-emitting device includes an EL layer 786 between a pair of electrodes (a lower electrode 772 and an upper electrode 788). The EL layer 786 can be formed of a plurality of layers such as a layer 4420, a light-emitting layer 4411, and a layer 4430. The layer 4420 can include, for example, a layer containing a substance with a high electron-injection property (electron-injection layer) and a layer containing a substance with a high electron-transport property (electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430 provided between the pair of electrodes, can function as a single light-emitting unit, and the structure in FIG. 21A is referred to as a single structure in this specification.

FIG. 21B is a variation example of the EL layer 786 included in the light-emitting device illustrated in FIG. 21A. Specifically, the light-emitting device illustrated in FIG. 21B includes a layer 4431 over the lower electrode 772, a layer 4432 over the layer 4431, the light-emitting layer 4411 over the layer 4432, a layer 4421 over the light-emitting layer 4411, a layer 4422 over the layer 4421, and the upper electrode 788 over the layer 4422. For example, when the lower electrode 772 is an anode and the upper electrode 788 is a cathode, the layer 4431 functions as a hole-injection layer, the layer 4432 functions as a hole-transport layer, the layer 4421 functions as an electron-transport layer, and the layer 4422 functions as an electron-injection layer. Alternatively, when the lower electrode 772 is a cathode and the upper electrode 788 is an anode, the layer 4431 functions as an electron-injection layer, the layer 4432 functions as an electron-transport layer, the layer 4421 functions as a hole-transport layer, and the layer 4422 functions as a hole-injection layer. With such a layer structure, carriers can be efficiently injected to the light-emitting layer 4411, and the efficiency of the recombination of carriers in the light-emitting layer 4411 can be enhanced.

Note that a structure in which a plurality of light-emitting layers (light-emitting layers 4411, 4412, and 4413) are provided between the layer 4420 and the layer 4430 as illustrated in FIG. 21C and FIG. 21D is a variation of the single structure.

A structure in which a plurality of light-emitting units (an EL layer 786a and an EL layer 786b) are connected in series with a charge-generation layer 4440 therebetween as illustrated in FIG. 21E or FIG. 21F is referred to as a tandem structure in this specification. Note that the tandem structure may be referred to as a stack structure. The tandem structure enables a light-emitting device capable of high-luminance light emission.

In FIG. 21C and FIG. 21D, light-emitting materials that emit light of the same color, or moreover, the same light-emitting material may be used for the light-emitting layer 4411, the light-emitting layer 4412, and the light-emitting layer 4413. For example, a light-emitting material that emit blue light may be used for the light-emitting layer 4411, the light-emitting layer 4412, and the light-emitting layer 4413. A color conversion layer may be provided as a layer 785 illustrated in FIG. 21D.

Alternatively, light-emitting materials that emit light of different colors may be used for the light-emitting layer 4411, the light-emitting layer 4412, and the light-emitting layer 4413. White light emission can be obtained when the light-emitting layer 4411, the light-emitting layer 4412, and the light-emitting layer 4413 emit light of complementary colors. A color filter (also referred to as a coloring layer) may be provided as the layer 785 illustrated in FIG. 21D. When white light passes through the color filter, light of a desired color can be obtained.

In FIG. 21E and FIG. 21F, light-emitting materials that emit light of the same color, or moreover, the same light-emitting material may be used for the light-emitting layer 4411 and the light-emitting layer 4412. Alternatively, light-emitting materials that emit light of different colors may be used for the light-emitting layer 4411 and the light-emitting layer 4412. White light emission can be obtained when the light-emitting layer 4411 and the light-emitting layer 4412 emit light of complementary colors. FIG. 21F illustrates an example in which the layer 785 is further provided. One or both of a color conversion layer and a color filter (coloring layer) can be used as the layer 785.

Note that also in FIG. 21C, FIG. 21D, FIG. 21E, and FIG. 21F, the layer 4420 and the layer 4430 may each have a stacked-layer structure of two or more layers as illustrated in FIG. 21B.

A structure in which light emission colors (e.g., blue (B), green (G), and red (R)) are separately formed for the light-emitting devices is referred to as an SBS structure in some cases.

The emission color of the light-emitting device can be red, green, blue, cyan, magenta, yellow, white, or the like depending on the material that constitutes the EL layer 786. Furthermore, the color purity can be further increased when the light-emitting device has a microcavity structure.

The light-emitting device that emits white light preferably contains two or more kinds of light-emitting substances in the light-emitting layer. To obtain white light emission, two or more kinds of light-emitting substances are selected such that their emission colors are complementary. For example, when an emission color of a first light-emitting layer and an emission color of a second light-emitting layer are complementary colors, the light-emitting device can be configured to emit white light as a whole. The same applies to a light-emitting device including three or more light-emitting layers.

The light-emitting layer preferably contains two or more light-emitting substances that emit light of R (red), G (green), B (blue), Y (yellow), O (orange), and the like. Alternatively, the light-emitting layer preferably contains two or more light-emitting substances that emit light containing two or more of spectral components of R, G, and B.

This embodiment can be combined with the other embodiments as appropriate.

### Embodiment 6

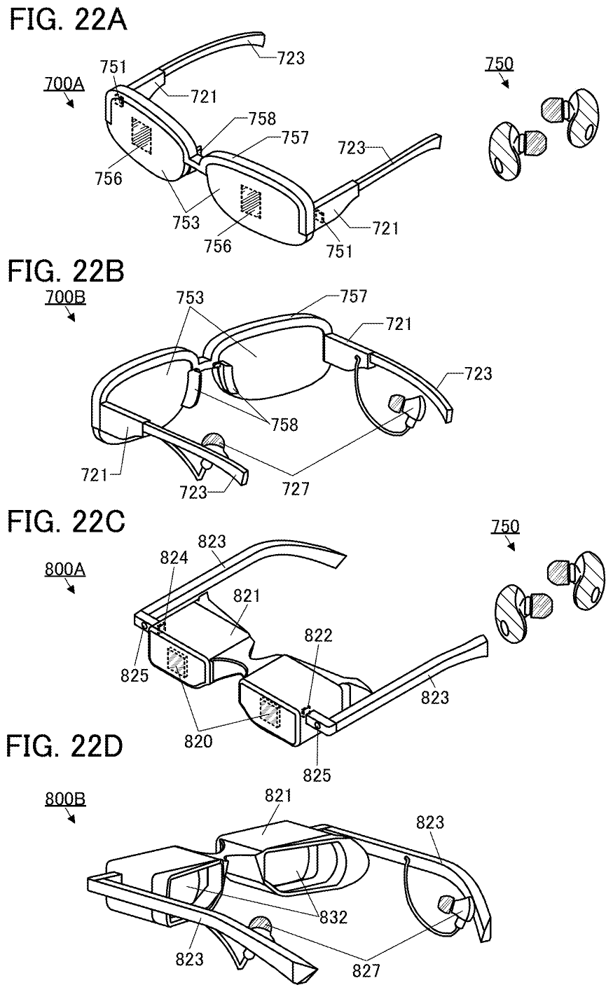

In this embodiment, electronic devices of one embodiment of the present invention are described with reference to FIG. 22 to FIG. 24.

An electronic device of this embodiment can each be used for the display system of one embodiment of the present invention. Specifically, the electronic device can be used for a wearable display apparatus or a terminal in the display system of one embodiment of the present invention.

The electronic device of this embodiment includes the display panel of one embodiment of the present invention in a display portion. The display panel of one embodiment of the present invention can be easily increased in resolution and definition and can achieve high display quality. Thus, the display panel of one embodiment of the present invention can be used for a display portion of a variety of electronic devices.

Examples of electronic devices include a digital camera, a digital video camera, a digital photo frame, a mobile phone, a portable game console, a portable information terminal, and an audio reproducing device in addition to electronic devices with a relatively large screen, such as a television device, a desktop or laptop personal computer, a monitor of a computer or the like, digital signage, and a large game machine like a pachinko machine.

In particular, a display panel of one embodiment of the present invention can have high resolution, and thus can be favorably used for an electronic device having a relatively small display portion. Examples of such an electronic device include watch-type and bracelet-type information terminal devices (wearable devices) and wearable devices capable of being worn on a head, such as a VR device like a head-mounted display, a glasses-type AR device, and an MR device.

The definition of the display panel of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. Furthermore, the pixel density (resolution) of the display panel of one embodiment of the present invention is preferably higher than or equal to 100 ppi, further preferably higher than or equal to 300 ppi, still further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, and yet further preferably higher than or equal to 7000 ppi. With the use of such a display panel having one or both of high definition and high resolution, the electronic device can provide higher realistic sensation, sense of depth, and the like in personal use such as portable use and home use. There is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices are described with reference to FIG. 22A to FIG. 22D. These wearable devices have one or both of a function of displaying AR contents and a function of displaying VR contents. Note that these wearable devices may have a function of displaying SR or MR contents, in addition to AR and VR contents. The electronic device has a function of displaying a content of at least one of AR, VR, SR, MR, and the like enables the user can feel a higher sense of immersion. The electronic devices illustrated in FIG. 22A to FIG. 22D are each suitable for a wearable display apparatus in the display system of one embodiment of the present invention.

An electronic device 700A illustrated in FIG. 22A and an electronic device 700B illustrated in FIG. 22B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display panel of one embodiment of the present invention can be used for the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of or in addition to the wireless communication device, a connector to which a cable for supplying a video signal and a power supply potential can be connected may be provided.

The electronic device 700A and the electronic device 700B are provided with a battery so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

A variety of touch sensors can be applied to the touch sensor module. Any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element (also referred to as a photoelectric conversion device) can be used as a light-receiving element (also referred to as a light-receiving device). One or both of an inorganic semiconductor and an organic semiconductor can be used for an active layer of the photoelectric conversion device.

An electronic device 800A illustrated in FIG. 22C and an electronic device 800B illustrated in FIG. 22D each include a pair of display portions 820, a housing 821, a communication portion 822, a pair of wearing portions 823, a control portion 824, a pair of image capturing portions 825, and a pair of lenses 832.

The display panel of one embodiment of the present invention can be used in the display portions 820. Thus, the electronic device can perform display with extremely high resolution. This enables a user to feel high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the wearing portions 823. FIG. 22C or the like illustrates an example in which the wearing portion 823 has a shape like a temple (also referred to as a joint or the like) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance from an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be applied to any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 22A has a function of transmitting information to the earphones 750 with the wireless communication function. For another example, the electronic device 800A illustrated in FIG. 22C has a function of transmitting information to the earphones 750 with the wireless communication function.

The electronic device may include an earphone portion. The electronic device 700B illustrated in FIG. 22B includes earphone portions 727. For example, a structure in which the earphone portions 727 and the control portion are connected to each other by wire can be employed. Part of a wiring that connects the earphone portions 727 and the control portion may be positioned inside the housing 721 or the wearing portion 723.

Similarly, the electronic device 800B illustrated in FIG. 22D includes earphone portions 827. For example, a structure in which the earphone portions 827 and the control portion 824 are connected to each other by wire can be employed. Part of a wiring that connects the earphone portions 827 and the control portion 824 may be positioned inside the housing 821 or the wearing portions 823. The earphone portions 827 and the wearing portions 823 may include magnets. This is preferable because the earphone portions 827 can be fixed to the wearing portions 823 with magnetic force and thus can be easily housed.

Note that the electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

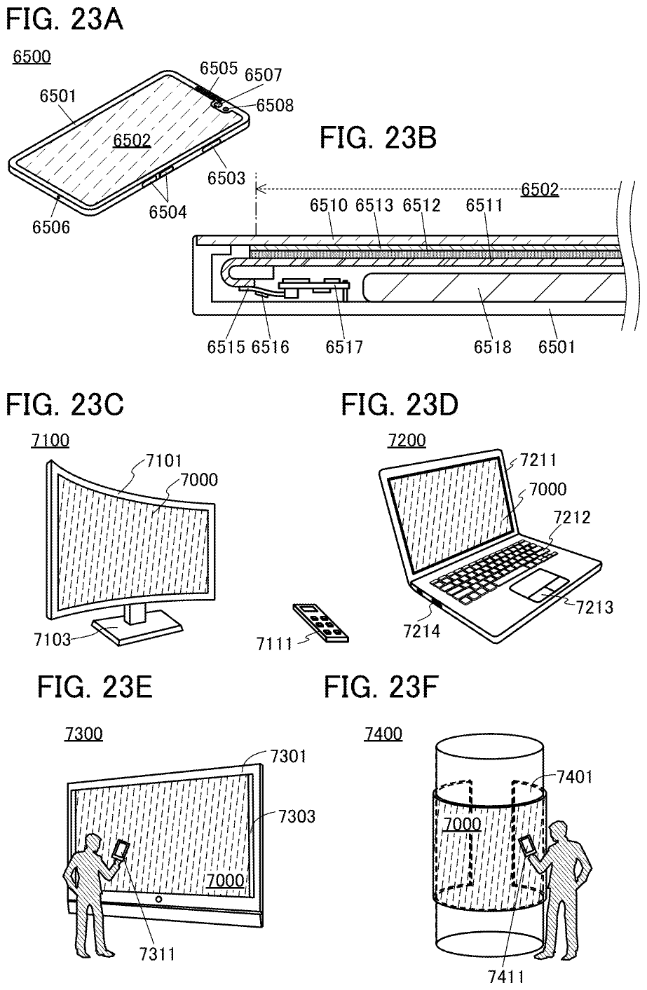

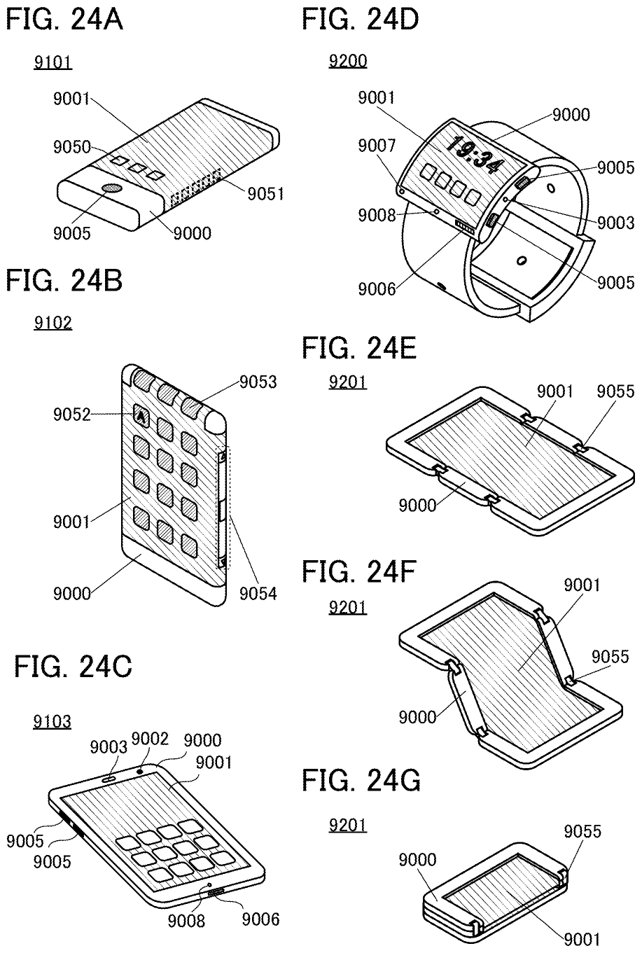

The electronic devices illustrated in FIG. 23 and FIG. 24 are each suitable for the terminal in the display system of one embodiment of the present invention.

An electronic device 6500 illustrated in FIG. 23A is a portable information terminal that can be used for a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display panel of one embodiment of the present invention can be used for the display portion 6502.

FIG. 23B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be obtained. Since the display panel 6511 is extremely thin, the battery 6518 with high capacity can be mounted while the thickness of the electronic device is reduced. Moreover, part of the display panel 6511 is folded back so that a connection portion with the FPC 6515 is provided on the back side of the pixel portion, whereby an electronic device with a narrow bezel can be obtained.

FIG. 23C illustrates an example of a television device. In a television device 7100, a display portion 7000 is incorporated in a housing 7101. Here, the housing 7101 is supported by a stand 7103.

The display panel of one embodiment of the present invention can be used for the display portion 7000.

Operation of the television device 7100 illustrated in FIG. 23C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be operated and videos displayed on the display portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 23D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display panel of one embodiment of the present invention can be used for the display portion 7000.

FIG. 23E and FIG. 23F illustrate examples of digital signage.

Digital signage 7300 illustrated in FIG. 23E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 23F is digital signage 7400 attached to a cylindrical pillar 7401. The digital signage 7400 includes the display portion 7000 provided along a curved surface of the pillar 7401.

The display panel of one embodiment of the present invention can be used for the display portion 7000 in FIG. 23E and FIG. 23F.

A larger area of the display portion 7000 can increase the amount of information that can be provided at a time. The larger the display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 23E and FIG. 23F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

Electronic devices illustrated in FIG. 24A to FIG. 24G each include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 24A to FIG. 24G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a storage medium (an external storage medium or a storage medium incorporated in the camera), a function of displaying the taken image on the display portion, or the like.

The electronic devices illustrated in FIG. 24A to FIG. 24G are described in detail below.

FIG. 24A is a perspective view illustrating a portable information terminal 9101. For example, the portable information terminal 9101 can be used for a smartphone. Note that the portable information terminal 9101 may include the speaker 9003, the connection terminal 9006, the sensor 9007, or the like. The portable information terminal 9101 can display characters and image information on its plurality of surfaces. FIG. 24A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 24B is a perspective view illustrating a portable information terminal 9102. The portable information terminal 9102 has a function of displaying information on three or more surfaces of the display portion 9001. Shown here is an example in which information 9052, information 9053, and information 9054 are displayed on different surfaces. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 24C is a perspective view of a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 24D is a perspective view illustrating a watch-type portable information terminal 9200. For example, the portable information terminal 9200 can be used for a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 24E to FIG. 24G are perspective views illustrating a foldable portable information terminal 9201. FIG. 24E is a perspective view of an opened state of the portable information terminal 9201, FIG. 24G is a perspective view of a folded state thereof, and FIG. 24F is a perspective view of a state in the middle of change from one of FIG. 24E and FIG. 24G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### REFERENCE NUMERALS

100: display apparatus, 100A: display apparatus, 100B: display apparatus, 100C: display apparatus, 100D: display apparatus, 100E: display apparatus, 100F: display apparatus, 101: substrate, 103: pixel, 110: light-emitting element, 110a: subpixel, 110b: subpixel, 110B: light-emitting element, 110c: subpixel, 110d: subpixel, 110G: light-emitting element, 110R: light-emitting element, 111: conductive layer, 111B: conductive layer, 111C: connection electrode, 111G: conductive layer, 111R: conductive layer, 111S: conductive layer, 112: EL layer, 112B: EL layer, 112Bf: EL film, 112G: EL layer, 112Gf: EL film, 112R: EL layer, 112Rf: EL film, 112S: active layer, 113: common electrode, 114: common layer, 115: conductive layer, 115B: conductive layer, 115G: conductive layer, 115R: conductive layer, 117: conductive layer, 117B: conductive layer, 117G: conductive layer, 117R: conductive layer, 120: slit, 121: protective layer, 122: resin layer, 124a: pixel, 124b: pixel, 126: resin layer, 128: substrate, 129: coloring layer, 129a: coloring layer, 129b: coloring layer, 129c: coloring layer, 129d: black matrix, 131a: resin layer, 131af: resin film, 131b: insulating layer, 131bf: insulating film, 140: resin layer, 143a: resist mask, 143b: resist mask, 143c: resist mask, 144: sacrificial film, 144B: sacrificial film, 144G: sacrificial film, 144R: sacrificial film, 145: sacrificial layer, 145B: sacrificial layer, 145G: sacrificial layer, 145R: sacrificial layer, 146B: sacrificial film, 146G: sacrificial film, 146R: sacrificial film, 147: sacrificial layer, 147B: sacrificial layer, 147G: sacrificial layer, 147R: sacrificial layer, 150: light-receiving element, 161: conductive layer, 240: capacitor, 241: conductive layer, 243: insulating layer, 245: conductive layer, 251: conductive layer, 252: conductive layer, 254: insulating layer, 255: insulating layer, 255a: insulating layer, 255b: insulating layer, 256: plug, 257: conductive layer, 261: insulating layer, 262: insulating layer, 263: insulating layer, 264: insulating layer, 265: insulating layer, 271: plug, 274: plug, 274a: conductive layer, 274b: conductive layer, 280: display module, 281: display portion, 282: circuit portion, 283: pixel circuit portion, 283a: pixel circuit, 284: pixel portion, 284a: pixel, 285: terminal portion, 286: wiring portion, 290: FPC, 291: substrate, 292: substrate, 301: substrate, 301A: substrate, 301B: substrate, 310: transistor, 310A: transistor, 310B: transistor, 311: conductive layer, 312: low-resistance region, 313: insulating layer, 314: insulating layer, 315: element isolation layer, 320: transistor, 320A: transistor, 320B: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 351: substrate, 352: finger, 353: layer, 355: functional layer, 357: layer, 359: substrate, 400: display panel, 401: substrate, 402: driver circuit portion, 403: driver circuit portion, 404: display portion, 405: pixel, 405B: subpixel, 405G: subpixel, 405R: subpixel, 410: transistor, 410a: transistor, 411: semiconductor layer, 411i: channel formation region, 411n: low-resistance region, 412: insulating layer, 413: conductive layer, 414a: conductive layer, 414b: conductive layer, 415: conductive layer, 416: insulating layer, 421: insulating layer, 422: insulating layer, 423: insulating layer, 426: insulating layer, 430: pixel, 450: transistor, 450a: transistor, 451: semiconductor layer, 452: insulating layer, 453: conductive layer, 454a: conductive layer, 454b: conductive layer, 455: conductive layer, 700A: electronic device, 700B: electronic device, 721: housing, 723: wearing portion, 727: earphone portion, 750: earphone, 751: display panel, 753: optical member, 756: display region, 757: frame, 758: nose pad, 772: lower electrode, 785: layer, 786: EL layer, 786a: EL layer, 786b: EL layer, 788: upper electrode, 800A: electronic device, 800B: electronic device, 820: display portion, 821: housing, 822: communication portion, 823: wearing portion, 824: control portion, 825: image capturing portion, 827: earphone portion, 832: lens, 4411: light-emitting layer, 4412: light-emitting layer, 4413: light-emitting layer, 4420: layer, 4421: layer, 4422: layer, 4430: layer, 4431: layer, 4432: layer, 4440: charge generation layer, 6500: electronic device, 6501: housing, 6502: display portion, 6503: power source button, 6504: button, 6505: a speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: a speaker, 7311: information terminal, 7400: digital signage, 7401: pillar, 7411: information terminal, 9000: housing, 9001: display portion, 9002: camera, 9003: a speaker, 9005: control key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising:
a first insulating layer;
a first conductive layer provided in an opening of the first insulating layer;
a first EL layer over the first conductive layer and the first insulating layer;
a second insulating layer which is in contact with a side surface of the first EL layer and a top surface of the first insulating layer; and
a second conductive layer over the first EL layer and the second insulating layer.

2. The display apparatus according to claim 1, further comprising a first resin layer over the second insulating layer,
wherein the second insulating layer comprises a first region sandwiched between the side surface of the first EL layer and the first resin layer, and a second region sandwiched between the top surface of the first insulating layer and the first resin layer, and
wherein the second conductive layer is in contact with a top surface of the first EL layer and a top surface of the first resin layer.

3. The display apparatus according to claim 1, further comprising a first resin layer and a first layer,
wherein the first layer contains a material with a high electron-injection property,
wherein the first resin layer is provided over the second insulating layer,
wherein the second insulating layer comprises a first region between a side surface of the first EL layer and the first resin layer, and a second region between a top surface of the first insulating layer and the first resin layer,
wherein the first layer is in contact with a top surface of the first EL layer and a top surface of the first resin layer, and
wherein the second conductive layer is in contact with a top surface of the first layer.

4. A display apparatus comprising:
a first light-emitting element;
a second light-emitting element arranged to be adjacent to the first light-emitting element;
a first insulating layer; and
a second insulating layer,
wherein the first light-emitting element comprises a first conductive layer provided in a first opening of the first insulating layer, a first EL layer over the first conductive layer and the first insulating layer, and a common electrode over the first EL layer,
wherein the second light-emitting element comprises a second conductive layer provided in a second opening of the first insulating layer, a second EL layer over the second conductive layer and the first insulating layer, and the common electrode over the second EL layer,
wherein the second insulating layer is in contact with a side surface of the first EL layer, a side surface of the second EL layer, and a top surface of the first insulating layer, and
wherein the common electrode is provided over the second insulating layer and comprises a third region overlapping with the second insulating layer.

5. The display apparatus according to claim 4, further comprising a first resin layer over the second insulating layer,
wherein the first resin layer is provided in a fourth region between the first EL layer and the second EL layer, and
wherein the common electrode is in contact with a top surface of the first EL layer, a top surface of the second EL layer, and a top surface of the first resin layer.

6. The display apparatus according to claim 4, further comprising a first resin layer and a common layer,
wherein the common layer contains a material with a high electron-injection property,
wherein the first resin layer is provided over the first insulating layer,
wherein the first resin layer is provided in a fourth region between the first EL layer and the second EL layer,
wherein the common layer is in contact with a top surface of the first EL layer, a top surface of the second EL layer, and a top surface of the first resin layer, and
wherein the common electrode is in contact with a top surface of the common layer.
